(19) United States
(12) Patent Application Publication
(10) Pub. No.: US 2026/0246442 A1
(43) Pub. Date: Aug. 20, 2026

(54) BULK ACOUSTIC WAVE RESONATOR, FABRICATION METHOD THEREOF, AND ELECTRONIC DEVICE

(71) Applicants: Beijing BOE Technology Development Co., Ltd., Beijing (CN); BOE TECHNOLOGY GROUP CO., LTD., Beijing (CN)

(72) Inventor: Xiyuan WANG, Beijing (CN)

(21) Appl. No.: 18/995,242

(22) PCT Filed: Mar. 22, 2023
(86) PCT No.: PCT/CN2023/083009

§ 371 Date: Jan. 16, 2025

(51) Int. Cl. H03H 9/02; H03H 3/02; H03H 9/17

(52) U.S. Cl. CPC H03H 9/02102; H03H 3/02; H03H 9/173; H03H 2003/021

(57) ABSTRACT

A bulk acoustic wave resonator includes a base substrate, a first electrode, a piezoelectric layer and a second electrode; where the first electrode is on the base substrate, the second electrode is on a side of the first electrode away from the base substrate, the piezoelectric layer is between the first electrode and the second electrode, and orthographic projections of any two of the first electrode, the piezoelectric layer and the second electrode on the base substrate at least partially overlap each other; where a temperature drift compensation layer is on a side of the piezoelectric layer close to the base substrate and/or on a side of the piezoelectric layer away from the base substrate; and the temperature drift compensation layer is made of a material having a property of expanding with heat and contracting with cold, and is configured to suppress temperature drift of the bulk acoustic wave resonator.

### TECHNICAL FIELD

The present disclosure relates to the field of communication technology, and in particular to a bulk acoustic wave resonator, a fabrication method thereof, and an electronic device.

### BACKGROUND

In the field of mobile communication, due to the narrow range of available frequencies allocated and the large number of frequency bands used for mobile communication, a spacing between adjacent frequency bands is narrow (about several megahertz to tens of megahertz), and a bandwidth of a single frequency band is narrow (tens of megahertz); it is required that a filter used in a mobile phone must have performance characteristics of small in-band ripple, large out-of-band rejection, and good rectangularity. A conventional micro strip filter has a large volume, insufficient out-of-band rejection, and poor rectangularity, and cannot meet the requirements; a cavity filter has a large volume, and cannot meet the requirements; a dielectric filter has large in-band insertion loss and poor rectangularity, and cannot meet the requirements; and an IPD (integrated passive device) filter has large in-band ripple and poor rectangularity, and cannot meet the requirements.

A bulk acoustic wave resonator is a basic structural unit of a bulk acoustic wave filter. An existing bulk acoustic wave resonator adopts a silicon wafer as a substrate material, thereon with a sandwich structure consisting of a first electrode, a piezoelectric material, and a second electrode from bottom to top. The operation principle is as follows: a radio frequency signal is transmitted from an electrode at one end of the resonator, then the radio frequency signal is converted into an acoustic wave signal of mechanical vibration at an interface of the piezoelectric material and this metal electrode through the inverse piezoelectric effect, the acoustic wave signal forms a resonant standing wave with a certain frequency in the sandwich structure of the first electrode, the piezoelectric material and the second electrode, the frequency of the radio frequency signal is equal to a resonance frequency of the resonator, the acoustic wave signal is transmitted to an electrode at the other end of the resonator, and the acoustic wave signal is converted into the radio frequency signal at an interface of the other metal electrode and the piezoelectric material through the piezoelectric effect. The resonator has a fixed resonance frequency, and when the frequency of the radio frequency signal is equal to the resonance frequency of the resonator, the conversion efficiency of the radio frequency signal→the acoustic wave signal→the radio frequency signal is high; when the frequency of the radio frequency signal is not equal to the resonance frequency of the resonator, the conversion efficiency of the radio frequency signal→the acoustic wave signal→the radio frequency signal is very low, and most of the radio frequency signals cannot be transmitted through the resonator, that is, the resonator functions as a filter to filter the radio frequency signal.

### SUMMARY

The present disclosure aims to solve at least one of the technical problems in the prior art and provides a bulk acoustic wave resonator, a fabrication method thereof, and an electronic device.

An embodiment of the present disclosure provides a bulk acoustic wave resonator, which includes a base substrate, a first electrode, a piezoelectric layer, and a second electrode, where the first electrode is on the base substrate, the second electrode is on a side of the first electrode away from the base substrate, the piezoelectric layer is between the first electrode and the second electrode, and orthographic projections of any two of the first electrode, the piezoelectric layer and the second electrode on the base substrate at least partially overlap each other;
where a temperature drift compensation layer is on a side of the piezoelectric layer close to the base substrate and/or a side of the piezoelectric layer away from the base substrate; and the temperature drift compensation layer is made of a material having a property of expanding with heat and contracting with cold, and is configured to suppress temperature drift of the bulk acoustic wave resonator.

The material of the temperature drift compensation layer is ZrW₂O₈, Zn₂GeO₄, HfW₂O₈, ZrMo₂O₈, HfMo₂O₈, ZrV₂O₇, HfV₂O₇, ZrV_{1.7}Mo_{0.3}O_{7+δ}, ZrV_{1.5}Mo_{0.5}O_{7+δ}, Cu₂V₂O₇, Cu₂₋ₓZnₓV₂O₇, Cu_{2-y}M_{y}V₂O₇, Cu_{1.5}Mg_{0.5}V₂O₇, Cu₂P₂O₇, Cu₂PVO₇, HfMgW₃O₁₂, HfMgMo₃O₁₂, ZrMgMo₃O₁₂, ZrMgW₃O₁₂, ZrMnMo₃O₁₂, HfMnMo₃O₁₂, AScY₂XO₁₂, TaVO₅, NbVO₅, Ag₂O, Th₂O(PO₄)₂, U₂O(PO₄)₂, Zr₂O(PO₄)₂, ScF₃, CaZrF₆, CaHfF₆, MgZrF₆, CaNbF₆, CaTiF₆, Zn(CN)₂, Cd(CN)₂, AgB(CN)₄, CuB(CN)₄, ScCo(CN)₆, Si(NCN)₂, Mn₃AN(A is Zn or Ga), GdInO3, PbTiO3, PbVO3, PbVO_{2.79}F_{0.21}, PbV₁₋ₓCrₓO₃, Bi_{0.5}Na_{0.5}VO₃, GeTe, LaCu₃Fe₄O₁₂, BiNiO₃, V₂OPO₄, Ca₂RuO₄, Sr₂IrO₄, Sr₂RhO₄, Ca₂MnO₄, Ca₂GeO₄, Ca₃Mn₂O₇, or Ga₂Ti₂O₇; and
for Cu₂₋ₓZnₓV₂O₇, x is 0.1 or 0.2; for Cu_{2-y}M_{y}V₂O₇, M is any one of Yb, Sm and Ce, and y is 0.05; and for AScY₂XO₁₂, A is Zr or Hf, Y is W or Mo, and X is V or P.

A thickness of the temperature drift compensation layer is in a range from 1 nm to 100 μm.

The temperature drift compensation layer has a hollow out pattern.

The temperature drift compensation layer is on the side of the piezoelectric layer close to the base substrate, and on a side of the first electrode away from the piezoelectric layer.

The temperature drift compensation layer is on the side of the piezoelectric layer away from the base substrate, and on a side of the second electrode away from the piezoelectric layer.

The first electrode includes a first sub-electrode and a second sub-electrode sequentially arranged in a direction away from the base substrate, and the temperature drift compensation layer is on the side of the piezoelectric layer close to the base substrate, and between the first sub-electrode and the second sub-electrode.

The first electrode includes a third sub-electrode and a fourth sub-electrode sequentially arranged in a direction away from the base substrate, and the temperature drift compensation layer is on the side of the piezoelectric layer close to the base substrate, and between the third sub-electrode and the fourth sub-electrode.

The base substrate has a first groove occupying a portion of the base substrate in a thickness direction of the base substrate; and an isolation layer is on a side, facing the first electrode, of an opening of the first groove.

The bulk acoustic wave resonator further includes an isolation layer between the base substrate and the first electrode; and a space is defined between the isolation layer and the base substrate.

The base substrate has a first cavity penetrating through the base substrate in a thickness direction of the base substrate; and an isolation layer is on a side of the base substrate close to the first electrode.

An embodiment of the present disclosure further provides a method of fabricating a bulk acoustic wave resonator, which includes: sequentially forming a first electrode, a piezoelectric layer and a second electrode on a base substrate, where orthographic projections of any two of the first electrode, the piezoelectric layer and the second electrode on the base substrate at least partially overlap each other; where the method further includes: forming a temperature drift compensation layer on a side of the piezoelectric layer close to the first base substrate and/or on a side of the piezoelectric layer away from the first base substrate; and the temperature drift compensation layer is made of a material having a property of expanding with heat and contracting with cold, and is configured to suppress temperature drift of the bulk acoustic wave resonator.

The material of the temperature drift compensation layer is ZrW₂O₈, Zn₂GeO₄, HfW₂O₈, ZrMo₂O₈, HfMo₂O₈, ZrV₂O₇, HfV₂O₇, ZrV_{1.7}Mo_{0.3}O_{7+δ}, ZrV_{1.5}Mo_{0.5}O_{7+δ}, Cu₂V₂O₇, Cu₂₋ₓZnₓV₂O₇, Cu_{2-y}M_{y}V₂O₇, Cu_{1.5}Mg_{0.5}V₂O₇, Cu₂P₂O₇, Cu₂PVO₇, HfMgW₃O₁₂, HfMgMo₃O₁₂, ZrMgMo₃O₁₂, ZrMgW₃O₁₂, ZrMnMo₃O₁₂, HfMnMo₃O₁₂, AScY₂XO₁₂, TaVO₅, NbVO₅, Ag₂O, Th₂O(PO₄)₂, U₂O(PO₄)₂, Zr₂O(PO₄)₂, ScF₃, CaZrF₆, CaHfF₆, MgZrF₆, CaNbF₆, CaTiF₆, Zn(CN)₂, Cd(CN)₂, AgB(CN)₄, CuB(CN)₄, ScCo(CN)₆, Si(NCN)₂, Mn₃AN(A is Zn or Ga), GdInO3, PbTiO3, PbVO3, PbVO_{2.79}F_{0.21}, PbV₁₋ₓCrₓO₃Bi_{0.5}Na_{0.5}VO₃, GeTe, LaCu₃Fe₄O₁₂, BiNiO₃, V₂OPO₄, Ca₂RuO₄, Sr₂IrO₄, Sr₂RhO₄, Ca₂MnO₄, Ca₂GeO₄, Ca₃Mn₂O₇, or Ga₂Ti₂O₇, and
for Cu₂₋ₓZnₓV₂O₇, x is 0.1 or 0.2; for Cu_{2-y}M_{y}V₂O₇, M is any one of Yb, Sm and Ce, and y is 0.05; and for AScY₂XO₁₂, A is Zr or Hf, Y is W or Mo, and X is V or P.

A thickness of the temperature drift compensation layer is in a range from 1 nm to 100 μm.

The temperature drift compensation layer has a hollow out pattern.

In the fabrication method, the forming the temperature drift compensation layer on the side of the piezoelectric layer close to the base substrate is prior to the forming the first electrode.

In the fabrication method, the forming the temperature drift compensation layer on the side of the piezoelectric layer away from the base substrate is subsequent to the forming the second electrode.

The forming the first electrode includes: sequentially forming a first sub-electrode and a second sub-electrode in a direction away from the base substrate; and
in the fabrication method, the forming the temperature drift compensation layer on the side of the piezoelectric layer close to the base substrate is prior to forming the first sub-electrode and subsequent to forming the second sub-electrode.

The forming the second electrode includes: sequentially forming a third sub-electrode and a fourth sub-electrode in a direction away from the base substrate; and
in the fabrication method, the forming the temperature drift compensation layer on the side of the piezoelectric layer away from the base substrate is prior to forming the third sub-electrode and subsequent to forming the fourth sub-electrode.

The fabrication method further includes: processing the base substrate to form a first groove occupying a portion of the base substrate in a thickness direction of the base substrate; and providing an isolation layer on a side, facing the first electrode, of an opening of the first groove.

The fabrication method further includes: forming an isolation layer prior to the forming the first electrode such that a space is defined between the isolation layer and the base substrate.

The fabrication method further includes: processing the base substrate to form a first cavity penetrating through the base substrate in a thickness direction of the base substrate; and forming an isolation layer on a side of the base substrate close to the first electrode.

An embodiment of the present disclosure provides an electronic device, which includes any one of the bulk acoustic wave resonators described above.

### BRIEF DESCRIPTION OF DRAWINGS

FIG. 1 is a schematic diagram illustrating a structure of a back etched bulk acoustic wave resonator.

FIG. 2 is a schematic diagram illustrating a structure of a film bulk acoustic wave resonator.

FIG. 3 is a schematic diagram illustrating a structure of another film bulk acoustic wave resonator.

FIG. 4 is a schematic diagram illustrating a structure of a solid mounted bulk acoustic wave resonator.

FIG. 5 is a schematic diagram illustrating a structure of a bulk acoustic wave resonator in a first example implemented in the present disclosure.

FIG. 6 is a flow chart illustrating how to fabricate the bulk acoustic wave resonator shown in FIG. 5.

FIG. 7 is a schematic diagram illustrating a structure of a bulk acoustic wave resonator in a second example implemented in the present disclosure.

FIG. 8 is a flow chart illustrating how to fabricate the bulk acoustic wave resonator shown in FIG. 7.

FIG. 9 is a schematic diagram illustrating a structure of a bulk acoustic wave resonator in a third example implemented in the present disclosure.

FIG. 10 is a schematic diagram illustrating a structure of a bulk acoustic wave resonator in a fourth example implemented in the present disclosure.

FIG. 11 is a flow chart illustrating how to fabricate the bulk acoustic wave resonator shown in FIG. 10.

FIG. 12 is a schematic diagram illustrating a structure of a bulk acoustic wave resonator in a fifth example implemented in the present disclosure.

FIG. 13 is a flow chart illustrating how to fabricate the bulk acoustic wave resonator shown in FIG. 12.

FIG. 14 is a schematic diagram illustrating a structure of a bulk acoustic wave resonator in a sixth example implemented in the present disclosure.

FIG. 15 is a schematic diagram illustrating a structure of a bulk acoustic wave resonator in a seventh example implemented in the present disclosure.

FIG. 16 is a flow chart illustrating how to fabricate the bulk acoustic wave resonator shown in FIG. 15.

FIG. 17 is a schematic diagram illustrating a structure of a bulk acoustic wave resonator in an eighth example implemented in the present disclosure.

FIG. 18 is a flow chart illustrating how to fabricate the bulk acoustic wave resonator shown in FIG. 17.

FIG. 19 is a schematic diagram illustrating a structure of a bulk acoustic wave resonator in a ninth example implemented in the present disclosure.

FIG. 20 is a schematic diagram illustrating a structure of a bulk acoustic wave resonator in a tenth example implemented in the present disclosure.

FIG. 21 is a flow chart illustrating how to fabricate the bulk acoustic wave resonator shown in FIG. 20.

FIG. 22 is a schematic diagram illustrating a structure of a bulk acoustic wave resonator in an eleventh example implemented in the present disclosure.

FIG. 23 is a schematic diagram illustrating a structure of a bulk acoustic wave resonator in a twelfth example implemented in the present disclosure.

FIG. 24 is a flow chart illustrating how to fabricate the bulk acoustic wave resonator shown in FIG. 23.

FIG. 25 is a schematic diagram illustrating a structure of a bulk acoustic wave resonator in a thirteenth example implemented in the present disclosure.

FIG. 26 is a schematic diagram illustrating a structure of a bulk acoustic wave resonator in a fourteenth example implemented in the present disclosure.

FIG. 27 is a schematic diagram illustrating a structure of a bulk acoustic wave resonator in a fifteenth example implemented in the present disclosure.

### DETAIL DESCRIPTION OF EMBODIMENTS

In order to make the technical solutions of the present disclosure better understood by one of ordinary skill in the art, the present disclosure will be further described in detail below with reference to the accompanying drawings and the specific implementations.

Unless defined otherwise, technical or scientific terms used in the present disclosure shall have the ordinary meaning as understood by one of ordinary skill in the art to which the present disclosure belongs. The words “first”, “second”, and the like used in the present disclosure are not intended to indicate any order, quantity, or importance, but rather serve to distinguish one element from another. Also, the word “a”, “an”, “the” or the like does not denote a limitation of quantity, but rather denotes the presence of at least one. The word “including”, “includes”, “comprising”, “comprises”, or the like means that the element or item preceding the word includes the element or item listed after the word and its equivalent, but does not exclude other elements or items. The word “connected”, “coupled” or the like is not restricted to physical or mechanical connections, but may include electrical connections, whether direct or indirect. The words “upper”, “lower”, “left”, “right”, and the like are used only to indicate relative positional relationships, and when the absolute position of the object being described is changed, the relative positional relationships may also be changed accordingly.

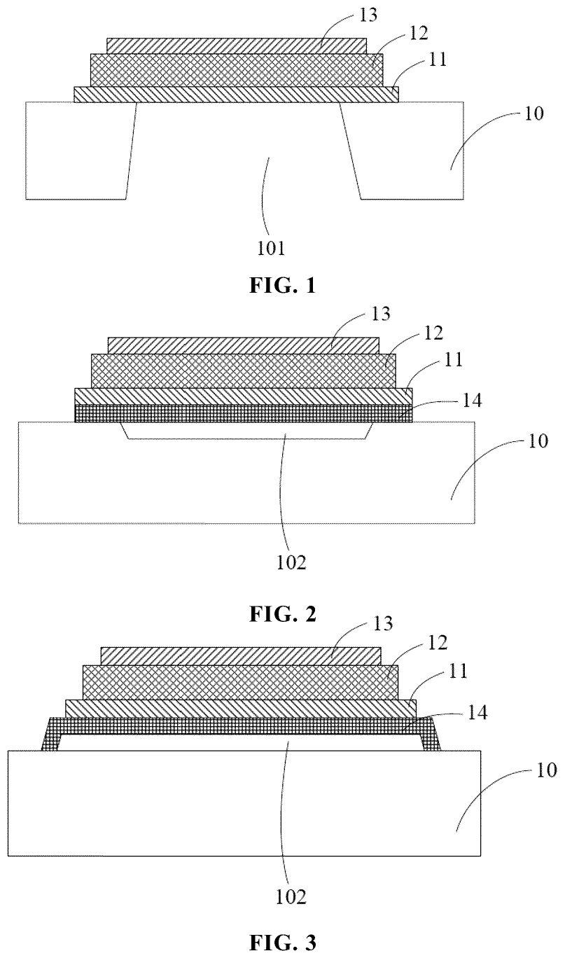

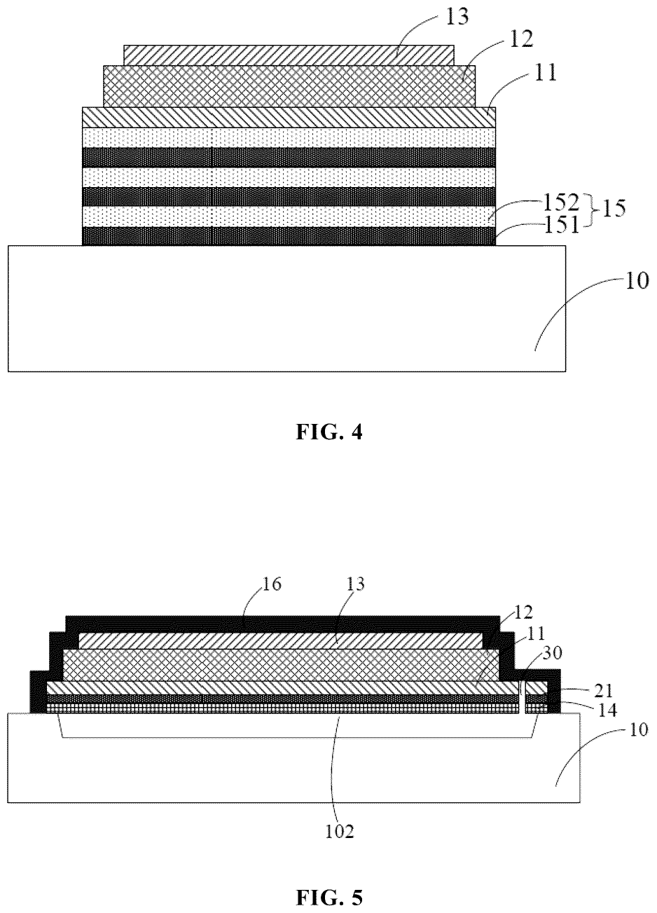

As shown in FIGS. 1 to 4, in order to reduce an insertion loss of the bulk acoustic wave resonator during a filtering process, it is required to limit the acoustic wave signal as much as possible in a piezoelectric layer 12 between a first electrode 11 and a second electrode 13, to prevent the acoustic wave signal from diffusing out, and therefore, an acoustic wave reflector is usually constructed on upper and lower surfaces of the resonator. The upper surface generally adopts an air medium with low acoustic impedance as a reflector, and according to the different acoustic reflectors on the lower surfaces, the bulk acoustic wave resonators are divided into three major classes: a back etched bulk acoustic wave resonator as shown in FIG. 1; a Film Bulk Acoustic wave Resonator (abbreviated as FBAR), as shown in FIGS. 2 and 3; and a Solid Mounted bulk acoustic wave Resonator (abbreviated as SMR), as shown in FIG. 4. In the FBAR, a first groove 102, which is formed by etching in a base substrate 10, is constructed under the first electrode as an air gap, and then the first electrode is supported by an isolation layer 14, as shown in FIG. 2. Alternatively, the first groove 102 is formed in the isolation layer 14 as an air gap, as shown in FIG. 3. In the SMR, an acoustic mirror structure 15, that is formed by alternately and repeatedly laminating high acoustic impedance layers 151 and low acoustic impedance layers 152, is constructed under the first electrode 11. In the back etched bulk acoustic wave resonator, by forming a cavity through deeply etching a back surface of the silicon substrate, a first cavity 101 formed in the base substrate 10 is constructed under the first electrode 11 as an air layer.

The inventor finds that, no matter in which one bulk acoustic wave resonator, the piezoelectric layer 12 is made of C-axis-oriented crystalline AlN, which has an increased in-plane lattice constant and a decreased out-of-plane lattice constant with an increase of temperature, so that a propagation speed of the acoustic wave decreases, and it can be known from the qualitative formula that the resonance frequency of the bulk acoustic wave resonator will decrease, that is, a temperature drift phenomenon will occur.

In view of the above technical problems, a temperature drift compensation layer is disposed on a side of the piezoelectric layer 12 close to the base substrate 10 and/or a side of the piezoelectric layer 12 away from the base substrate 10 for resisting temperature drift, and a material of the temperature drift compensation layer expands with heat and contracts with cold. Specifically, the temperature drift compensation layer can suppress the increase of the in-plane lattice constant of the film material of the piezoelectric layer 12 with the increase of temperature, and the suppression degree can be adjusted according to the specific material and a thickness of the temperature drift compensation layer, so that the out-of-plane lattice constant of the film material of the piezoelectric layer 12 can be decreased, increased, or unchanged with the increase of ambient temperature, that is, can be flexibly adjusted, and thus the bulk acoustic wave resonator with positive temperature coefficient, negative temperature coefficient or even a zero temperature coefficient can be obtained.

It should be noted that, where the temperature drift compensation layer is located on the side of the piezoelectric layer 12 close to the base substrate 10, the piezoelectric layer still is required to be electrically connected to the first electrode 11, and where the temperature drift compensation layer is located on the side of the piezoelectric layer 12 away from the base substrate 10, the piezoelectric layer still is required to be electrically connected to the second electrode 13.

In addition, since the back etched bulk acoustic wave resonator and the film bulk acoustic wave resonator are prone to temperature drift, the temperature drift compensation layer is mainly added to the back etched bulk acoustic wave resonator and the film bulk acoustic wave resonator. However, the temperature drift compensation layer may also be added to the solid mounted bulk acoustic wave resonator. The following description will be made only for some cases where the film bulk acoustic wave resonator shown in FIG. 2 is added with a temperature drift compensation layer. In order to provide a clearer description of the bulk acoustic wave resonator in the embodiments of the present disclosure, the temperature drift compensation layer on the side of the piezoelectric layer 12 close to the base substrate 10 is referred to as a first temperature drift compensation layer 21, and the temperature drift compensation layer on the side of the piezoelectric layer 12 away from the base substrate 10 is referred to as a second temperature drift compensation layer 22.

A first example is as follows: FIG. 5 is a schematic diagram illustrating a structure of a bulk acoustic wave resonator in the first example implemented in the present disclosure. As shown in FIG. 5, the bulk acoustic wave resonator includes a base substrate 10, and an isolation layer 14, a first temperature drift compensation layer 21, a first electrode 11, a piezoelectric layer 12, and a second electrode 13 sequentially disposed on the base substrate 10. The base substrate 10 has a first groove 102 occupying a portion of the base substrate 10 in a thickness direction of the base substrate 10, that is, an air gap is formed under the isolation layer 14. A release hole 30 penetrating through the first electrode 11, the first temperature drift compensation layer 21, and the isolation layer 14 serves to release a sacrificial layer formed in the first groove 102 in a process of fabricating the bulk acoustic wave resonator (details are described in the fabrication method).

With continued reference to FIG. 5, a radio frequency signal is transmitted from the upper left corner in FIG. 5, and then is converted into an acoustic wave signal through the inverse piezoelectric effect at an interface between the second electrode 13 and the piezoelectric layer 12; and then the acoustic wave signal longitudinally propagates in the piezoelectric layer 12, and is converted into a radio frequency signal through the piezoelectric effect when being transmitted to an interface between the first electrode 11 and the piezoelectric layer 12; and then the radio frequency signal is transmitted out. The air gap under the bulk acoustic wave resonator and the air layer above the bulk acoustic wave resonator act as acoustic reflectors, which serve to limit the acoustic signal in the resonator instead of being dissipated out, so that the insertion loss of the resonator can be reduced. The first temperature drift compensation layer 21 in the embodiment of the present disclosure is different from a general material, and a material of the temperature drift compensation layer has a property of contracting with heat and expanding with cold (that is, the material of the temperature drift compensation layer contracts when heated and expands when cooled). When the ambient temperature rises, an increase of the in-plane lattice constant of the material of the piezoelectric layer 12, which is connected to the first temperature drift compensation layer 21 through the first electrode 11, is suppressed, and a degree of the suppression can be adjusted by factors such as selection of different kinds of thin film materials of the temperature drift compensation layer, different thicknesses of the temperature drift compensation layer, and the like, so that the out-plane lattice constant of the piezoelectric layer 12 can be decreased, increased, or unchanged with the rise of the ambient temperature, that is, can be flexibly adjusted, and thus the bulk acoustic wave resonator with a positive temperature coefficient, a negative temperature coefficient, or even a zero temperature coefficient can be obtained.

In some examples, a material of the base substrate 10 is preferably glass, and may alternatively be selected from Si, sapphire, SiC, GaAs, GaN, InP, BN, ZnO, and the like, and a thickness of the base substrate 10 is in a range from 0.1 μm to 10 mm. A thickness of the air gap on the base substrate 10 is in a range from 0.1 μm to 50 μm.

In some examples, a material of the first electrode 11 is selected from metal materials. For example, the material of the first electrode 11 is a metal Mo, or may be selected from Cu, Al, Co, Ag, Ti, Pt, Ru, W, Au, or an alloy material formed by any combination of the above metals. A thickness of the first electrode 11 is about in a range from 1 nm to 10 μm.

In some examples, a material of the piezoelectric layer 12 is preferably hBN, and may also be selected from cBN and wBN. Alternatively, the material of the piezoelectric layer 12 may also be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, PVDF, and the like. The piezoelectric layer 12 in the present embodiment may be made of one of the piezoelectric materials described above, or may be a stack of the piezoelectric materials described above. A thickness of the piezoelectric layer 12 is in a range from 10 nm to 100 μm.

In some examples, a material of the second electrode 13 may be selected from Cu, Al, Mo, Co, Ag, Ti, Pt, Ru, W, Au, and alloys thereof. A thickness of the second electrode 13 is in a range from 1 nm to 10 μm.

In some examples, the isolation layer 14 serves to electrically isolate the air gap from the bulk acoustic wave resonator and provide a structural support for the bulk acoustic wave resonator, and is made of a material selected from insulation materials such as SiO₂, Si₃N₄, Al₂O₃, and a stack of combinations thereof. A thickness of the isolation layer 14 is in a range from 1 nm to 100 μm.

In some examples, the first temperature drift compensation layer 21 is a thin film made of a material having a property of contracting with heat and expanding with cold, and has the property of contracting with heat and expanding with cold. The material of the first temperature drift compensation layer 21 may be selected from ZrW₂O₈, Zn₂GeO₄, HfW₂O₈, ZrMo₂O₈, HfMo₂O₈, ZrV₂O₇, HfV₂O₇, ZrV_{1.7}Mo_{0.3}O_{7+δ}, ZrV_{1.5}Mo_{0.5}O_{7+δ}, Cu₂V₂O₇, Cu₂₋ₓZnₓV₂O₇ (x is 0.1 or 0.2), Cu_{2-y}M_{y}V₂O₇ (M is any one of Yb, Sm, and Ce, and y is 0.05), Cu_{1.5}Mg_{0.5}V₂O₇, Cu₂P₂O₇, Cu₂PVO₇, HfMgW₂O₁₂, HfMgMo₃O₁₂, ZrMgMo₃O₁₂, ZrMgW₃O₁₂, ZrMnMo₃O₁₂, HfMnMo₃O₁₂, AScY₂XO₁₂ (A is Zr or Hf, Y is W or Mo, and X is V or P), TaVO₅, NbVO₅, Ag₂O, Th₂O(PO₄)₂, U₂O(PO₄)₂, Zr₂O(PO₄)₂, ScF₃, CaZrF₆, CaHfF₆, MgZrF₆, CaNbF₆, CaTiF₆, Zn(CN)₂, Cd(CN)₂, AgB(CN)₄, CuB(CN)₄, ScCo(CN)₆, Si(NCN)₂, Mn₃AN(A is Zn or Ga), GdInO3, PbTiO3, PbVO3, PbVO_{2.79}F_{0.21}, PbV₁₋ₓCrₓO₃, Bi_{0.5}Na_{0.5}VO₃, GeTe, LaCu₃Fe₄O₁₂, BiNiO₃, V₂OPO₄, Ca₂RuO₄, Sr₂IrO₄, Sr₂RhO₄, Ca₂MnO₄, Ca₂GeO₄, Ca₃Mn₂O₇, and Ga₃Ti₂O₇. A thickness of the first temperature drift compensation layer 21 is in a range from 1 nm to 100 μm.

In some examples, referring to FIG. 5, an encapsulation layer 16 is provided on a side of the second electrode 13 away from the base substrate 10. A material of the encapsulation layer 16 is preferably an organic compound capable of blocking moisture and oxygen, such as polyimide, epoxy, or the like, or may be an inorganic material such as SiNₓ, Al₂O₃, or the like. The encapsulation layer 16 may be a single layer of one material or may be a stack of multiple materials.

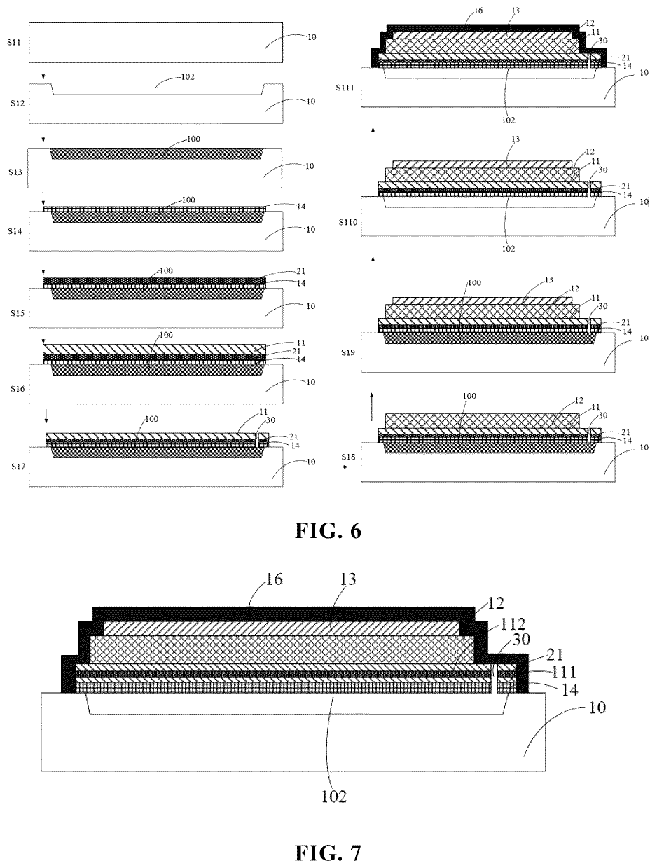

Next, a method of fabricating the bulk acoustic wave resonator in the first example will be described. FIG. 6 is a flow chart illustrating how to fabricate the bulk acoustic wave resonator shown in FIG. 5. As shown in FIG. 6, the fabrication method specifically includes the following steps S11 to S111.

At the step S11, the base substrate 10 is provided.

In some examples, taking the base substrate 10 being a mono-crystalline silicon substrate as an example, the step S11 may specifically include: firstly, performing ultrasonic cleaning with deionized water on the mono-crystalline silicon substrate; then putting the mono-crystalline silicon substrate into a mixed solution of H₂SO₄:H₂O=3:1, and heating the mixed solution to 250° C. and washing the mono-crystalline silicon substrate for 15 minutes; then putting the mono-crystalline silicon substrate into deionized water for ultrasonic cleaning; then putting the mono-crystalline silicon substrate into a mixed solution of NH₄OH:H₂O=1:6, and heating the mixed solution to 80° C. and washing the mono-crystalline silicon substrate for 15 minutes; taking out the mono-crystalline silicon substrate and putting the mono-crystalline silicon substrate into deionized water for washing; next, putting the mono-crystalline silicon substrate into a mixed solution of HCl:H₂O₂:H₂O=1:1:5, heating the mixed solution to 85° C. and washing the mono-crystalline silicon substrate for 15 minutes, and taking out the mono-crystalline silicon substrate and putting the mono-crystalline silicon substrate into diluted hydrofluoric acid of HF:H₂O=1:20, and rinsing the mono-crystalline silicon substrate for 10 seconds, to remove an oxide layer on the surface of the mono-crystalline silicon substrate; and finally, putting the mono-crystalline silicon substrate into deionized water for 20 minutes of ultrasonic cleaning, and drying the mono-crystalline silicon substrate with an air knife, thereby finishing the whole cleaning process of the base substrate 10.

At the step S12, the first groove 102 is formed in the base substrate 10.

In some examples, the step S12 may specifically include: fabricating a mask pattern on the base substrate 10, and performing a photolithography process including photoresist coating (or spraying), pre-baking, exposing, developing, and post-baking. Then, an etching process is performed to form the first groove 102, and the etching process may be wet etching or dry etching, preferably wet etching. Finally, a photoresist stripping process is performed, thereby finishing the fabrication of the first groove 102.

At the step S13, a sacrificial layer is formed in the first groove 102.

In some examples, a material of the sacrificial layer may be a loose amorphous silicon dioxide doped with boron and phosphorus. The step S13 may specifically include: forming a slurry containing the loose amorphous silicon dioxide doped with boron and phosphorus by any one of Plasma Enhanced Chemical Vapor Deposition (PECVD), Sub-Atmospheric Pressure Chemical Vapor Deposition (SACVD), and screen printing; performing thermal annealing at 700° C. to 900° C. for 15 to 30 minutes in a vacuum chamber, so that a film of the loose amorphous silicon dioxide doped with boron and phosphorus is liquefied, and the resultant liquid flows and completely fills up the first groove 102, to level the first groove 102; and then cooling and curing the liquid. Finally, chemical mechanical polishing is performed, the base substrate 10 is pressed against a rough polishing pad by a polishing head, a surface of the base substrate 10 is planarized through a certain time of coupling effects of polishing solution corrosion, particle friction, polishing pad friction, and the like, until a surface of the material overflowing from the surface of the first groove 102 is polished to have a height equal to a height of the surface of the base substrate 10.

At the step S14, the isolation layer 14 is formed on the base substrate 10.

In some examples, the step S14 may specifically include: fabricating an isolation layer film on the base substrate 10. Firstly, an electrical insulation material is deposited by radio frequency magnetron sputtering, Pulsed Laser Sputtering (PLD), Atomic Layer Deposition (ALD), or Plasma Chemical Vapor Deposition (PCVD). A photolithography process is performed on the isolation layer film, to form a pattern including the isolation layer 14, and the photolithography process includes photoresist coating (or spraying), pre-baking, exposing, developing, and post-baking. Finally, etching is performed, preferably a wet etching process is performed, and alternatively a dry etching process may be selected.

At the step S15, the first temperature drift compensation layer 21 is formed on a side of the isolation layer 14 away from the base substrate 10.

In some examples, the step S15 may specifically include: firstly depositing a temperature drift compensation layer film preferably by radio frequency magnetron sputtering, and alternatively by Pulsed Laser Deposition (PLD), Molecular Beam Epitaxy (MBE), Metal Organic Chemical Vapor Deposition (MOCVD), Plasma Enhanced Chemical Vapor Deposition (PECVD), sol-gel method (firstly coating a slurry containing a material of the temperature drift compensation layer, and then performing heat sintering), thermal evaporation, electron beam evaporation, or the like. Then a photolithography process is performed on the temperature drift compensation layer film, where the photolithography process includes photoresist coating (or spraying), pre-baking, exposing, developing, and post-baking. Finally, etching is performed, preferably a wet etching process is performed, and alternatively a dry etching process may be selected, to form a pattern of the first temperature drift compensation layer 21.

At the step S16, the first electrode 11 is formed on a side of the first temperature drift compensation layer 21 away from the base substrate 10.

In some examples, in a case where the first electrode 11 is made of a metal material, the step S16 may include: depositing a first metal film on a side of the first temperature drift compensation layer 21 away from the base substrate 10 preferably by direct current magnetron sputtering (radio frequency magnetron sputtering is also possible), alternatively by Pulsed Laser Deposition (PLD), Molecular Beam Epitaxy (MBE), thermal evaporation, electron beam evaporation, or the like, or by attaching a copper foil. Then, a photolithography process is performed on the first metal film, where the photolithography process includes photoresist coating (or spraying), pre-baking, exposing, developing, and post-baking. Next, an etching process is performed to form a pattern including the first electrode 11, where the etching process is preferably a wet etching process, and alternatively, a dry etching process may be selected. Finally, a photoresist stripping process is performed, thereby completing the fabrication of the first electrode 11.

At the step S17, the release hole 30 penetrating through the first electrode 11, the isolation layer 14, and the first temperature drift compensation layer 21 is formed.

In some examples, the step S17 may specifically include: firstly performing a photolithography process on a side of the first electrode 11 away from the base substrate 10, including photoresist coating (or spraying), pre-baking, exposing, developing, and post-baking, to expose a position where the release hole is located. Then, a dry etching process is performed to etch the first electrode 11, then new etching gas is introduced to etch the first temperature drift compensation layer 21, then the etching gas is replaced again to etch the isolation layer 14, until the sacrificial layer is exposed, and finally a photoresist stripping process is performed, thereby forming the release hole 30.

At the step S18, the piezoelectric layer 12 is formed on a side of the first electrode 11 away from the base substrate 10.

In some examples, taking the piezoelectric layer 12 being an AlN single-layer structure as an example, the step S18 may include: forming a piezoelectric material layer on the side of the first electrode 11 away from the base substrate 10, and conducting an oriented growth of the piezoelectric material layer, where the piezoelectric material layer is preferably formed through radio frequency magnetron sputtering (or direct current magnetron sputtering), and for the AlN piezoelectric material, Al is selected as a target material, and by controlling gas pressure and temperature of Ar and N₂ during deposition, and time and temperature during post-annealing, a C-axis oriented AlN piezoelectric material layer is formed, and preferably, the growth orientation is (001). The deposition manner of the piezoelectric material layer may be selected from Pulsed Laser Deposition (PLD), Molecular Beam Epitaxy (MBE), Metal Organic Chemical Vapor Deposition (MOCVD), Plasma Enhanced Chemical Vapor Deposition (PECVD), and the like. Next, a photolithography process, including photoresist coating (or spraying), pre-baking, exposing, developing, and post-baking, is performed on the piezoelectric material layer. Etching is then performed to form a pattern including the piezoelectric layer 12, preferably a wet etching process is performed, and alternatively a dry etching process may be selected. Finally, a photoresist stripping process is performed, thereby completing the fabrication of the piezoelectric layer 12.

At the step S19, the second electrode 13 is formed on a side of the piezoelectric layer 12 away from the first electrode 11.

In some examples, in a case where the second electrode 13 is made of a metal material, the step S19 may specifically include: firstly depositing a third metal film on the side of the piezoelectric layer 12 away from the first electrode 11 preferably by direct current magnetron sputtering (radio frequency magnetron sputtering is also possible), and alternatively by Pulsed Laser Deposition (PLD), Molecular Beam Epitaxy (MBE), thermal evaporation, electron beam evaporation, or the like. Next, a photolithography process is performed on the third metal film, where the photolithography process includes photoresist coating (or spraying), pre-baking, exposing, developing, and post-baking. Thereafter, etching is performed to form a pattern including the second electrode 13. The etching process is preferably a wet etching process, and alternatively, a dry etching process may be selected. Finally, a photoresist stripping process is performed, thereby completing the fabrication of the second electrode 13.

At the step S110, the sacrificial layer is removed.

In some examples, the step S110 may include: etching the sacrificial layer, preferably through a wet etching process. A mixed etching solution of hydrofluoric acid, dilute nitric acid and deionized water is used to perform an immersion etching process (an etching temperature may be properly increased for increasing the wet etching rate) on the sacrificial layer for a long enough time, to ensure that the material of silicon dioxide doped with boron and phosphorus filled in the first groove 102 is completely dissolved. Finally, the first groove 102 is ultrasonically cleaned with deionized water for many times, and then dried, to form the first groove 102.

At the step S111, the encapsulation layer 16 is formed on a side of the second electrode 13 away from the base substrate 10.

In some examples, taking the encapsulation layer 16 made of an organic compound material as an example, the step S111 may specifically include: firstly coating an organic material liquid, which may specifically be selected from spin coating, spraying, inkjet printing, transferring, and the like; and then heating and curing the organic material liquid, to form a pattern of the encapsulation layer 16.

At this point, the fabrication of the bulk acoustic wave resonator is completed. Alternatively, if a plurality of bulk acoustic wave resonators are simultaneously fabricated, the fabrication method provided by the embodiment of the present disclosure may further include a step of device cutting.

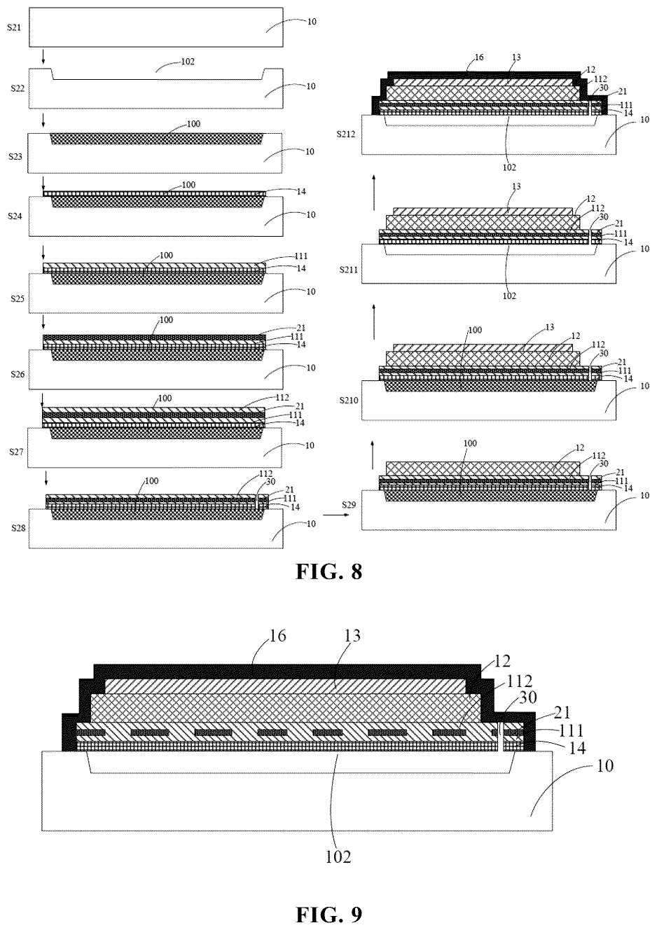

A second example is as follows: FIG. 7 is a schematic diagram illustrating a structure of a bulk acoustic wave resonator in the second example implemented in the present disclosure. As shown in FIG. 7, the bulk acoustic wave resonator includes a base substrate 10, and an isolation layer 14, a first temperature drift compensation layer 21, a first electrode 11, a piezoelectric layer 12, and a second electrode 13 disposed on the base substrate 10. The first electrode 11 includes a first sub-electrode 111 and a second sub-electrode 112, and in the bulk acoustic wave resonator, the isolation layer 14, the first sub-electrode 111, the first temperature drift compensation layer 21, the second sub-electrode 112, the piezoelectric layer 12, and the second electrode 13 are sequentially disposed in a direction away from the base substrate 10. The base substrate base 10 has a first groove 102 occupying a portion of the base substrate base 10 in a thickness direction of the base substrate 10, that is, an air gap is formed under the isolation layer 14. A release hole 30 penetrating through the first sub-electrode 111, the second sub-electrode 112, the first temperature drift compensation layer 21, and the isolation layer 14 serves to release a sacrificial layer formed in the first groove 102 in a process of fabricating the bulk acoustic wave resonator (details are described in the fabrication method).

With continued reference to FIG. 7, a radio frequency signal is transmitted from the upper left corner in FIG. 7, and then is converted into an acoustic wave signal through the inverse piezoelectric effect at an interface between the second electrode 13 and the piezoelectric layer 12; and then the acoustic wave signal longitudinally propagates in the piezoelectric layer 12, and is converted into a radio frequency signal through the piezoelectric effect when being transmitted to an interface between the second sub-electrode 112 and the piezoelectric layer 12; and then the radio frequency signal is transmitted out. The air gap under the bulk acoustic wave resonator and the air layer above the bulk acoustic wave resonator act as acoustic reflectors, which serve to limit the acoustic signal in the resonator instead of being dissipated out, so that the insertion loss of the resonator can be reduced. The first temperature drift compensation layer 21 in the embodiment of the present disclosure is different from a general material, and a material of the temperature drift compensation layer has a property of contracting with heat and expanding with cold. When the ambient temperature rises, an increase of the in-plane lattice constant of the material of the piezoelectric layer 12, which is connected to the first temperature drift compensation layer 21 through the first electrode 11, is suppressed, and a degree of the suppression can be adjusted by factors such as selection of different kinds of thin film materials of the temperature drift compensation layer, different thicknesses of the temperature drift compensation layer, and the like, so that the out-plane lattice constant of the piezoelectric layer 12 can be decreased, increased, or unchanged with the rise of the ambient temperature, that is, can be flexibly adjusted, and thus the bulk acoustic wave resonator with a positive temperature coefficient, a negative temperature coefficient, or even a zero temperature coefficient can be obtained.

In some examples, a material of the base substrate 10 is preferably glass, and may alternatively be selected from Si, sapphire, SiC, GaAs, GaN, InP, BN, ZnO, and the like, and a thickness of the base substrate 10 is in a range from 0.1 μm to 10 mm. A thickness of the air gap on the base substrate 10 is in a range from 0.1 μm to 50 μm.

In some examples, materials of the first sub-electrode 111 and the second sub-electrode 112 are selected from metal materials. For example, the materials of the first sub-electrode 111 and the second sub-electrode 112 are a metal Mo, or may be selected from Cu, Al, Co, Ag, Ti, Pt, Ru, W, Au, or an alloy material formed by any combination of the above metals. A thickness of the first electrode 11 composed of the first sub-electrode 111 and the second sub-electrode 112 is about in a range from 1 nm to 10 μm.

In some examples, a material of the piezoelectric layer 12 is preferably hBN, and may also be selected from cBN and wBN. Alternatively, the material of the piezoelectric layer 12 may also be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, PVDF, and the like. The piezoelectric layer 12 in the present embodiment may be made of one of the piezoelectric materials described above, or may be a stack of the piezoelectric materials described above. A thickness of the piezoelectric layer 12 is in a range from 10 nm to 100 μm.

In some examples, a material of the second electrode 13 may be selected from Cu, Al, Mo, Co, Ag, Ti, Pt, Ru, W, Au, and alloys thereof. A thickness of the second electrode 13 is in a range from 1 nm to 10 μm.

In some examples, the isolation layer 14 serves to electrically isolate the air gap from the bulk acoustic wave resonator and provide a structural support for the bulk acoustic wave resonator, and is made of a material selected from insulation materials such as SiO₂, Si₃N₄, Al₂O₃, and a stack of combinations thereof. A thickness of the isolation layer 14 is in a range from 1 nm to 100 μm.

In some examples, the first temperature drift compensation layer 21 is a thin film made of a material having a property of contracting with heat and expanding with cold, and has the property of contracting with heat and expanding with cold. The material of the first temperature drift compensation layer 21 may be selected from ZrW₂O₈, Zn₂GeO₄, HfW₂O₈, ZrMo₂O₈, HfMo₂O₈, ZrV₂O₇, HfV₂O₇, ZrV_{1.7}Mo_{0.3}O_{7+δ}, ZrV_{1.5}Mo_{0.5}O_{7+δ}, Cu₂V₂O₇, Cu₂₋ₓZnₓV₂O₇ (x is 0.1 or 0.2), Cu_{2-y}M_{y}V₂O₇ (M is any one of Yb, Sm, and Ce, and y is 0.05), Cu_{1.5}Mg_{0.5}V₂O₇, Cu₂P₂O₇, Cu₂PVO₇, HfMgW₂O₁₂, HfMgMo₃O₁₂, ZrMgMo₃O₁₂, ZrMgW₃O₁₂, ZrMnMo₃O₁₂, HfMnMo₃O₁₂, AScY₂XO₁₂ (A is Zr or Hf, Y is W or Mo, and X is V or P), TaVO₅, NbVO₅, Ag₂O, Th₂O(PO₄)₂, U₂O(PO₄)₂, Zr₂O(PO₄)₂, ScF₃, CaZrF₆, CaHfF₆, MgZrF₆, CaNbF₆, CaTiF₆, Zn(CN)₂, Cd(CN)₂, AgB(CN)₄, CuB(CN)₄, ScCo(CN)₆, Si(NCN)₂, Mn₃AN(A is Zn or Ga), GdInO3, PbTiO3, PbVO3, PbVO_{2.79}F_{0.21}, PbV₁₋ₓCrₓO₃, Bi_{0.5}Na_{0.5}VO₃, GeTe, LaCu₃Fe₄O₁₂, BiNiO₃, V₂OPO₄, Ca₂RuO₄, Sr₂IrO₄, Sr₂RhO₄, Ca₂MnO₄, Ca₂GeO₄, Ca₃Mn₂O₇, and Gas Ti₂O₇. A thickness of the first temperature drift compensation layer 21 is in a range from 1 nm to 100 μm.

In some examples, referring to FIG. 7, an encapsulation layer 16 is provided on a side of the second electrode 13 away from the base substrate 10. A material of the encapsulation layer 16 is preferably an organic compound capable of blocking moisture and oxygen, such as polyimide, epoxy, or the like, or may be an inorganic material such as SiNₓ, Al₂O₃, or the like. The encapsulation layer 16 may be a single layer of one material or may be a stack of multiple materials.

Next, a method of fabricating the bulk acoustic wave resonator in the second example will be described. FIG. 8 is a flow chart illustrating how to fabricate the bulk acoustic wave resonator shown in FIG. 7. As shown in FIG. 8, the fabrication method specifically includes the following steps S21 to S212.

At the step S21, the base substrate 10 is provided.

In some examples, taking the base substrate 10 being a mono-crystalline silicon substrate as an example, the step S21 may specifically include: firstly, performing ultrasonic cleaning with deionized water on the mono-crystalline silicon substrate; then putting the mono-crystalline silicon substrate into a mixed solution of H₂SO₄:H₂O=3:1, and heating the mixed solution to 250° C. and washing the mono-crystalline silicon substrate for 15 minutes; then putting the mono-crystalline silicon substrate into deionized water for ultrasonic cleaning; then putting the mono-crystalline silicon substrate into a mixed solution of NH₄OH:H₂O=1:6, and heating the mixed solution to 80° C. and washing the mono-crystalline silicon substrate for 15 minutes; taking out the mono-crystalline silicon substrate and putting the mono-crystalline silicon substrate into deionized water for washing; next, putting the mono-crystalline silicon substrate into a mixed solution of HCl:H₂O₂:H₂O=1:1:5, heating the mixed solution to 85° C. and washing the mono-crystalline silicon substrate for 15 minutes, and taking out the mono-crystalline silicon substrate and putting the mono-crystalline silicon substrate into diluted hydrofluoric acid of HF:H₂O=1:20, and rinsing the mono-crystalline silicon substrate for 10 seconds, to remove an oxide layer on the surface of the mono-crystalline silicon substrate; and finally, putting the mono-crystalline silicon substrate into deionized water for 20 minutes of ultrasonic cleaning, and drying the mono-crystalline silicon substrate with an air knife, thereby finishing the whole cleaning process of the base substrate 10.

At the step S22, the first groove 102 is formed in the base substrate 10.

In some examples, the step S22 may specifically include: fabricating a mask pattern on the base substrate 10, and performing a photolithography process including photoresist coating (or spraying), pre-baking, exposing, developing, and post-baking. Then, an etching process is performed to form the first groove 102, and the etching process may be wet etching or dry etching, preferably wet etching. Finally, a photoresist stripping process is performed, thereby finishing the fabrication of the first groove 102.

At the step S23, a sacrificial layer is formed in the first groove 102.

In some examples, a material of the sacrificial layer may be a loose amorphous silicon dioxide doped with boron and phosphorus. The step S23 may specifically include: forming a slurry containing the loose amorphous silicon dioxide doped with boron and phosphorus by any one of Plasma Enhanced Chemical Vapor Deposition (PECVD), Sub-Atmospheric Pressure Chemical Vapor Deposition (SACVD), and screen printing; performing thermal annealing at 700° C. to 900° C. for 15 to 30 minutes in a vacuum chamber, so that a film of the loose amorphous silicon dioxide doped with boron and phosphorus is liquefied, and the resultant liquid flows and completely fills up the first groove 102, to level the first groove 102; and then cooling and curing the liquid. Finally, chemical mechanical polishing is performed, the base substrate 10 is pressed against a rough polishing pad by a polishing head, a surface of the base substrate 10 is planarized through a certain time of coupling effects of polishing solution corrosion, particle friction, polishing pad friction, and the like, until a surface of the material overflowing from the surface of the first groove 102 is polished to have a height equal to a height of the surface of the base substrate 10.

At the step S24, the isolation layer 14 is formed on the base substrate 10.

In some examples, the step S24 may specifically include: fabricating an isolation layer film on the base substrate 10. Firstly, an electrical insulation material is deposited by radio frequency magnetron sputtering, Pulsed Laser Sputtering (PLD), Atomic Layer Deposition (ALD), or Plasma Chemical Vapor Deposition (PCVD). A photolithography process is performed on the isolation layer film, to form a pattern including the isolation layer 14, and the photolithography process includes photoresist coating (or spraying), pre-baking, exposing, developing, and post-baking. Finally, etching is performed, preferably a wet etching process is performed, and alternatively a dry etching process may be selected.

At the step S25, the first sub-electrode 111 is formed on a side of the isolation layer 14 away from the base substrate 10.

In some examples, in a case where the first electrode 11 is made of a metal material, the step S25 may include: depositing a first metal film on the side of the isolation layer 14 away from the base substrate 10 preferably by direct current magnetron sputtering (radio frequency magnetron sputtering is also possible), and alternatively by Pulsed Laser Deposition (PLD), Molecular Beam Epitaxy (MBE), thermal evaporation, electron beam evaporation, or the like, or by attaching a copper foil. Then, a photolithography process is performed on the first metal film, where the photolithography process includes photoresist coating (or spraying), pre-baking, exposing, developing, and post-baking. Next, an etching process is performed to form a pattern including the first sub-electrode 111, where the etching process is preferably a wet etching process, and alternatively, a dry etching process may be selected. Finally, a photoresist stripping process is performed, thereby completing the fabrication of the first sub-electrode 111.

At the step S26, the first temperature drift compensation layer 21 is formed on a side of the first sub-electrode 111 away from the base substrate 10.

In some examples, the step S26 may specifically include: firstly depositing a temperature drift compensation layer film preferably by radio frequency magnetron sputtering, and alternatively by Pulsed Laser Deposition (PLD), Molecular Beam Epitaxy (MBE), Metal Organic Chemical Vapor Deposition (MOCVD), Plasma Enhanced Chemical Vapor Deposition (PECVD), sol-gel method (firstly coating a slurry containing a material of the temperature drift compensation layer, and then performing heat sintering), thermal evaporation, electron beam evaporation, or the like. Then a photolithography process is performed on the temperature drift compensation layer film, where the photolithography process includes photoresist coating (or spraying), pre-baking, exposing, developing, and post-baking. Finally, etching is performed, preferably a wet etching process is performed, and alternatively a dry etching process may be selected, to form a pattern of the first temperature drift compensation layer 21.

At the step S27, the second sub-electrode 112 is formed on a side of the first temperature drift compensation layer 21 away from the base substrate 10.

In some examples, in a case where the second sub-electrode 112 is made of a metal material, the step S27 may include: depositing a second metal film on the side of the first temperature drift compensation layer 21 away from the base substrate 10, preferably by direct current magnetron sputtering (radio frequency magnetron sputtering is also possible), alternatively by Pulsed Laser Deposition (PLD), Molecular Beam Epitaxy (MBE), thermal evaporation, electron beam evaporation, or the like, or by attaching a copper foil. Then, a photolithography process is performed on the second metal film, where the photolithography process includes photoresist coating (or spraying), pre-baking, exposing, developing, and post-baking. Next, an etching process is performed to form a pattern including the second sub-electrode 112, where the etching process is preferably a wet etching process, and alternatively, a dry etching process may be selected. Finally, a photoresist stripping process is performed, thereby completing the fabrication of the second sub-electrode 112.

At the step S28, the release hole 30 is formed to penetrate through the first sub-electrode 111, the second sub-electrode 112, the isolation layer 14, and the first temperature drift compensation layer 21.

In some examples, the step S27 may specifically include: firstly performing a photolithography process on a side of the second sub-electrode 112 away from the base substrate 10, including photoresist coating (or spraying), pre-baking, exposing, developing, and post-baking, to expose a position where the release hole is located. Then, a dry etching process is performed to etch the second sub-electrode 112, then etching gas is replaced to etch the first temperature drift compensation layer 21, then the etching gas is replaced again to etch the first sub-electrode 111, then the etching gas is replaced again to etch the isolation layer 14, until the sacrificial layer is exposed, and finally a photoresist stripping process is performed, thereby forming the release hole 30.

At the step S29, the piezoelectric layer 12 is formed on a side of the first electrode 11 away from the base substrate 10.

In some examples, taking the piezoelectric layer 12 being an AlN single-layer structure as an example, the step S29 may include: forming a piezoelectric material layer on the side of the first electrode 11 away from the base substrate 10, and conducting an oriented growth of the piezoelectric material layer, where the piezoelectric material layer is preferably formed through radio frequency magnetron sputtering (or direct current magnetron sputtering), and for the AlN piezoelectric material, a target material is Al, and by controlling gas pressure and temperature of Ar and N₂ during deposition and post-annealing time and temperature, a C-axis oriented AlN piezoelectric material layer is formed, and preferably, the growth orientation is (001). The piezoelectric material layer may be formed by Pulsed Laser Deposition (PLD), Molecular Beam Epitaxy (MBE), Metal Organic Chemical Vapor Deposition (MOCVD), Plasma Enhanced Chemical Vapor Deposition (PECVD), or the like. Next, a photolithography process, including photoresist coating (or spraying), pre-baking, exposing, developing, and post-baking, is performed on the piezoelectric material layer. Etching is then performed to form a pattern including the piezoelectric layer 12, preferably a wet etching process is performed, and alternatively, a dry etching process may be selected. Finally, a photoresist stripping process is performed, thereby completing the fabrication of the piezoelectric layer 12.

At the step S210, the second electrode 13 is formed on a side of the piezoelectric layer 12 away from the first electrode 11.

In some examples, in a case where the second electrode 13 is made of a metal material, the step S210 may specifically include: firstly depositing a third metal film on the side of the piezoelectric layer 12 away from the first electrode 11 preferably by direct current magnetron sputtering (radio frequency magnetron sputtering is also possible), and alternatively by Pulsed Laser Deposition (PLD), Molecular Beam Epitaxy (MBE), thermal evaporation, electron beam evaporation, or the like. Next, a photolithography process is performed on the third metal film, where the photolithography process includes photoresist coating (or spraying), pre-baking, exposing, developing, and post-baking. Thereafter, an etching process is performed to form a pattern including the second electrode 13. The etching process is preferably a wet etching process. Alternatively, a dry etching process may be selected. Finally, a photoresist stripping process is performed, thereby completing the fabrication of the second electrode 13.

At the step S211, the sacrificial layer is removed.

In some examples, the step S211 may include: etching the sacrificial layer, preferably through a wet etching process. A mixed etching solution of hydrofluoric acid, dilute nitric acid and deionized water is used to perform an immersion etching process (an etching temperature may be properly increased for increasing the wet etching rate) on the sacrificial layer for a long enough time, to ensure that the material of silicon dioxide doped with boron and phosphorus filled in the first groove 102 is completely dissolved. Finally, the first groove 102 is ultrasonically cleaned with deionized water for many times, and then dried, to form the first groove 102.

At the step S212, forming the encapsulation layer 16 on a side of the second electrode 13 away from the base substrate 10.

In some examples, taking the encapsulation layer 16 made of an organic compound material as an example, the step S212 may specifically include: firstly coating an organic material liquid, which may specifically be selected from spin coating, spraying, inkjet printing, transferring, and the like; and then heating and curing the organic material liquid, to form a pattern of the encapsulation layer 16.

At this point, the fabrication of the bulk acoustic wave resonator is completed. Alternatively, if a plurality of bulk acoustic wave resonators are simultaneously fabricated, the fabrication method provided by the embodiment of the present disclosure may further include a step of device cutting.

A third example is as follows: FIG. 9 is a schematic diagram illustrating a structure of a bulk acoustic wave resonator in a third example implemented in the present disclosure. As shown in FIG. 9, the structure of the bulk acoustic wave resonator in this example is substantially the same as that of the bulk acoustic wave resonator in the second example, except that the first temperature drift compensation layer 21 has a hollow out pattern in this example. That is, the first temperature drift compensation layer 21 has through holes extending in the thickness direction thereof, and in this case, the first sub-electrode 111 and the second sub-electrode 112 of the first electrode 11 may be electrically connected together by the through holes penetrating through the first temperature drift compensation layer 21, so that the resistance of the first electrode 11 is reduced, and the in-band insertion loss of the bulk acoustic wave resonator is reduced. The same structures as in the second example may be adopted for the remaining structures in the bulk acoustic wave resonator, and therefore, the details are not repeated herein.

The method of fabricating the bulk acoustic wave resonator in the third example may be the same as the fabrication method in the second example, except that during forming the first temperature drift compensation layer 21, the through holes extending in the thickness direction thereof are formed. That is, the hollow out pattern is formed. The remaining steps are the same as those in the second example, and therefore, the details are not repeated herein.

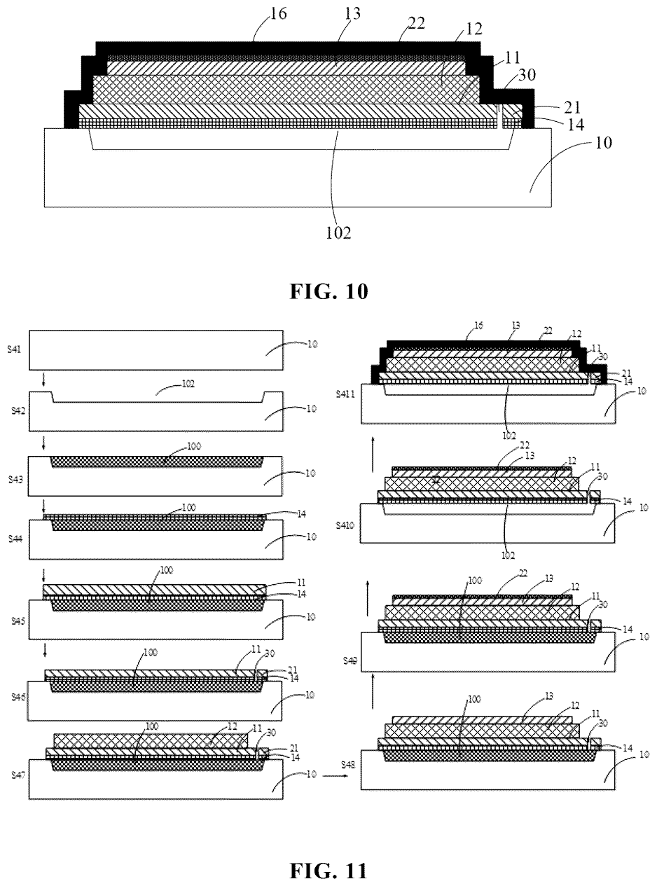

A fourth example is as follows: FIG. 10 is a schematic diagram illustrating a structure of a bulk acoustic wave resonator in a fourth example implemented in the present disclosure. As shown in FIG. 10, the bulk acoustic wave resonator includes a base substrate 10, and an isolation layer 14, a first electrode 11, a piezoelectric layer 12, a second electrode 13, and a second temperature drift compensation layer 22 sequentially disposed on the base substrate 10. The base substrate 10 has a first groove 102 occupying a portion of the base substrate 10 in a thickness direction of the base substrate 10, that is, an air gap is formed under the isolation layer 14. A release hole 30 penetrating through the first electrode 11 and the isolation layer 14 serves to release a sacrificial layer formed in the first groove 102 in a process of fabricating the bulk acoustic wave resonator (details are described in the fabrication method).

With continued reference to FIG. 10, a radio frequency signal is transmitted from the upper left corner in FIG. 10, and then is converted into an acoustic wave signal through the inverse piezoelectric effect at an interface between the second electrode 13 and the piezoelectric layer 12; and then the acoustic wave signal longitudinally propagates in the piezoelectric layer 12, and is converted into a radio frequency signal through the piezoelectric effect when being transmitted to an interface between the first electrode 11 and the piezoelectric layer 12; and then the radio frequency signal is transmitted out. The air gap under the bulk acoustic wave resonator and the air layer above the bulk acoustic wave resonator act as acoustic reflectors, which serve to limit the acoustic signal in the resonator instead of being dissipated out, so that the insertion loss of the resonator can be reduced. The second temperature drift compensation layer 22 in the embodiment of the present disclosure is different from a general material, and a material of the second temperature drift compensation layer 22 has a property of contracting with heat and expanding with cold. When the ambient temperature rises, an increase of the in-plane lattice constant of the material of the piezoelectric layer 12, which is connected to the second temperature drift compensation layer 22 through the second electrode 13, is suppressed, and a degree of the suppression can be adjusted by factors such as selection of different kinds of thin film materials of the temperature drift compensation layer, different thicknesses of the temperature drift compensation layer, and the like, so that the out-plane lattice constant of the piezoelectric layer 12 can be decreased, increased, or unchanged with the rise of the ambient temperature, that is, can be flexibly adjusted, and thus the bulk acoustic wave resonator with a positive temperature coefficient, a negative temperature coefficient, or even a zero temperature coefficient can be obtained.

In some examples, a material of the base substrate 10 is preferably glass, and may alternatively be selected from Si, sapphire, SiC, GaAs, GaN, InP, BN, ZnO, and the like, and a thickness of the base substrate 10 is in a range from 0.1 μm to 10 mm. A thickness of the air gap on the base substrate 10 is in a range from 0.1 μm to 50 μm.

In some examples, a material of the first electrode 11 is selected from metal materials. For example, the material of the first electrode 11 is a metal Mo, or may be selected from Cu, Al, Co, Ag, Ti, Pt, Ru, W, Au, or an alloy material formed by combining any of the above metals. A thickness of the first electrode 11 is about in a range from 1 nm to 10 μm.

In some examples, a material of the piezoelectric layer 12 is preferably hBN, and may also be selected from cBN and wBN. Alternatively, the material of the piezoelectric layer 12 may also be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, PVDF, and the like. The piezoelectric layer 12 in the present embodiment may be made of one of the piezoelectric materials described above, or may be a stack of the piezoelectric materials described above. A thickness of the piezoelectric layer 12 is in a range from 10 nm to 100 μm.

In some examples, a material of the second electrode 13 may be selected from Cu, Al, Mo, Co, Ag, Ti, Pt, Ru, W, Au, and alloys thereof. A thickness of the second electrode 13 is in a range from 1 nm to 10 μm.

In some examples, the isolation layer 14 serves to electrically isolate the air gap from the bulk acoustic wave resonator and provide a structural support for the bulk acoustic wave resonator, and is made of a material selected from insulation materials such as SiO₂, Si₃N₄, Al₂O₃, and a stack of combinations thereof. A thickness of the isolation layer 14 is in a range from 1 nm to 100 μm.

In some examples, the second temperature drift compensation layer 22 is a thin film made of a material having a property of contracting with heat and expanding with cold, and has the property of contracting with heat and expanding with cold. The material of the second temperature drift compensation layer 22 may be selected from ZrW₂O₈, Zn₂GeO₄, HfW₂O₈, ZrMo₂O₈, HfMo₂O₈, ZrV₂O₇, HfV₂O₇, ZrV_{1.7}Mo_{0.3}O_{7+δ}, ZrV_{1.5}Mo_{0.5}O_{7+δ}, Cu₂V₂O₇, Cu₂₋ₓZnₓV₂O₇(x is 0.1 or 0.2), Cu_{2-y}M_{y}V₂O₇(M is any one of Yb, Sm, and Ce, and y is 0.05), Cu_{1.5}Mg_{0.5}V₂O₇, Cu₂P₂O₇, Cu₂PVO₇, HfMgW₂O₁₂, HfMgMo₃O₁₂, ZrMgMo₃O₁₂, ZrMgW₃O₁₂, ZrMnMo₃O₁₂, HfMnMo₃O₁₂, AScY₂XO₁₂ (A is Zr or Hf, Y is W or Mo, and X is V or P), TaVO₅, NbVO₅, Ag₂O, Th₂O(PO₄)₂, U₂O(PO₄)₂, Zr₂O(PO₄)₂, ScF₃, CaZrF₆, CaHfF₆, MgZrF₆, CaNbF₆, CaTiF₆, Zn(CN)₂, Cd(CN)₂, AgB(CN)₄, CuB(CN)₄, ScCo(CN)₆, Si(NCN)₂, Mn₃AN(A is Zn or Ga), GdInO3, PbTiO3, PbVO3, PbVO_{2.79}F_{0.21}, PbV₁₋ₓCrₓO₃, Bi_{0.5}Na_{0.5}VO₃, GeTe, LaCu₃Fe₄O₁₂, BiNiO₃, V₂OPO₄, Ca₂RuO₄, Sr₂IrO₄, Sr₂RhO₄, Ca₂MnO₄, Ca₂GeO₄, Ca₃Mn₂O₇, and Ga₃Ti₂O₇. A thickness of the second temperature drift compensation layer 22 is in a range from 1 nm to 100 μm.

In some examples, referring to FIG. 10, an encapsulation layer 16 is provided on a side of the second temperature drift compensation layer 22 away from the base substrate 10. A material of the encapsulation layer 16 is preferably an organic compound capable of blocking moisture and oxygen, such as polyimide, epoxy, or the like, or may be an inorganic material such as SiNₓ, Al₂O₃, or the like. The encapsulation layer 16 may be a single layer of one material or may be a stack of multiple materials.

Next, a method of fabricating the bulk acoustic wave resonator in the fourth example will be described. FIG. 11 is a flow chart illustrating how to fabricate the bulk acoustic wave resonator shown in FIG. 10. As shown in FIG. 11, the fabrication method specifically includes the following steps S41 to S411.

At the step S41, the base substrate 10 is provided.

In some examples, taking the base substrate 10 being a mono-crystalline silicon substrate as an example, step S41 may specifically include: firstly, performing ultrasonic cleaning with deionized water on the mono-crystalline silicon substrate; then putting the mono-crystalline silicon substrate into a mixed solution of H₂SO₄:H₂O=3:1, and heating the mixed solution to 250° C. and washing the mono-crystalline silicon substrate for 15 minutes; then putting the mono-crystalline silicon substrate into deionized water for ultrasonic cleaning; then putting the mono-crystalline silicon substrate into a mixed solution of NH₄OH:H₂O=1:6, and heating the mixed solution to 80° C. and washing the mono-crystalline silicon substrate for 15 minutes; taking out the mono-crystalline silicon substrate and putting the mono-crystalline silicon substrate into deionized water for washing; next, putting the mono-crystalline silicon substrate into a mixed solution of HCl:H₂O₂:H₂O=1:1:5, heating the mixed solution to 85° C. and washing the mono-crystalline silicon substrate for 15 minutes, and taking out the mono-crystalline silicon substrate and putting the mono-crystalline silicon substrate into diluted hydrofluoric acid of HF:H₂O=1:20, and rinsing the mono-crystalline silicon substrate for 10 seconds, to remove an oxide layer on the surface of the mono-crystalline silicon substrate; and finally, putting the mono-crystalline silicon substrate into deionized water for 20 minutes of ultrasonic cleaning, and drying the mono-crystalline silicon substrate with an air knife, thereby finishing the whole cleaning process of the base substrate 10.

At the step S42, the first groove 102 is formed in the base substrate 10.

In some examples, step S42 may specifically include: fabricating a mask pattern on the base substrate 10, and performing a photolithography process including photoresist coating (or spraying), pre-baking, exposing, developing, and post-baking. Then, an etching process is performed to form the first groove 102, and the etching process may be wet etching or dry etching, preferably wet etching. Finally, a photoresist stripping process is performed, thereby finishing the fabrication of the first groove 102.

At the step S43, a sacrificial layer is formed in the first groove 102.

In some examples, a material of the sacrificial layer may be a loose amorphous silicon dioxide doped with boron and phosphorus. The step S43 may specifically include: forming a slurry containing the loose amorphous silicon dioxide doped with boron and phosphorus by any one of Plasma Enhanced Chemical Vapor Deposition (PECVD), Sub-Atmospheric Pressure Chemical Vapor Deposition (SACVD), and screen printing; performing thermal annealing at 700° C. to 900° C. for 15 to 30 minutes in a vacuum chamber, so that a film of the loose amorphous silicon dioxide doped with boron and phosphorus is liquefied, and the resultant liquid flows and completely fills up the first groove 102, to level the first groove 102; and then cooling and curing the liquid. Finally, chemical mechanical polishing is performed, the base substrate 10 is pressed against a rough polishing pad by a polishing head, a surface of the base substrate 10 is planarized through a certain time of coupling effects of polishing solution corrosion, particle friction, polishing pad friction, and the like, until a surface of the material overflowing from the surface of the first groove 102 is polished to have a height equal to a height of the surface of the base substrate 10.

At the step S44, the isolation layer 14 is formed on the base substrate 10.

In some examples, the step S44 may specifically include: fabricating an isolation layer film on the base substrate 10. Firstly, an electrical insulation material is deposited by radio frequency magnetron sputtering, Pulsed Laser Sputtering (PLD), Atomic Layer Deposition (ALD), or Plasma Chemical Vapor Deposition (PCVD). A photolithography process is performed on the isolation layer film, to form a pattern including the isolation layer 14, and the photolithography process includes photoresist coating (or spraying), pre-baking, exposing, developing, and post-baking. Finally, an etching process is performed. Preferably, a wet etching process is performed. Alternatively, a dry etching process may be selected.

At the step S45, the first electrode 11 is formed on a side of the isolation layer 14 away from the base substrate 10.

In some examples, in a case where the first electrode 11 is made of a metal material, the step S45 may include: depositing a first metal film on the side of the first temperature drift compensation layer 21 away from the base substrate 10 preferably by direct current magnetron sputtering (radio frequency magnetron sputtering is also possible). Alternatively, Pulsed Laser Deposition (PLD), Molecular Beam Epitaxy (MBE), thermal evaporation, electron beam evaporation, or the like may be selected, or attaching a copper foil may be adopted. Then, a photolithography process is performed on the first metal film, where the photolithography process includes photoresist coating (or spraying), pre-baking, exposing, developing, and post-baking. Next, an etching process is performed to form a pattern including the first electrode 11, where the etching process is preferably a wet etching process. Alternatively, a dry etching process may be selected. Finally, a photoresist stripping process is performed, thereby completing the fabrication of the first electrode 11.

At the step S46, the release hole 30 is formed to penetrate through the first electrode 11 and the isolation layer 14.

In some examples, the step S46 may specifically include: firstly performing a photolithography process on a side of the first electrode 11 away from the base substrate 10, including photoresist coating (or spraying), pre-baking, exposing, developing, and post-baking, to expose a position where the release hole is located. Then, a dry etching process is performed to etch the first electrode 11, then etching gas is replaced to etch the isolation layer 14, until the sacrificial layer is exposed. Finally, a photoresist stripping process is performed, thereby forming the release hole 30.

At the step S47, the piezoelectric layer 12 is formed on a side of the first electrode 11 away from the base substrate 10.

In some examples, taking the piezoelectric layer 12 being an AlN single-layer structure as an example, the step S47 may include: forming a piezoelectric material layer on the side of the first electrode 11 away from the base substrate 10, and conducting an oriented growth of the piezoelectric material layer, where the piezoelectric material layer is preferably formed through radio frequency magnetron sputtering (or direct current magnetron sputtering), and for the AlN piezoelectric material, a target material is Al, and by controlling gas pressure and temperature of Ar and N₂ during deposition and post-annealing time and temperature, a C-axis oriented AlN piezoelectric material layer is formed, and preferably, the growth orientation is (001). The piezoelectric material layer may be deposited by Pulsed Laser Deposition (PLD), Molecular Beam Epitaxy (MBE), Metal Organic Chemical Vapor Deposition (MOCVD), Plasma Enhanced Chemical Vapor Deposition (PECVD), or the like. Next, a photolithography process, including photoresist coating (or spraying), pre-baking, exposing, developing, and post-baking, is performed on the piezoelectric material layer. An etching process is then performed to form a pattern including the piezoelectric layer 12. Preferably a wet etching process is performed. Alternatively, a dry etching process may be selected. Finally, a photoresist stripping process is performed, thereby completing the fabrication of the piezoelectric layer 12.

At the step S48, the second electrode 13 is formed on a side of the piezoelectric layer 12 away from the first electrode 11.

In some examples, in a case where the second electrode 13 is made of a metal material, the step S48 may specifically include: firstly depositing a second metal film on the side of the piezoelectric layer 12 away from the first electrode 11 preferably by direct current magnetron sputtering (radio frequency magnetron sputtering is also possible). Alternatively, Pulsed Laser Deposition (PLD), Molecular Beam Epitaxy (MBE), thermal evaporation, electron beam evaporation, or the like may be selected. Then, a photolithography process is performed on the second metal film, where the photolithography process includes photoresist coating (or spraying), pre-baking, exposing, developing, and post-baking. Thereafter, an etching process is performed to form a pattern including the second electrode 13. The etching process is preferably a wet etching process. Alternatively, a dry etching process may be selected. Finally, a photoresist stripping process is performed, thereby completing the fabrication of the second electrode 13.

At the step S49, the second temperature drift compensation layer 22 is formed on a side of the second electrode 13 away from the base substrate 10.

In some examples, the step S49 may specifically include: firstly depositing a temperature drift compensation layer film preferably by radio frequency magnetron sputtering. Alternatively, Pulsed Laser Deposition (PLD), Molecular Beam Epitaxy (MBE), Metal Organic Chemical Vapor Deposition (MOCVD), Plasma Enhanced Chemical Vapor Deposition (PECVD), sol-gel method (firstly coating a slurry containing a material of the temperature drift compensation layer, and then performing heat sintering), thermal evaporation, electron beam evaporation, or the like may be selected. Then, a photolithography process is performed on the temperature drift compensation layer film, where the photolithography process includes photoresist coating (or spraying), pre-baking, exposing, developing, and post-baking. Finally, an etching process is performed to form a pattern of the second temperature drift compensation layer 22. Preferably, a wet etching process is performed. Alternatively, a dry etching process may be selected.

At the step S410, the sacrificial layer is removed.

In some examples, the step S410 may include: etching the sacrificial layer, preferably through a wet etching process. A mixed etching solution of hydrofluoric acid, dilute nitric acid and deionized water is used to perform an immersion etching process (an etching temperature may be properly increased for increasing the wet etching rate) on the sacrificial layer for a long enough time, to ensure that the material of silicon dioxide doped with boron and phosphorus filled in the first groove 102 is completely dissolved. Finally, the first groove 102 is ultrasonically cleaned with deionized water for many times, and dried, to form the first groove 102.

At the step S411, the encapsulation layer 16 is formed on a side of the second electrode 13 away from the base substrate 10.

In some examples, taking the encapsulation layer 16 made of an organic compound material as an example, the step S411 may specifically include: firstly coating an organic material liquid, which may specifically be selected from spin coating, spraying, inkjet printing, transferring, and the like; and then heating and curing the organic material liquid, to form a pattern of the encapsulation layer 16.

At this point, the fabrication of the bulk acoustic wave resonator is completed. Alternatively, if a plurality of bulk acoustic wave resonators are simultaneously fabricated, the fabrication method provided by the embodiment of the present disclosure may further include a step of device cutting.

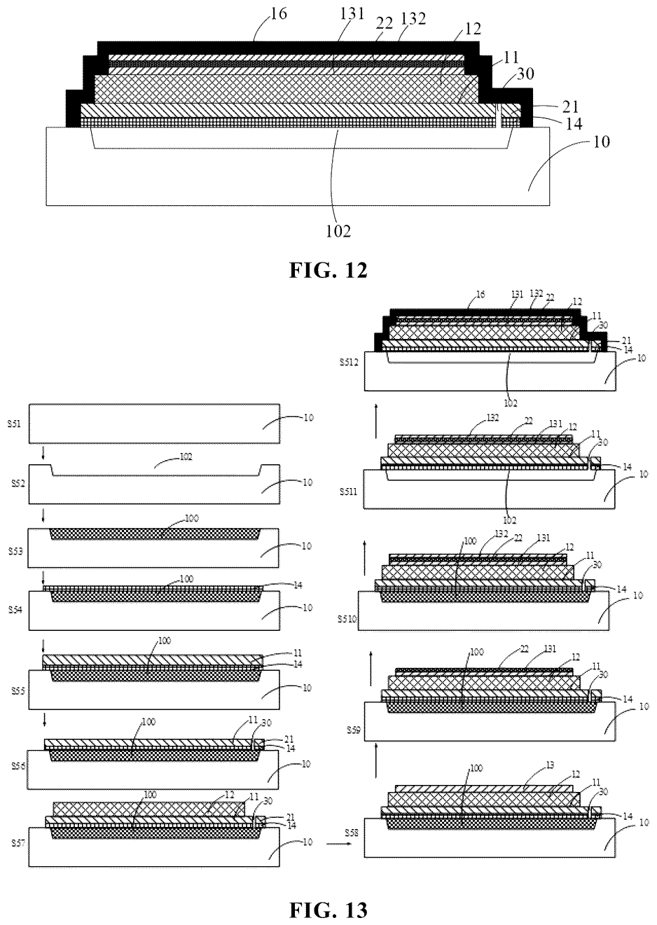

A fifth example is as follows: FIG. 12 is a schematic diagram illustrating a structure of a bulk acoustic wave resonator in a fifth example implemented in the present disclosure. As shown in FIG. 12, the bulk acoustic wave resonator includes a base substrate 10, and an isolation layer 14, a first electrode 11, a piezoelectric layer 12, a second electrode 13, and a second temperature drift compensation layer 22 disposed on the base substrate 10. The second electrode 13 includes a third sub-electrode 131 and a fourth sub-electrode 132, and in the bulk acoustic wave resonator, the isolation layer 14, the first electrode 11, the piezoelectric layer 12, the third sub-electrode 131, the second temperature drift compensation layer 22, and the fourth sub-electrode 132 are sequentially disposed in a direction away from the base substrate 10. The base substrate base 10 has a first groove 102 occupying a portion of the base substrate base 10 in a thickness direction of the base substrate 10. That is, an air gap is formed under the isolation layer 14. A release hole 30 penetrating through the first electrode 11 and the isolation layer 14 serves to release a sacrificial layer formed in the first groove 102 in a process of fabricating the bulk acoustic wave resonator (details are described in the fabrication method).

With continued reference to FIG. 12, a radio frequency signal is transmitted from the upper left corner in FIG. 12, and then is converted into an acoustic wave signal through the inverse piezoelectric effect at an interface between the third sub-electrode 131 and the piezoelectric layer 12; and then the acoustic wave signal longitudinally propagates in the piezoelectric layer 12, and is converted into a radio frequency signal through the piezoelectric effect when being transmitted to an interface between the first electrode 11 and the piezoelectric layer 12; and then the radio frequency signal is transmitted out. The air gap under the bulk acoustic wave resonator and the air layer above the bulk acoustic wave resonator act as acoustic reflectors, which serve to limit the acoustic signal in the resonator instead of being dissipated out, so that the insertion loss of the resonator can be reduced. The second temperature drift compensation layer 22 in the embodiment of the present disclosure is different from a general material, and a material of the second temperature drift compensation layer 22 has a property of contracting with heat and expanding with cold. When the ambient temperature rises, an increase of the in-plane lattice constant of the material of the piezoelectric layer 12, which is connected to the second temperature drift compensation layer 22 through the fourth sub-electrode 132, is suppressed, and a degree of the suppression can be adjusted by factors such as selection of different kinds of thin film materials of the temperature drift compensation layer, different thicknesses of the temperature drift compensation layer, and the like, so that the out-plane lattice constant of the piezoelectric layer 12 can be decreased, increased, or unchanged with the rise of the ambient temperature, that is, can be flexibly adjusted, and thus the bulk acoustic wave resonator with a positive temperature coefficient, a negative temperature coefficient, or even a zero temperature coefficient can be obtained.

In some examples, a material of the base substrate 10 is preferably glass, and may alternatively be selected from Si, sapphire, SiC, GaAs, GaN, InP, BN, ZnO, and the like, and a thickness of the base substrate 10 is in a range from 0.1 μm to 10 mm. A thickness of the air gap on the base substrate 10 is in a range from 0.1 μm to 50 μm.

In some examples, a material of the first electrode 11 is selected from metal materials. For example, the materials of the first sub-electrode 111 and the second sub-electrode 112 are a metal Mo, or may be selected from Cu, Al, Co, Ag, Ti, Pt, Ru, W, Au, or an alloy material formed by combining any of the above metals. A thickness of the first electrode 11 composed of the first sub-electrode 111 and the second sub-electrode 112 is about in a range from 1 nm to 10 μm.

In some examples, a material of the piezoelectric layer 12 is preferably hBN, and may also be selected from cBN and wBN. Alternatively, the material of the piezoelectric layer 12 may also be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, PVDF, and the like. The piezoelectric layer 12 in the present embodiment may be made of one of the piezoelectric materials described above, or may be a stack of the piezoelectric materials described above. A thickness of the piezoelectric layer 12 is in a range from 10 nm to 100 μm.

In some examples, materials of the third sub-electrode 131 and the fourth sub-electrode 132 may be selected from Cu, Al, Mo, Co, Ag, Ti, Pt, Ru, W, Au, and alloys thereof. A thickness of the second electrode 13 is in a range from 1 nm to 10 μm.

In some examples, the isolation layer 14 serves to electrically isolate the air gap from the bulk acoustic wave resonator and provide a structural support for the bulk acoustic wave resonator, and is made of a material selected from insulation materials such as SiO₂, Si₃N₄, Al₂O₃, and a stack of combinations thereof. A thickness of the isolation layer 14 is in a range from 1 nm to 100 μm.

In some examples, the second temperature drift compensation layer 22 is a thin film made of a material having a property of contracting with heat and expanding with cold, and has the property of contracting with heat and expanding with cold. The material of the second temperature drift compensation layer 22 may be selected from ZrW₂O₈, Zn₂GeO₄, HfW₂O₈, ZrMo₂O₈, HfMo₂O₈, ZrV₂O₇, HfV₂O₇, ZrV_{1.7}Mo_{0.3}O_{7+δ}, ZrV_{1.5}Mo_{0.5}O_{7+δ}, Cu₂V₂O₇, Cu₂₋ₓZnₓV₂O₇(x is 0.1 or 0.2), Cu_{2-y}M_{y}V₂O₇ (M is any one of Yb, Sm, and Ce, and y is 0.05), Cu_{1.5}Mg_{0.5}V₂O₇, Cu₂P₂O₇, Cu₂PVO₇, HfMgW₂O₁₂, HfMgMo₃O₁₂, ZrMgMo₃O₁₂, ZrMgW₃O₁₂, ZrMnMo₃O₁₂, HfMnMo₃O₁₂, AScY₂XO₁₂ (A is Zr or Hf, Y is W or Mo, and X is V or P), TaVO₅, NbVO₅, Ag₂O, Th₂O(PO₄)₂, U₂O(PO₄)₂, Zr₂O(PO₄)₂, ScF₃, CaZrF₆, CaHfF₆, MgZrF₆, CaNbF₆, CaTiF₆, Zn(CN)₂, Cd(CN)₂, AgB(CN)₄, CuB(CN)₄, ScCo(CN)₆, Si(NCN)₂, Mn₃AN(A is Zn or Ga), GdInO3, PbTiO3, PbVO3, PbVO_{2.79}F_{0.21}, PbV₁₋ₓCrₓO₃, Bi_{0.5}Na_{0.5}VO₃, GeTe, LaCu₃Fe₄O₁₂, BiNiO₃, V₂OPO₄, Ca₂RuO₄, Sr₂IrO₄, Sr₂RhO₄, Ca₂MnO₄, Ca₂GeO₄, Ca₃Mn₂O₇, and Ga₃Ti₂O₇. A thickness of the second temperature drift compensation layer 22 is in a range from 1 nm to 100 μm.

In some examples, referring to FIG. 12, an encapsulation layer 16 is provided on a side of the second electrode 13 away from the base substrate 10. A material of the encapsulation layer 16 is preferably an organic compound capable of blocking moisture and oxygen, such as polyimide, epoxy, or the like, or may be an inorganic material such as SiNₓ, Al₂O₃, or the like. The encapsulation layer 16 may be a single layer of one material or may be a stack of multiple materials.

Next, a method of fabricating the bulk acoustic wave resonator in the fifth example will be described. FIG. 13 is a flow chart illustrating how to fabricate the bulk acoustic wave resonator shown in FIG. 12. As shown in FIG. 13, the fabrication method specifically includes the following steps S51 to S512.

At the step S51, the base substrate 10 is provided.

In some examples, taking the base substrate 10 being a mono-crystalline silicon substrate as an example, step S51 may specifically include: firstly, performing ultrasonic cleaning with deionized water on the mono-crystalline silicon substrate; then putting the mono-crystalline silicon substrate into a mixed solution of H₂SO₄:H₂O=3:1, and heating the mixed solution to 250° C. and washing the mono-crystalline silicon substrate for 15 minutes; then putting the mono-crystalline silicon substrate into deionized water for ultrasonic cleaning; then putting the mono-crystalline silicon substrate into a mixed solution of NH₄OH:H₂O=1:6, and heating the mixed solution to 80° C. and washing the mono-crystalline silicon substrate for 15 minutes; taking out the mono-crystalline silicon substrate and putting the mono-crystalline silicon substrate into deionized water for washing; next, putting the mono-crystalline silicon substrate into a mixed solution of HCl:H₂O₂:H₂O=1:1:5, heating the mixed solution to 85° C. and washing the mono-crystalline silicon substrate for 15 minutes, and taking out the mono-crystalline silicon substrate and putting the mono-crystalline silicon substrate into diluted hydrofluoric acid of HF:H₂O=1:20, and rinsing the mono-crystalline silicon substrate for 10 seconds, to remove an oxide layer thereof on the surface of the mono-crystalline silicon substrate; and finally, putting the mono-crystalline silicon substrate into deionized water for 20 minutes of ultrasonic cleaning, and drying the mono-crystalline silicon substrate with an air knife, thereby finishing the whole cleaning process of the base substrate 10.

At the step S52, the first groove 102 is formed in the base substrate 10.

In some examples, step S52 may specifically include: fabricating a mask pattern on the base substrate 10, and performing a photolithography process including photoresist coating (or spraying), pre-baking, exposing, developing, and post-baking. Then, an etching process is performed to form the first groove 102, and the etching process may be wet etching or dry etching, preferably wet etching. Finally, a photoresist stripping process is performed, thereby finishing the fabrication of the first groove 102.

At the step S53, a sacrificial layer is formed in the first groove 102.

In some examples, a material of the sacrificial layer may be a loose amorphous silicon dioxide doped with boron and phosphorus. The step S53 may specifically include: forming a slurry containing the loose amorphous silicon dioxide doped with boron and phosphorus by any one of Plasma Enhanced Chemical Vapor Deposition (PECVD), Sub-Atmospheric Pressure Chemical Vapor Deposition (SACVD), and screen printing; performing thermal annealing at 700° C. to 900° C. for 15 to 30 minutes in a vacuum chamber, so that a film of the loose amorphous silicon dioxide doped with boron and phosphorus is liquefied, and the resultant liquid flows and completely fill up the first groove 102, to level the first groove 102; and then cooling and curing the liquid. Finally, chemical mechanical polishing is performed, the base substrate 10 is pressed against a rough polishing pad by a polishing head, a surface of the base substrate 10 is planarized through a certain time of coupling effects of polishing solution corrosion, particle friction, polishing pad friction, and the like, until a surface of the material overflowing from the surface of the first groove 102 is polished to have a height equal to a height of the surface of the base substrate 10.

At the step S54, the isolation layer 14 is formed on the base substrate 10.

In some examples, the step S54 may specifically include: fabricating an isolation layer film on the base substrate 10. Firstly, an electrical insulation material is deposited by radio frequency magnetron sputtering, Pulsed Laser Sputtering (PLD), Atomic Layer Deposition (ALD), or Plasma Chemical Vapor Deposition (PCVD). A photolithography process is performed on the isolation layer film, to form a pattern including the isolation layer 14, and the photolithography process includes photoresist coating (or spraying), pre-baking, exposing, developing, and post-baking. Finally, etching is performed, preferably a wet etching process is performed. Alternatively, a dry etching process may be selected.

At the step S55, the first electrode 11 is formed on a side of the isolation layer 14 away from the base substrate 10.

In some examples, in a case where the first electrode 11 is made of a metal material, the step S55 may include: depositing a first metal film on the side of the first temperature drift compensation layer 21 away from the base substrate 10 preferably by direct current magnetron sputtering (radio frequency magnetron sputtering is also possible). Alternatively, Pulsed Laser Deposition (PLD), Molecular Beam Epitaxy (MBE), thermal evaporation, electron beam evaporation, or the like may be selected, or attaching a copper foil may be adopted. Then, a photolithography process is performed on the first metal film, where the photolithography process includes photoresist coating (or spraying), pre-baking, exposing, developing, and post-baking. Next, an etching process is performed to form a pattern including the first electrode 11, where the etching process is preferably a wet etching process. Alternatively, a dry etching process may be selected. Finally, a photoresist stripping process is performed, thereby completing the fabrication of the first electrode 11.

At the step S56, the release hole 30 penetrating the first electrode 11 and the isolation layer 14 is formed.

In some examples, the step S56 may specifically include: firstly performing a photolithography process on the first electrode 11 at a side away from the base substrate 10, including photoresist coating (or spraying), pre-baking, exposing, developing, and post-baking, to expose a position where the release hole is located. Then, a dry etching process is performed to etch the first electrode 11, then etching gas is replaced to etch the isolation layer 14, until the sacrificial layer is exposed, and finally a photoresist stripping process is performed, thereby forming the release hole 30.

At the step S57, the piezoelectric layer 12 is formed on a side of the first electrode 11 away from the base substrate 10.

In some examples, taking the piezoelectric layer 12 being an AlN single-layer structure as an example, the step S57 may include: forming a piezoelectric material layer on the side of the first electrode 11 away from the base substrate 10, and conducting an oriented growth of the piezoelectric material layer, where the piezoelectric material layer is preferably formed through radio frequency magnetron sputtering (or direct current magnetron sputtering), and for the AlN piezoelectric material, a target material is Al, and by controlling gas pressure and temperature of Ar and N₂ during deposition and post-annealing time and temperature, a C-axis oriented AlN piezoelectric material layer is formed, and preferably, the growth orientation is (001). The deposition manner of the piezoelectric material layer may be selected from Pulsed Laser Deposition (PLD), Molecular Beam Epitaxy (MBE), Metal Organic Chemical Vapor Deposition (MOCVD), Plasma Enhanced Chemical Vapor Deposition (PECVD), and the like. Next, a photolithography process, including photoresist coating (or spraying), pre-baking, exposing, developing, and post-baking, is performed on the piezoelectric material layer. An etching process is then performed to form a pattern including the piezoelectric layer 12. Preferably a wet etching process is performed. Alternatively, a dry etching process may be selected. Finally, a photoresist stripping process is performed, thereby completing the fabrication of the piezoelectric layer 12.

At the step S58, the third sub-electrode 131 is formed on a side of the piezoelectric layer 12 away from the first electrode 11.

In some examples, when the third sub-electrode 131 is made of a metal material, the step S58 may specifically include first depositing a second metal film on the side of the piezoelectric layer 12 away from the first electrode 11 preferably by direct current magnetron sputtering (radio frequency magnetron sputtering is also possible). Alternatively, Pulsed Laser Deposition (PLD), Molecular Beam Epitaxy (MBE), thermal evaporation, electron beam evaporation, or the like may be selected. Then, a photolithography process is performed on the second metal film, where the photolithography process includes photoresist coating (or spraying), pre-baking, exposing, developing, and post-baking. Thereafter, an etching process is performed to form a pattern including the third sub-electrode 131. The etching process is preferably a wet etching process. Alternatively, a dry etching process may be selected. Finally, a photoresist stripping process is performed, thereby completing the fabrication of the third sub-electrode 131.

At the step S59, the second temperature drift compensation layer 22 is formed on a side of the third sub-electrode 131 away from the base substrate 10.

In some examples, the step S59 may specifically include: firstly depositing a temperature drift compensation layer film preferably by radio frequency magnetron sputtering. Alternatively, Pulsed Laser Deposition (PLD), Molecular Beam Epitaxy (MBE), Metal Organic Chemical Vapor Deposition (MOCVD), Plasma Enhanced Chemical Vapor Deposition (PECVD), sol-gel method (firstly coating a slurry containing a material of the temperature drift compensation layer, and then performing heat sintering), thermal evaporation, electron beam evaporation, or the like may be selected. Then a photolithography process is performed on the temperature drift compensation layer film, where the photolithography process includes photoresist coating (or spraying), pre-baking, exposing, developing, and post-baking. Finally, an etching process is performed to form a pattern of the second temperature drift compensation layer 22. Preferably a wet etching process is performed. Alternatively, a dry etching process may be selected.

At the step S510, the fourth sub-electrode 132 is formed on a side of the second temperature drift compensation layer 22 away from the third sub-electrode 131.

In some examples, in a case where the fourth sub-electrode 132 is made of a metal material, the step S510 may specifically include: firstly depositing a third metal film on the side of the piezoelectric layer 12 away from the first electrode 11 preferably by direct current magnetron sputtering (radio frequency magnetron sputtering is also possible). Alternatively, Pulsed Laser Deposition (PLD), Molecular Beam Epitaxy (MBE), thermal evaporation, electron beam evaporation, or the like may be selected. Next, a photolithography process is performed on the third metal film, where the photolithography process includes photoresist coating (or spraying), pre-baking, exposing, developing, and post-baking. Thereafter, an etching process is performed to form a pattern including the fourth sub-electrode 132. The etching process is preferably a wet etching process. Alternatively, a dry etching process may be selected. Finally, a photoresist stripping process is performed, thereby completing the fabrication of the fourth sub-electrode 132.

At the step S511, the sacrificial layer is removed.

In some examples, the step S511 may include: etching the sacrificial layer, preferably through a wet etching process. A mixed etching solution of hydrofluoric acid, dilute nitric acid and deionized water is used to perform an immersion etching process (an etching temperature may be properly increased for increasing the wet etching rate) on the sacrificial layer for a long enough time, to ensure that the material of silicon dioxide doped with boron and phosphorus filled in the first groove 102 is completely dissolved. Finally, the first groove 102 is ultrasonically cleaned with deionized water for many times, and dried, to form the first groove 102.

At the step S512, the encapsulation layer 16 is formed on a side of the fourth sub-electrode 132 away from the base substrate 10.

In some examples, taking the encapsulation layer 16 made of an organic compound material as an example, the step S512 may specifically include: firstly coating an organic material liquid, which may specifically be selected from spin coating, spraying, inkjet printing, transferring, and the like; and then heating and curing the organic material liquid, to form a pattern of the encapsulation layer 16.

At this point, the fabrication of the acoustic wave resonator is completed. Alternatively, if a plurality of bulk acoustic wave resonators are simultaneously fabricated, the fabrication method provided by the embodiment of the present disclosure may further include a step of device cutting.

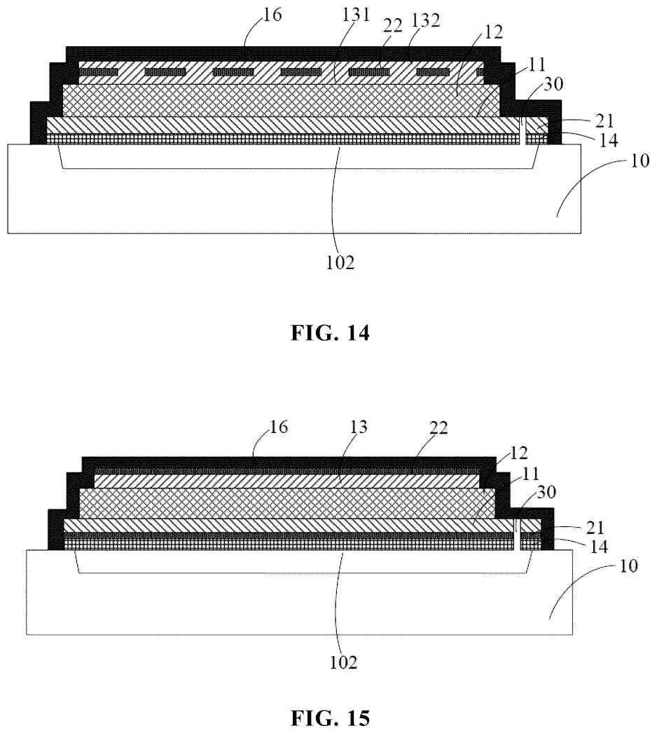

A sixth example is as follows: FIG. 14 is a schematic diagram illustrating a structure of a bulk acoustic wave resonator in a sixth example implemented in the present disclosure. As shown in FIG. 14, the structure of the bulk acoustic wave resonator in this example is substantially the same as that of the bulk acoustic wave resonator in the fifth example, except that the second temperature drift compensation layer 22 has a hollow out pattern in this example. That is, the second temperature drift compensation layer 22 has through holes extending in the thickness direction thereof, and in this case, the third sub-electrode 131 and the fourth sub-electrode 132 of the second electrode 13 may be electrically connected together by the through holes penetrating through the second temperature drift compensation layer 22, so that the resistance of the second electrode 13 is reduced, and the in-band insertion loss of the bulk acoustic wave resonator is reduced. The same structures as in the fifth example may be adopted for the remaining structures in the bulk acoustic wave resonator, and therefore, the details are not repeated herein.

The method of fabricating the bulk acoustic wave resonator in the sixth example may be the same as the fabrication method in the fifth example, except that during forming the second temperature drift compensation layer 22, the through holes extending in the thickness direction thereof are formed, that is, the hollow out pattern is formed. The remaining steps are the same as those in the fifth example, and therefore, the details are not repeated herein.

A seventh example is as follows: FIG. 15 is a schematic diagram illustrating a structure of a bulk acoustic wave resonator in a seventh example implemented in the present disclosure. As shown in FIG. 15, the bulk acoustic wave resonator includes a base substrate 10, and an isolation layer 14, a first temperature drift compensation layer 21, a first electrode 11, a piezoelectric layer 12, a second electrode 13, and a second temperature drift compensation layer 22 sequentially disposed on the base substrate 10. The base substrate 10 has a first groove 102 occupying a portion of the base substrate 10 in a thickness direction of the base substrate 10, that is, an air gap is formed under the isolation layer 14. A release hole 30 penetrating through the first electrode 11, the first temperature drift compensation layer 21, and the isolation layer 14 serves to release a sacrificial layer formed in the first groove 102 in a process of fabricating the bulk acoustic wave resonator (details are described in the fabrication method).

With continued reference to FIG. 15, a radio frequency signal is transmitted from the upper left corner in FIG. 15, and then is converted into an acoustic wave signal through the inverse piezoelectric effect at an interface between the second electrode 13 and the piezoelectric layer 12; and then the acoustic wave signal longitudinally propagates in the piezoelectric layer 12, and is converted into a radio frequency signal through the piezoelectric effect when being transmitted to an interface between the first electrode 11 and the piezoelectric layer 12; and then the radio frequency signal is transmitted out. The air gap under the bulk acoustic wave resonator and the air layer above the bulk acoustic wave resonator act as acoustic reflectors, which serve to limit the acoustic signal in the resonator structure instead of being dissipated, so that the insertion loss of the resonator can be reduced. The first temperature drift compensation layer 21 in the embodiment of the present disclosure is different from a general material, and a material of the temperature drift compensation layer has a property of contracting with heat and expanding with cold. When the ambient temperature rises, an increase of the in-plane lattice constant of the material of the piezoelectric layer 12, which is connected to the first temperature drift compensation layer 21 through the first electrode 11 and connected to the second temperature drift compensation layer 22 through the second electrode 13, is suppressed, and a degree of the suppression can be adjusted by factors such as different kinds of selection of a thin film material of the temperature drift compensation layer and different thicknesses of the temperature drift compensation layer, so that the out-plane lattice constant of the piezoelectric layer 12 can be decreased, increased, or unchanged with the rise of the ambient temperature, that is, can be flexibly adjusted, and thus the bulk acoustic wave resonator with a positive temperature coefficient, a negative temperature coefficient, or even a zero temperature coefficient can be obtained.

In some examples, a material of the base substrate 10 is preferably glass, and may alternatively be selected from Si, sapphire, SiC, GaAs, GaN, InP, BN, ZnO, and the like, and a thickness of the base substrate 10 is in a range from 0.1 μm to 10 mm. A thickness of the air gap on the base substrate 10 is in a range from 0.1 μm to 50 μm.

In some examples, a material of the first electrode 11 is selected from metal materials. For example, the material of the first electrode 11 is a metal Mo, or may be selected from Cu, Al, Co, Ag, Ti, Pt, Ru, W, Au, or an alloy material formed by combining any of the above metals. A thickness of the first electrode 11 is about in a range from 1 nm to 10 μm.

In some examples, a material of the piezoelectric layer 12 is preferably hBN, and may also be selected from cBN and wBN. Alternatively, the material of the piezoelectric layer 12 may also be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, PVDF, and the like. The piezoelectric layer 12 in the present embodiment may be made of one of the piezoelectric materials described above, or may be a stack of the piezoelectric materials described above. A thickness of the piezoelectric layer 12 is in a range from 10 nm to 100 μm.

In some examples, a material of the second electrode 13 may be selected from Cu, Al, Mo, Co, Ag, Ti, Pt, Ru, W, Au, and alloys thereof. A thickness of the second electrode 13 is in a range from 1 nm to 10 μm.

In some examples, the isolation layer 14 serves to electrically isolate the air gap from the bulk acoustic wave resonator and provide a structural support for the bulk acoustic wave resonator, and is made of a material selected from insulation materials such as SiO₂, Si₃N₄, Al₂O₃, and a stack of combinations thereof. A thickness of the isolation layer 14 is in a range from 1 nm to 100 μm.

In some examples, the first temperature drift compensation layer 21 and the second temperature drift compensation layer 22 are both thin films made of materials having a property of contracting with heat and expanding with cold, and have the property of contracting with heat and expanding with cold. The materials of the first temperature drift compensation layer 21 and the second temperature drift compensation layer 22 may be selected from ZrW₂O₈, Zn₂GeO₄, HfW₂O₈, ZrMo₂O₈, HfMo₂O₈, ZrV₂O₇, HfV₂O₇, ZrV_{1.7}Mo_{0.3}O_{7+δ}, ZrV_{1.5}Mo_{0.5}O_{7+δ}, Cu₂V₂O₇, Cu₂₋ₓZnₓV₂O₇ (x is 0.1 or 0.2), Cu_{2-y}M_{y}V₂O₇ (M is any one of Yb, Sm, and Ce, and y is 0.05), Cu_{1.5}Mg_{0.5}V₂O₇, Cu₂P₂O₇, Cu₂PVO₇, HfMgW₃O₁₂, HfMgMo₃O₁₂, ZrMgMo₃O₁₂, ZrMgW₃O₁₂, ZrMnMo₃O₁₂, HfMnMo₃O₁₂, AScY₂XO₁₂ (A is Zr or Hf, Y is W or Mo, and X is V or P), TaVO₅, NbVO₅, Ag₂O, Th₂O(PO₄)₂, U₂O(PO₄)₂, Zr₂O(PO₄)₂, ScF₃, CaZrF₆, CaHfF₆, MgZrF₆, CaNbF₆, CaTiF₆, Zn(CN)₂, Cd(CN)₂, AgB(CN)₄, CuB(CN)₄, ScCo(CN)₆, Si(NCN)₂, Mn₃AN(A is Zn or Ga), GdInO3, PbTiO3, PbVO3, PbVO_{2.79}F_{0.21}, PbV₁₋ₓCrₓO₃, Bi_{0.5}Na_{0.5}VO₃, GeTe, LaCu₃Fe₄O₁₂, BiNiO₃, V₂OPO₄, Ca₂RuO₄, Sr₂IrO₄, Sr₂RhO₄, Ca₂MnO₄, Ca₂GeO₄, Ca₃Mn₂O₇, and Ga₃Ti₂O₇. Thicknesses of the first temperature drift compensation layer 21 and the second temperature drift compensation layer 22 are both in a range from 1 nm to 100 μm.

In some examples, referring to FIG. 15, an encapsulation layer 16 is provided on a side of the second temperature drift compensation layer 22 away from the base substrate 10. A material of the encapsulation layer 16 is preferably an organic compound capable of blocking moisture and oxygen, such as polyimide, epoxy, or the like, or may be an inorganic material such as SiNₓ, Al₂O₃, or the like. The encapsulation layer 16 may be a single layer of one material or may be a stack of multiple materials.

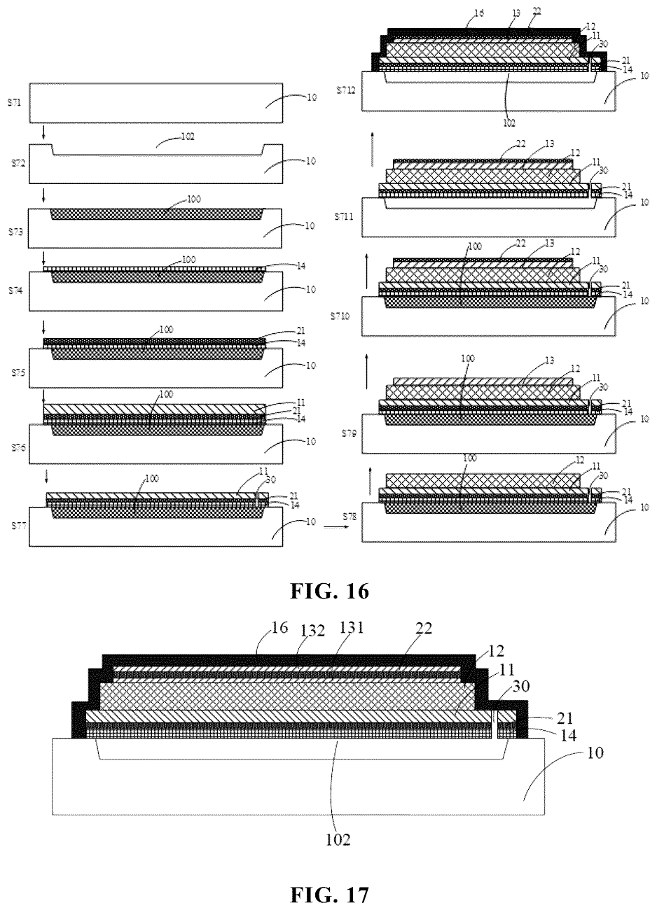

Next, a method of fabricating the bulk acoustic wave resonator in the seventh example will be described. FIG. 16 is a flow chart illustrating how to fabricate the bulk acoustic wave resonator shown in FIG. 15. As shown in FIG. 16, the fabrication method specifically includes the following steps S71 to S712.

At the step S71, the base substrate 10 is provided.

In some examples, taking the base substrate 10 being a mono-crystalline silicon substrate as an example, step S71 may specifically include: firstly, performing ultrasonic cleaning with deionized water on the mono-crystalline silicon substrate; then putting the mono-crystalline silicon substrate into a mixed solution of H₂SO₄:H₂O=3:1, and heating the mixed solution to 250° C. and washing the mono-crystalline silicon substrate for 15 minutes; then putting the mono-crystalline silicon substrate into deionized water for ultrasonic cleaning; then putting the mono-crystalline silicon substrate into a mixed solution of NH₄OH:H₂O=1:6, and heating the mixed solution to 80° C. and washing the mono-crystalline silicon substrate for 15 minutes; taking out the mono-crystalline silicon substrate and putting the mono-crystalline silicon substrate into deionized water for washing; next, putting the mono-crystalline silicon substrate into a mixed solution of HCl:H₂O₂:H₂O=1:1:5, heating the mixed solution to 85° C. and washing the mono-crystalline silicon substrate for 15 minutes, and taking out the mono-crystalline silicon substrate and putting the mono-crystalline silicon substrate into diluted hydrofluoric acid of HF:H₂O=1:20, and rinsing the mono-crystalline silicon substrate for 10 seconds, to remove an oxide layer on the surface of the mono-crystalline silicon substrate; and finally, putting the mono-crystalline silicon substrate into deionized water for 20 minutes of ultrasonic cleaning, and drying the mono-crystalline silicon substrate with an air knife, thereby finishing the whole cleaning process of the base substrate 10.

At the step S72, the first groove 102 is formed in the base substrate 10.

In some examples, step S72 may specifically include: fabricating a mask pattern on the base substrate 10, and performing a photolithography process including photoresist coating (or spraying), pre-baking, exposing, developing, and post-baking. Then, an etching process is performed to form the first groove 102, and the etching process may be wet etching or dry etching, preferably wet etching. Finally, a photoresist stripping process is performed, thereby finishing the fabrication of the first groove 102.

At the step S73, a sacrificial layer is formed in the first groove 102.

In some examples, a material of the sacrificial layer may be a loose amorphous silicon dioxide doped with boron and phosphorus. The step S73 may specifically include: forming a slurry containing the loose amorphous silicon dioxide doped with boron and phosphorus by any one of Plasma Enhanced Chemical Vapor Deposition (PECVD), Sub-Atmospheric Pressure Chemical Vapor Deposition (SACVD), and screen printing; performing thermal annealing at 700° C. to 900° C. for 15 to 30 minutes in a vacuum chamber, so that a film of the loose amorphous silicon dioxide doped with boron and phosphorus is liquefied, and the resultant liquid flows and completely fills up the first groove 102, to level the first groove 102; and then cooling and curing the liquid. Finally, chemical mechanical polishing is performed, the base substrate 10 is pressed against a rough polishing pad by a polishing head, a surface of the base substrate 10 is planarized through a certain time of coupling effects of polishing solution corrosion, particle friction, polishing pad friction, and the like, until a surface of the material overflowing from the surface of the first groove 102 is polished to have a height equal to a height of the surface of the base substrate 10.

At the step S74, the isolation layer 14 is formed on the base substrate 10.

In some examples, the step S74 may specifically include: fabricating an isolation layer film on the base substrate 10. Firstly, an electrical insulation material is deposited by radio frequency magnetron sputtering, Pulsed Laser Sputtering (PLD), Atomic Layer Deposition (ALD), or Plasma Chemical Vapor Deposition (PCVD). A photolithography process is performed on the isolation layer film, to form a pattern including the isolation layer 14, and the photolithography process includes photoresist coating (or spraying), pre-baking, exposing, developing, and post-baking. Finally, an etching process is performed. Preferably a wet etching process is performed. Alternatively, a dry etching process may be selected.

At the step S75, the first temperature drift compensation layer 21 is formed on a side of the isolation layer 14 away from the base substrate 10.

In some examples, the step S75 may specifically include: firstly depositing a temperature drift compensation layer film preferably by radio frequency magnetron sputtering. Alternatively, Pulsed Laser Deposition (PLD), Molecular Beam Epitaxy (MBE), Metal Organic Chemical Vapor Deposition (MOCVD), Plasma Enhanced Chemical Vapor Deposition (PECVD), sol-gel method (firstly coating a slurry containing a material of the temperature drift compensation layer, and then performing heat sintering), thermal evaporation, electron beam evaporation, or the like may be selected. Then a photolithography process is performed on the temperature drift compensation layer film, where the photolithography process includes photoresist coating (or spraying), pre-baking, exposing, developing, and post-baking. Finally, an etching process is performed to form a pattern of the first temperature drift compensation layer 21. Preferably a wet etching process is performed. Alternatively, a dry etching process may be selected.

At the step S76, the first electrode 11 is formed on a side of the first temperature drift compensation layer 21 away from the base substrate 10.

In some examples, in a case where the first electrode 11 is made of a metal material, the step S76 may include: depositing a first metal film on the side of the first temperature drift compensation layer 21 away from the base substrate 10 preferably by direct current magnetron sputtering (radio frequency magnetron sputtering is also possible). Alternatively, Pulsed Laser Deposition (PLD), Molecular Beam Epitaxy (MBE), thermal evaporation, electron beam evaporation, or the like may be selected, or attaching a copper foil may be adopted. Then, a photolithography process is performed on the first metal film, where the photolithography process includes photoresist coating (or spraying), pre-baking, exposing, developing, and post-baking. Next, an etching process is performed to form a pattern including the first electrode 11, where the etching process is preferably a wet etching process. Alternatively, a dry etching process may be selected. Finally, a photoresist stripping process is performed, thereby completing the fabrication of the first electrode 11.

At the step S77, the release hole 30 is formed to penetrate the first electrode 11, the isolation layer 14, and the first temperature drift compensation layer 21.

In some examples, the step S77 may specifically include: firstly performing a photolithography process on the first electrode 11 at a side away from the base substrate 10, including photoresist coating (or spraying), pre-baking, exposing, developing, and post-baking, to expose a position where the release hole is located. Then, a dry etching process is performed to etch the first electrode 11, then etching gas is replaced to etch the first temperature drift compensation layer 21, then the etching gas is replaced again to etch the isolation layer 14, until the sacrificial layer is exposed. Finally a photoresist stripping process is performed, thereby forming the release hole 30.

At the step S78, the piezoelectric layer 12 is formed on a side of the first electrode 11 away from the base substrate 10.

In some examples, taking the piezoelectric layer 12 being an AlN single-layer structure as an example, the step S78 may include: forming a piezoelectric material layer on the side of the first electrode 11 away from the base substrate 10, and conducting an oriented growth of the piezoelectric material layer, where the piezoelectric material layer is preferably formed through radio frequency magnetron sputtering (or direct current magnetron sputtering), and for the AlN piezoelectric material, a target material is Al, and by controlling gas pressure and temperature of Ar and N₂ during deposition and post-annealing time and temperature, a C-axis oriented AlN piezoelectric material layer is formed, and preferably, the growth orientation is (001). The piezoelectric material layer may be deposited by Pulsed Laser Deposition (PLD), Molecular Beam Epitaxy (MBE), Metal Organic Chemical Vapor Deposition (MOCVD), Plasma Enhanced Chemical Vapor Deposition (PECVD), or the like. Next, a photolithography process, including photoresist coating (or spraying), pre-baking, exposing, developing, and post-baking, is performed on the piezoelectric material layer. An etching process is then performed to form a pattern including the piezoelectric layer 12. Preferably, a wet etching process is performed. Alternatively, a dry etching process may be selected. Finally, a photoresist stripping process is performed, thereby completing the fabrication of the piezoelectric layer 12.

At the step S79, the second electrode 13 is formed on a side of the piezoelectric layer 12 away from the first electrode 11.

In some examples, in a case where the second electrode 13 is made of a metal material, the step S79 may specifically include: firstly depositing a third metal film on the side of the piezoelectric layer 12 away from the first electrode 11 preferably by direct current magnetron sputtering (radio frequency magnetron sputtering is also possible). Alternatively, Pulsed Laser Deposition (PLD), Molecular Beam Epitaxy (MBE), thermal evaporation, electron beam evaporation, or the like may be selected. Next, a photolithography process is performed on the third metal film, where the photolithography process includes photoresist coating (or spraying), pre-baking, exposing, developing, and post-baking. Thereafter, an etching process is performed to form a pattern including the second electrode 13. The etching process is preferably a wet etching process. Alternatively, a dry etching process may be selected. Finally, a photoresist stripping process is performed, thereby completing the fabrication of the second electrode 13.

At the step S710, the second temperature drift compensation layer 22 is formed on a side of the second electrode 13 away from the base substrate 10.

In some examples, the step S710 may specifically include: firstly depositing a temperature drift compensation layer film preferably by radio frequency magnetron sputtering. Alternatively, Pulsed Laser Deposition (PLD), Molecular Beam Epitaxy (MBE), Metal Organic Chemical Vapor Deposition (MOCVD), Plasma Enhanced Chemical Vapor Deposition (PECVD), sol-gel method (firstly coating a slurry containing a material of the temperature drift compensation layer, and then performing heat sintering), thermal evaporation, electron beam evaporation, or the like my be selected. Then a photolithography process is performed on the temperature drift compensation layer film, where the photolithography process includes photoresist coating (or spraying), pre-baking, exposing, developing, and post-baking. Finally, an etching process is performed to form a pattern of the second temperature drift compensation layer 22. Preferably, a wet etching process is performed. Alternatively, a dry etching process may be selected.

At the step S711, the sacrificial layer is removed.

In some examples, the step S711 may include: etching the sacrificial layer, preferably through a wet etching process. A mixed etching solution of hydrofluoric acid, dilute nitric acid and deionized water is used to perform an immersion etching process (an etching temperature may be properly increased for increasing the wet etching rate) on the sacrificial layer for a long enough time, to ensure that the material of silicon dioxide doped with boron and phosphorus filled in the first groove 102 is completely dissolved. Finally, the first groove 102 is ultrasonically cleaned with deionized water for many times, and dried, to form the first groove 102.

At the step S712, the encapsulation layer 16 is formed on a side of the second electrode 13 away from the base substrate 10.

In some examples, taking the encapsulation layer 16 made of an organic compound material as an example, the step S712 may specifically include: firstly coating an organic material liquid, which may specifically be selected from spin coating, spraying, inkjet printing, transferring, and the like; and then heating and curing the organic material liquid, to form a pattern of the encapsulation layer 16.

At this point, the fabrication of the acoustic wave resonator is completed. Alternatively, if a plurality of bulk acoustic wave resonators are simultaneously fabricated, the fabrication method provided by the embodiment of the present disclosure may further include a step of device cutting.

An eighth example is as follows: FIG. 17 is a schematic diagram illustrating a structure of a bulk acoustic wave resonator in an eighth example implemented in the present disclosure. As shown in FIG. 17, the bulk acoustic wave resonator includes a base substrate 10, and an isolation layer 14, a first temperature drift compensation layer 21, a first electrode 11, a piezoelectric layer 12, a second electrode 13, and a second temperature drift compensation layer 22 disposed on the base substrate 10. The second electrode 13 includes a third sub-electrode 131 and a fourth sub-electrode 132, and in the bulk acoustic wave resonator, the isolation layer 14, the first temperature drift compensation layer 21, the first electrode 11, the piezoelectric layer 12, the third sub-electrode 131, the second temperature drift compensation layer 22, and the fourth sub-electrode 132 are sequentially disposed in a direction away from the base substrate 10. The base substrate base 10 has a first groove 102 occupying a portion of the base substrate 10 in a thickness direction of the base substrate 10, that is, an air gap is formed under the isolation layer 14. A release hole 30 penetrating through the first electrode 11 and the isolation layer 14 serves to release a sacrificial layer formed in the first groove 102 in a process of fabricating the bulk acoustic wave resonator (details are described in the fabrication method).

With continued reference to FIG. 17, a radio frequency signal is transmitted from the upper left corner in FIG. 17, and then is converted into an acoustic wave signal through the inverse piezoelectric effect at an interface between the third sub-electrode 131 and the piezoelectric layer 12; and then the acoustic wave signal longitudinally propagates in the piezoelectric layer 12, and is converted into a radio frequency signal through the piezoelectric effect when being transmitted to an interface between the first electrode 11 and the piezoelectric layer 12; and then the radio frequency signal is transmitted out. The air gap under the bulk acoustic wave resonator and the air layer above the bulk acoustic wave resonator act as acoustic reflectors, which serve to limit the acoustic signal in the resonator structure instead of being dissipated, so that the insertion loss of the resonator can be reduced. The second temperature drift compensation layer 22 in the embodiment of the present disclosure is different from a general material, and materials of the first temperature drift compensation layer 21 and the second temperature drift compensation layer 22 have the property of contracting with heat and expanding with cold. When the ambient temperature rises, an increase of the in-plane lattice constant of the material of the piezoelectric layer 12, which is connected to the first temperature drift compensation layer 21 through the first electrode 11 and connected to the second temperature drift compensation layer 22 through the fourth sub-electrode 132, is suppressed, and a degree of the suppression can be adjusted by by factors such as selection of different kinds of thin film materials of the temperature drift compensation layer, different thicknesses of the temperature drift compensation layer, and the like, so that the out-plane lattice constant of the piezoelectric layer 12 can be decreased, increased, or unchanged with the rise of the ambient temperature, that is, can be flexibly adjusted, and thus the bulk acoustic wave resonator with a positive temperature coefficient, a negative temperature coefficient, or even a zero temperature coefficient can be obtained.

In some examples, a material of the base substrate 10 is preferably glass, and may alternatively be selected from Si, sapphire, SiC, GaAs, GaN, InP, BN, ZnO, and the like, and a thickness of the base substrate 10 is in a range from 0.1 μm to 10 mm. A thickness of the air gap on the base substrate 10 is in a range from 0.1 μm to 50 μm.

In some examples, a material of the first electrode 11 is selected from metal materials. For example, the materials of the first sub-electrode 111 and the second sub-electrode 112 are a metal Mo, or may be selected from Cu, Al, Co, Ag, Ti, Pt, Ru, W, Au, or an alloy material formed by combining any of the above metals. A thickness of the first electrode 11 composed of the first sub-electrode 111 and the second sub-electrode 112 is about in a range from 1 nm to 10 μm.

In some examples, a material of the piezoelectric layer 12 is preferably hBN, and may alternatively be selected from cBN and wBN. Alternatively, the material of the piezoelectric layer 12 may be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, PVDF, or the like. The piezoelectric layer 12 in the present embodiment may be made of one of the piezoelectric materials described above, or may be a stack of the piezoelectric materials described above. A thickness of the piezoelectric layer 12 is in a range from 10 nm to 100 μm.

In some examples, materials of the third sub-electrode 131 and the fourth sub-electrode 132 may be selected from Cu, Al, Mo, Co, Ag, Ti, Pt, Ru, W, Au, and alloys thereof. A thickness of the second electrode 13 is in a range from 1 nm to 10 μm.

In some examples, the isolation layer 14 serves to electrically isolate the air gap from the bulk acoustic wave resonator and provide a structural support for the bulk acoustic wave resonator, and is made of a material selected from insulation materials such as SiO₂, Si₃N₄, Al₂O₃, and a stack of combinations thereof. A thickness of the isolation layer 14 is in a range from 1 nm to 100 μm.

In some examples, the first temperature drift compensation layer 21 and the second temperature drift compensation layer 22 are both thin films made of materials having a property of contracting with heat and expanding with cold, and have the property of contracting with heat and expanding with cold. The materials of the first temperature drift compensation layer 21 and the second temperature drift compensation layer 22 may be selected from ZrW₂O₈, Zn₂GeO₄, HfW₂O₈, ZrMo₂O₈, HfMo₂O₈, ZrV₂O₇, HfV₂O₇, ZrV_{1.7}Mo_{0.3}O_{7+δ}, ZrV_{1.5}Mo_{0.5}O_{7+δ}, Cu₂V₂O₇, Cu₂₋ₓZnₓV₂O₇ (x is 0.1 or 0.2), Cu_{2-y}M_{y}V₂O₇ (M is any one of Yb, Sm, and Ce, and y is 0.05), Cu_{1.5}Mg_{0.5}V₂O₇, Cu₂P₂O₇, Cu₂PVO₇, HfMgW₃O₁₂, HfMgMo₃O₁₂, ZrMgMo₃O₁₂, ZrMgW₃O₁₂, ZrMnMo₃O₁₂, HfMnMo₃O₁₂, AScY₂XO₁₂ (A is Zr or Hf, Y is W or Mo, and X is V or P), TaVO₅, NbVO₅, Ag₂O, Th₂O(PO₄)₂, U₂O(PO₄)₂, Zr₂O(PO₄)₂, ScF₃, CaZrF₆, CaHfF₆, MgZrF₆, CaNbF₆, CaTiF₆, Zn(CN)₂, Cd(CN)₂, AgB(CN)₄, CuB(CN)₄, ScCo(CN)₆, Si(NCN)₂, Mn₃AN(A is Zn or Ga), GdInO3, PbTiO3, PbVO3, PbVO_{2.79}F_{0.21}, PbV₁₋ₓCrₓO₃, Bi_{0.5}Na_{0.5}VO₃, GeTe, LaCu₃Fe₄O₁₂, BiNiO₃, V₂OPO₄, Ca₂RuO₄, Sr₂IrO₄, Sr₂RhO₄, Ca₂MnO₄, Ca₂GeO₄, Ca₃Mn₂O₇, and Gas Ti₂O₇. Thicknesses of the first temperature drift compensation layer 21 and the second temperature drift compensation layer 22 are both in a range from 1 nm to 100 μm.

In some examples, referring to FIG. 17, an encapsulation layer 16 is provided on a side of the second electrode 13 away from the base substrate 10. A material of the encapsulation layer 16 is preferably an organic compound capable of blocking moisture and oxygen, such as polyimide, epoxy, or the like, or may be an inorganic material such as SiNₓ, Al₂O₃, or the like. The encapsulation layer 16 may be a single layer of one material or may be a stack of multiple materials.

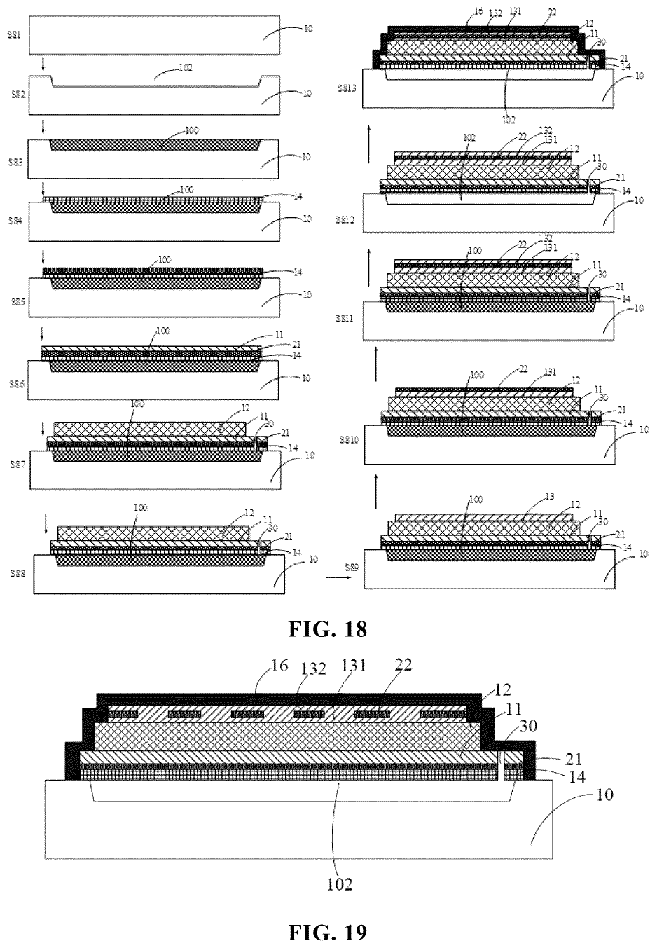

Next, a method of fabricating the bulk acoustic wave resonator in the eighth example will be described. FIG. 18 is a flow chart illustrating how to fabricate the bulk acoustic wave resonator shown in FIG. 17. As shown in FIG. 18, the fabrication method specifically includes the following steps S81 to S813.

At the step S81, the base substrate 10 is provided.

In some examples, taking the base substrate 10 being a mono-crystalline silicon substrate as an example, the step S81 may specifically include: firstly, performing ultrasonic cleaning with deionized water on the mono-crystalline silicon substrate; then putting the mono-crystalline silicon substrate into a mixed solution of H₂SO₄:H₂O=3:1, and heating the mixed solution to 250° C. and washing the mono-crystalline silicon substrate for 15 minutes; then putting the mono-crystalline silicon substrate into deionized water for ultrasonic cleaning; then putting the mono-crystalline silicon substrate into a mixed solution of NH₄OH:H₂O=1:6, and heating the mixed solution to 80° C. and washing the mono-crystalline silicon substrate for 15 minutes; taking out the mono-crystalline silicon substrate and putting the mono-crystalline silicon substrate into deionized water for washing; next, putting the mono-crystalline silicon substrate into a mixed solution of HCl:H₂O₂:H₂O=1:1:5, heating the mixed solution to 85° C. and washing the mono-crystalline silicon substrate for 15 minutes, and taking out the mono-crystalline silicon substrate and putting the mono-crystalline silicon substrate into diluted hydrofluoric acid of HF:H₂O=1:20, and rinsing the mono-crystalline silicon substrate for 10 seconds, to remove an oxide layer on the surface of the mono-crystalline silicon substrate; and finally, putting the mono-crystalline silicon substrate into deionized water for 20 minutes of ultrasonic cleaning, and drying the mono-crystalline silicon substrate with an air knife, thereby finishing the whole cleaning process of the base substrate 10.

At the step S82, the first groove 102 is formed in the base substrate 10.

In some examples, the step S82 may specifically include: fabricating a mask pattern on the base substrate 10, and performing a photolithography process including photoresist coating (or spraying), pre-baking, exposing, developing, and post-baking. Then, an etching process is performed to form the first groove 102. The etching process may be a wet etching process or a dry etching process, and the wet etching process is preferable. Finally, a photoresist stripping process is performed, thereby finishing the fabrication of the first groove 102.

At the step S83, a sacrificial layer is formed in the first groove 102.

In some examples, a material of the sacrificial layer may be a loose amorphous silicon dioxide doped with boron and phosphorus. The step S83 may specifically include: forming a slurry containing the loose amorphous silicon dioxide doped with boron and phosphorus by any one of Plasma Enhanced Chemical Vapor Deposition (PECVD), Sub-Atmospheric Pressure Chemical Vapor Deposition (SACVD), and screen printing; performing thermal annealing at 700° C. to 900° C. for 15 to 30 minutes in a vacuum chamber, so that a film of the loose amorphous silicon dioxide doped with boron and phosphorus is liquefied, and the resultant liquid flows and completely fills up the first groove 102, to level the first groove 102; and then cooling and curing the liquid. Finally, chemical mechanical polishing is performed, the base substrate 10 is pressed against a rough polishing pad by a polishing head, a surface of the base substrate 10 is planarized through a certain time of coupling effects of polishing solution corrosion, particle friction, polishing pad friction, and the like, until a surface of the material overflowing from the surface of the first groove 102 is polished to have a height equal to a height of the surface of the base substrate 10.

At the step S84, the isolation layer 14 is formed on the base substrate 10.

In some examples, the step S84 may specifically include: fabricating an isolation layer film on the base substrate 10. Firstly, an electrical insulation material is deposited, where the deposition manner may be selected from radio frequency magnetron sputtering, Pulsed Laser Sputtering (PLD), Atomic Layer Deposition (ALD), and Plasma Chemical Vapor Deposition (PCVD). A photolithography process is performed on the isolation layer film, to form a pattern including the isolation layer 14, and the photolithography process includes photoresist coating (or spraying), pre-baking, exposing, developing, and post-baking. Finally, an etching process is performed. Preferably, a wet etching process is performed. Alternatively, a dry etching process may be selected.

At the step S55, the first temperature drift compensation layer 21 is formed on a side of the isolation layer 14 away from the base substrate 10.

In some examples, the step S55 may specifically include: firstly depositing a temperature drift compensation layer film preferably by radio frequency magnetron sputtering. Alternatively, Pulsed Laser Deposition (PLD), Molecular Beam Epitaxy (MBE), Metal Organic Chemical Vapor Deposition (MOCVD), Plasma Enhanced Chemical Vapor Deposition (PECVD), sol-gel method (firstly coating a slurry containing a material of the temperature drift compensation layer, and then performing heat sintering), thermal evaporation, electron beam evaporation, or the like may be selected. Then, a photolithography process is performed on the temperature drift compensation layer film, where the photolithography process includes photoresist coating (or spraying), pre-baking, exposing, developing, and post-baking. Finally, an etching process is performed to form a pattern of the first temperature drift compensation layer 21. Preferably a wet etching process is performed. Alternatively, a dry etching process may be selected.

At the step S86, the first electrode 11 is formed on a side of the isolation layer 14 away from the base substrate 10.

In some examples, in a case where the first electrode 11 is made of a metal material, the step S86 may include: depositing a first metal film on the side of the first temperature drift compensation layer 21 away from the base substrate 10, where the deposition manner is preferably direct current magnetron sputtering (radio frequency magnetron sputtering is also possible). Alternatively, Pulsed Laser Deposition (PLD), Molecular Beam Epitaxy (MBE), thermal evaporation, electron beam evaporation, or the like may be selected, or attaching a copper foil may be adopted. Then, a photolithography process is performed on the first metal film, where the photolithography process includes photoresist coating (or spraying), pre-baking, exposing, developing, and post-baking. Next, an etching process is performed to form a pattern including the first electrode 11, where the etching process is preferably a wet etching process. Alternatively, a dry etching process may be selected. Finally, a photoresist stripping process is performed, thereby completing the fabrication of the first electrode 11.

At the step S87, the release hole 30 is formed to penetrate through the first electrode 11, the first temperature drift compensation layer 21, and the isolation layer 14.

In some examples, the step S87 may specifically include: firstly performing a photolithography process on a side of the first electrode 11 away from the base substrate 10, including photoresist coating (or spraying), pre-baking, exposing, developing, and post-baking, to expose a position where the release hole is located. Then, a dry etching process is performed to etch the first electrode 11, then etching gas is replaced to etch the first temperature drift compensation layer 21, then the etching gas is replaced again to etch the isolation layer 14, until the sacrificial layer is exposed. Finally, a photoresist stripping process is performed, thereby forming the release hole 30.

At the step S88, the piezoelectric layer 12 is formed on a side of the first electrode 11 away from the base substrate 10.

In some examples, taking the piezoelectric layer 12 being an AlN single-layer structure as an example, the step S88 may include: forming a piezoelectric material layer on the side of the first electrode 11 away from the base substrate 10, and conducting an oriented growth of the piezoelectric material layer, where the piezoelectric material layer is preferably formed through radio frequency magnetron sputtering (or direct current magnetron sputtering), and for the AlN piezoelectric material, a target material is Al, and by controlling gas pressure and temperature of Ar and N₂ during deposition and post-annealing time and temperature, a C-axis oriented AlN piezoelectric material layer is formed, and preferably, the growth orientation is (001). The deposition manner of the piezoelectric material layer may be selected from Pulsed Laser Deposition (PLD), Molecular Beam Epitaxy (MBE), Metal Organic Chemical Vapor Deposition (MOCVD), Plasma Enhanced Chemical Vapor Deposition (PECVD), and the like. Next, a photolithography process, including photoresist coating (or spraying), pre-baking, exposing, developing, and post-baking, is performed on the piezoelectric material layer. An etching process is then performed to form a pattern including the piezoelectric layer 12. Preferably, a wet etching process is performed. Alternatively, a dry etching process may be selected. Finally, a photoresist stripping process is performed, thereby completing the fabrication of the piezoelectric layer 12.

At the step S89, the third sub-electrode 131 is formed on a side of the piezoelectric layer 12 away from the first electrode 11.

In some examples, in a case where the third sub-electrode 131 is made of a metal material, the step S89 may specifically include: firstly depositing a second metal film on the side of the piezoelectric layer 12 away from the first electrode 11 preferably by direct current magnetron sputtering (radio frequency magnetron sputtering is also possible). Alternatively, Pulsed Laser Deposition (PLD), Molecular Beam Epitaxy (MBE), thermal evaporation, electron beam evaporation, or the like may be selected. Then, a photolithography process is performed on the second metal film, where the photolithography process includes photoresist coating (or spraying), pre-baking, exposing, developing, and post-baking. Thereafter, an etching process is performed to form a pattern including the third sub-electrode 131. The etching process is preferably a wet etching process. Alternatively, a dry etching process may be selected. Finally, a photoresist stripping process is performed, thereby completing the fabrication of the third sub-electrode 131.

At the step S810, the second temperature drift compensation layer 22 is formed on a side of the third sub-electrode 131 away from the base substrate 10.

In some examples, the step S810 may specifically include: firstly depositing a temperature drift compensation layer film preferably by radio frequency magnetron sputtering. Alternatively, Pulsed Laser Deposition (PLD), Molecular Beam Epitaxy (MBE), Metal Organic Chemical Vapor Deposition (MOCVD), Plasma Enhanced Chemical Vapor Deposition (PECVD), sol-gel method (firstly coating a slurry containing a material of the temperature drift compensation layer, and then performing heat sintering), thermal evaporation, electron beam evaporation, or the like may be selected. Then, a photolithography process is performed on the temperature drift compensation layer film, where the photolithography process includes photoresist coating (or spraying), pre-baking, exposing, developing, and post-baking. Finally, an etching process is performed to form a pattern of the second temperature drift compensation layer 22. Preferably, a wet etching process is performed. Alternatively, a dry etching process may be selected,

At the step S811, the fourth sub-electrode 132 is formed on a side of the second temperature drift compensation layer 22 away from the third sub-electrode 131.

In some examples, in a case where the fourth sub-electrode 132 is made of a metal material, the step S811 may specifically include: firstly depositing a third metal film on the side of the piezoelectric layer 12 away from the first electrode 11 preferably by direct current magnetron sputtering (radio frequency magnetron sputtering is also possible). Alternatively, Pulsed Laser Deposition (PLD), Molecular Beam Epitaxy (MBE), thermal evaporation, electron beam evaporation, or the like may be selected. Next, a photolithography process is performed on the third metal film, where the photolithography process includes photoresist coating (or spraying), pre-baking, exposing, developing, and post-baking. Thereafter, an etching process is performed to form a pattern including the fourth sub-electrode 132. The etching process is preferably a wet etching process. Alternatively, a dry etching process may be selected. Finally, a photoresist stripping process is performed, thereby completing the fabrication of the fourth sub-electrode 132.

At the step S812, the sacrificial layer is removed.

In some examples, the step S812 may include: etching the sacrificial layer, preferably through a wet etching process. A mixed etching solution of hydrofluoric acid, dilute nitric acid and deionized water is used to perform an immersion etching process (an etching temperature may be properly increased for increasing the wet etching rate) on the sacrificial layer for a long enough time, to ensure that the material of silicon dioxide doped with boron and phosphorus filled in the first groove 102 is completely dissolved. Finally, the first groove 102 is ultrasonically cleaned with deionized water for many times, and dried, to form the first groove 102.

At the step S813, the encapsulation layer 16 is formed on a side of the fourth sub-electrode 132 away from the base substrate 10.

In some examples, taking the encapsulation layer 16 made of an organic compound material as an example, the step S813 may specifically include: firstly coating an organic material liquid, which may specifically be selected from spin coating, spraying, inkjet printing, transferring, and the like; and then heating and curing the organic material liquid, to form a pattern of the encapsulation layer 16.

At this point, the fabrication of the acoustic wave resonator is completed. Alternatively, if a plurality of bulk acoustic wave resonators are simultaneously fabricated, the fabrication method provided by the embodiment of the present disclosure may further include a step of device cutting.

A ninth example is as follows: FIG. 19 is a schematic diagram illustrating a structure of a bulk acoustic wave resonator in a ninth example implemented in the present disclosure. As shown in FIG. 19, the structure of the bulk acoustic wave resonator in this example is substantially the same as that of the bulk acoustic wave resonator in the eighth example, except that the second temperature drift compensation layer 22 has a hollow out pattern in this example. That is, the second temperature drift compensation layer 22 has through holes extending in the thickness direction thereof, and in this case, the third sub-electrode 131 and the fourth sub-electrode 132 of the second electrode 13 may be electrically connected together by the through holes penetrating through the second temperature drift compensation layer 22, so that the resistance of the second electrode 13 is reduced, and the in-band insertion loss of the bulk acoustic wave resonator is reduced. The same structures as in the eighth example may be adopted for the remaining structures in the bulk acoustic wave resonator, and therefore, the details are not repeated herein.

The method of fabricating the bulk acoustic wave resonator in the ninth example may be the same as the fabrication method in the eighth example, except that during forming the second temperature drift compensation layer 22, the through holes extending in the thickness direction thereof are formed, that is, the hollow out pattern is formed. The remaining steps are the same as those in the eighth example, and therefore, the details are not repeated herein.

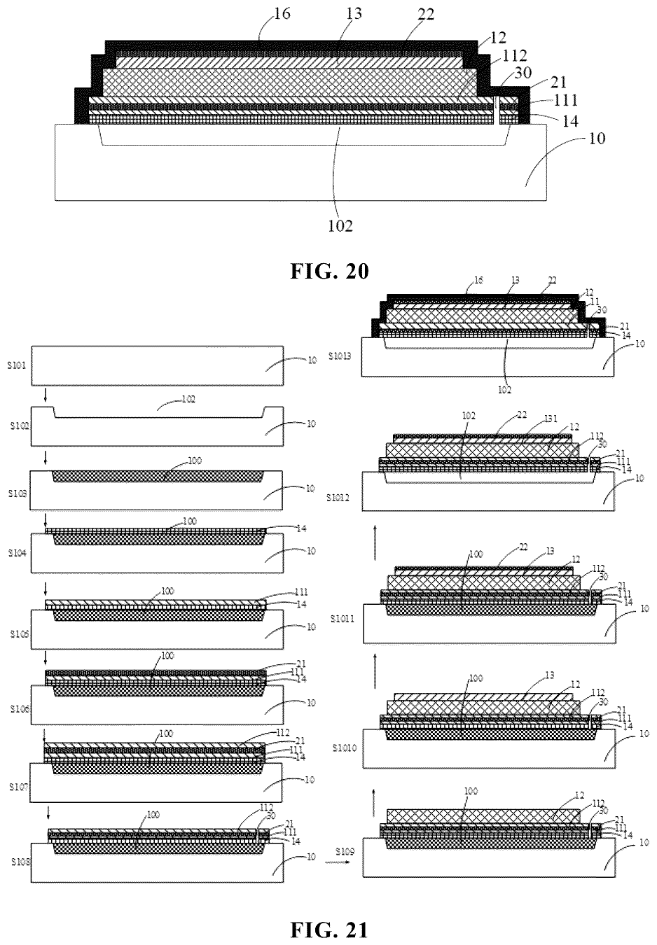

A tenth example is as follows: FIG. 20 is a schematic diagram illustrating a structure of a bulk acoustic wave resonator in a tenth example implemented in the present disclosure. As shown in FIG. 20, the bulk acoustic wave resonator includes a base substrate 10, and an isolation layer 14, a first temperature drift compensation layer 21, a first electrode 11, a piezoelectric layer 12, a second electrode 13, and a second temperature drift compensation layer 22 disposed on the base substrate 10. The first electrode 11 includes a first sub-electrode 111 and a second sub-electrode 112, and in the bulk acoustic wave resonator, the isolation layer 14, the first sub-electrode 111, the first temperature drift compensation layer 21, the second sub-electrode 112, the piezoelectric layer 12, the second electrode 13, and the second temperature drift compensation layer 22 are sequentially disposed in a direction away from the base substrate 10. The base substrate 10 has a first groove 102 occupying a portion of the base substrate 10 in a thickness direction of the base substrate 10, that is, an air gap is formed under the isolation layer 14. A release hole 30 penetrating through the first sub-electrode 111, the second sub-electrode 112, the first temperature drift compensation layer 21, and the isolation layer 14 serves to release a sacrificial layer formed in the first groove 102 in a process of fabricating the bulk acoustic wave resonator (details are described in the fabrication method).

With continued reference to FIG. 20, a radio frequency signal is transmitted from the upper left corner in FIG. 20, and then is converted into an acoustic wave signal through the inverse piezoelectric effect at an interface between the second electrode 13 and the piezoelectric layer 12; and then the acoustic wave signal longitudinally propagates in the piezoelectric layer 12, and is converted into a radio frequency signal through the piezoelectric effect when being transmitted to an interface between the second sub-electrode 112 and the piezoelectric layer 12; and then the radio frequency signal is transmitted out. The air gap under the bulk acoustic wave resonator and the air layer above the bulk acoustic wave resonator act as acoustic reflectors, which serve to limit the acoustic signal in the resonator structure instead of being dissipated, so that the insertion loss of the resonator can be reduced. The first temperature drift compensation layer 21 in the embodiment of the present disclosure is different from a general material, and a material of the temperature drift compensation layer has a property of contracting with heat and expanding with cold. When the ambient temperature rises, an increase of an in-plane lattice constant of the material of the piezoelectric layer 12, which is connected to the first temperature drift compensation layer 21 through the first electrode 11, is suppressed, and a degree of the suppression can be adjusted by factors such as different kinds of selection of thin film materials of the temperature drift compensation layer, different thicknesses of the temperature drift compensation layer, and the like, so that the out-plane lattice constant of the piezoelectric layer 12 can be decreased, increased, or unchanged with the rise of the ambient temperature, that is, can be flexibly adjusted, and thus the bulk acoustic wave resonator with a positive temperature coefficient, a negative temperature coefficient, or even a zero temperature coefficient can be obtained.

In some examples, a material of the base substrate 10 is preferably glass, and may alternatively be selected from Si, sapphire, SiC, GaAs, GaN, InP, BN, ZnO, and the like, and a thickness of the base substrate 10 is in a range from 0.1 μm to 10 mm. A thickness of the air gap on the base substrate 10 is in a range from 0.1 μm to 50 μm.

In some examples, materials of the first sub-electrode 111 and the second sub-electrode 112 are selected from metal materials. For example, the materials of the first sub-electrode 111 and the second sub-electrode 112 are a metal Mo, or may be selected from Cu, Al, Co, Ag, Ti, Pt, Ru, W, Au, or an alloy material formed by combining any of the above metals. A thickness of the first electrode 11 composed of the first sub-electrode 111 and the second sub-electrode 112 is about in a range from 1 nm to 10 μm.

In some examples, a material of the piezoelectric layer 12 is preferably hBN, and may alternatively be selected from cBN and wBN. Alternatively, the material of the piezoelectric layer 12 may be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, PVDF, and the like. The piezoelectric layer 12 in the present embodiment may be made of one of the piezoelectric materials described above, or may be a stack of the piezoelectric materials described above. A thickness of the piezoelectric layer 12 is in a range from 10 nm to 100 μm.

In some examples, a material of the second electrode 13 may be selected from Cu, Al, Mo, Co, Ag, Ti, Pt, Ru, W, Au, and alloys thereof. A thickness of the second electrode 13 is in a range from 1 nm to 10 μm.

In some examples, the isolation layer 14 serves to electrically isolate the air gap from the bulk acoustic wave resonator and provide a structural support for the bulk acoustic wave resonator, and is made of a material selected from insulation materials such as SiO₂, Si₃N₄, Al₂O₃, and a stack of combinations thereof. A thickness of the isolation layer 14 is in a range from 1 nm to 100 μm.

In some examples, the first temperature drift compensation layer 21 and the second temperature drift compensation layer 22 are both thin films made of materials having a property of contracting with heat and expanding with cold, and have the property of contracting with heat and expanding with cold. The materials of the first temperature drift compensation layer 21 and the second temperature drift compensation layer 22 may be selected from ZrW₂O₈, Zn₂GeO₄, HfW₂O₈, ZrMo₂O₈, HfMo₂O₈, ZrV₂O₇, HfV₂O₇, ZrV_{1.7}Mo_{0.3}O_{7+δ}, ZrV_{1.5}Mo_{0.5}O_{7+δ}, Cu₂V₂O₇, Cu₂₋ₓZnₓV₂O₇ (x is 0.1 or 0.2), Cu_{2-y}M_{y}V₂O₇ (M is any one of Yb, Sm, and Ce, and y is 0.05), Cu_{1.5}Mg_{0.5}V₂O₇, Cu₂P₂O₇, Cu₂PVO₇, HfMgW₃O₁₂, HfMgMo₃O₁₂, ZrMgMo₃O₁₂, ZrMgW₃O₁₂, ZrMnMo₃O₁₂, HfMnMo₃O₁₂, AScY₂XO₁₂ (A is Zr or Hf, Y is W or Mo, and X is V or P), TaVO₅, NbVO₅, Ag₂O, Th₂O(PO₄)₂, U₂O(PO₄)₂, Zr₂O(PO₄)₂, ScF₃, CaZrF₆, CaHfF₆, MgZrF₆, CaNbF₆, CaTiF₆, Zn(CN)₂, Cd(CN)₂, AgB(CN)₄, CuB(CN)₄, ScCo(CN)₆, Si(NCN)₂, Mn₃AN(A is Zn or Ga), GdInO3, PbTiO3, PbVO3, PbVO_{2.79}F_{0.21}, PbV₁₋ₓCrₓO₃Bi_{0.5}Na_{0.5}VO₃, GeTe, LaCu₃Fe₄O₁₂, BiNiO₃, V₂OPO₄, Ca₂RuO₄, Sr₂IrO₄, Sr₂RhO₄, Ca₂MnO₄, Ca₂GeO₄, Ca₃Mn₂O₇, and Ga₃Ti₂O₇. Thicknesses of the first temperature drift compensation layer 21 and the second temperature drift compensation layer 22 are both in a range from 1 nm to 100 μm.

In some examples, referring to FIG. 20, an encapsulation layer 16 is provided on a side of the second electrode 13 away from the base substrate 10. A material of the encapsulation layer 16 is preferably an organic compound capable of blocking moisture and oxygen, such as polyimide, epoxy, or the like, or may be an inorganic material such as SiNₓ, Al₂O₃, or the like. The encapsulation layer 16 may be a single layer of one material or may be a stack of multiple materials.

Next, a method of fabricating the bulk acoustic wave resonator in the tenth example will be described. FIG. 21 is a flow chart illustrating how to fabricate the bulk acoustic wave resonator shown in FIG. 20. As shown in FIG. 21, the fabrication method specifically includes the following steps S101 to S1013.

At the step S101, the base substrate 10 is provided.

In some examples, taking the base substrate 10 being a mono-crystalline silicon substrate as an example, the step S101 may specifically include: firstly, performing ultrasonic cleaning with deionized water on the mono-crystalline silicon substrate; then putting the mono-crystalline silicon substrate into a mixed solution of H₂SO₄:H₂O=3:1, and heating the mixed solution to 250° C. and washing the mono-crystalline silicon substrate for 15 minutes; then putting the mono-crystalline silicon substrate into deionized water for ultrasonic cleaning; then putting the mono-crystalline silicon substrate into a mixed solution of NH₄OH:H₂O=1:6, and heating the mixed solution to 80° C. and washing the mono-crystalline silicon substrate for 15 minutes; taking out the mono-crystalline silicon substrate and putting the mono-crystalline silicon substrate into deionized water for washing; next, putting the mono-crystalline silicon substrate into a mixed solution of HCl:H₂O₂:H₂O=1:1:5, heating the mixed solution to 85° C. and washing the mono-crystalline silicon substrate for 15 minutes, and taking out the mono-crystalline silicon substrate and putting the mono-crystalline silicon substrate into diluted hydrofluoric acid of HF:H₂O=1:20, and rinsing the mono-crystalline silicon substrate for 10 seconds, to remove an oxide layer on the surface of the mono-crystalline silicon substrate; and finally, putting the mono-crystalline silicon substrate into deionized water for 20 minutes of ultrasonic cleaning, and drying the mono-crystalline silicon substrate with an air knife, thereby finishing the whole cleaning process of the base substrate 10.

At the step S102, the first groove 102 is formed in the base substrate 10.

In some examples, the step S102 may specifically include: fabricating a mask pattern on the base substrate 10, and performing a photolithography process including photoresist coating (or spraying), pre-baking, exposing, developing, and post-baking. Then, an etching process is performed to form the first groove 102, and the etching process may be wet etching or dry etching, preferably wet etching. Finally, a photoresist stripping process is performed, thereby finishing the fabrication of the first groove 102.

At the step S103, a sacrificial layer is formed in the first groove 102.

In some examples, a material of the sacrificial layer may be a loose amorphous silicon dioxide doped with boron and phosphorus. The step S103 may specifically include: forming a slurry containing the loose amorphous silicon dioxide doped with boron and phosphorus by any one of Plasma Enhanced Chemical Vapor Deposition (PECVD), Sub-Atmospheric Pressure Chemical Vapor Deposition (SACVD), and screen printing; performing thermal annealing at 700° C. to 900° C. for 15 to 30 minutes in a vacuum chamber, so that a film of the loose amorphous silicon dioxide doped with boron and phosphorus is liquefied, and the resultant liquid flows and completely fills up the first groove 102, to level the first groove 102; and then cooling and curing the liquid. Finally, chemical mechanical polishing is performed, the base substrate 10 is pressed against a rough polishing pad by a polishing head, a surface of the base substrate 10 is planarized through a certain time of coupling effects of polishing solution corrosion, particle friction, polishing pad friction, and the like, until a surface of the material overflowing from the surface of the first groove 102 is polished to have a height equal to a height of the surface of the base substrate 10.

At the step S104, the isolation layer 14 is formed on the base substrate 10.

In some examples, the step S104 may specifically include: fabricating an isolation layer film on the base substrate 10. Firstly, an electrical insulation material is deposited by radio frequency magnetron sputtering, Pulsed Laser Sputtering (PLD), Atomic Layer Deposition (ALD), or Plasma Chemical Vapor Deposition (PCVD). A photolithography process is performed on the isolation layer film, to form a pattern including the isolation layer 14, and the photolithography process includes photoresist coating (or spraying), pre-baking, exposing, developing, and post-baking. Finally, an etching process is performed. Preferably, a wet etching process is performed. Alternatively, a dry etching process may be selected.

At the step S105, the first sub-electrode 111 is formed on a side of the isolation layer 14 away from the base substrate 10.

In some examples, in a case where the first electrode 11 is made of a metal material, the step S105 may include: depositing a first metal thin film on the side of the isolation layer 14 away from the base substrate 10 preferably by direct current magnetron sputtering (radio frequency magnetron sputtering is also possible). Alternatively, Pulsed Laser Deposition (PLD), Molecular Beam Epitaxy (MBE), thermal evaporation, electron beam evaporation, or the like may be selected, or attaching a copper foil may be adopted. Then, a photolithography process is performed on the first metal film, where the photolithography process includes photoresist coating (or spraying), pre-baking, exposing, developing, and post-baking. Next, an etching process is performed to form a pattern including the first sub-electrode 111, where the etching process is preferably a wet etching process. Alternatively, a dry etching process may be selected. Finally, a photoresist stripping process is performed, thereby completing the fabrication of the first sub-electrode 111.

At the step S106, the first temperature drift compensation layer 21 is formed on a side of the first sub-electrode 111 away from the base substrate 10.

In some examples, the step S106 may specifically include: firstly depositing a temperature drift compensation layer film preferably by radio frequency magnetron sputtering. Alternatively, Pulsed Laser Deposition (PLD), Molecular Beam Epitaxy (MBE), Metal Organic Chemical Vapor Deposition (MOCVD), Plasma Enhanced Chemical Vapor Deposition (PECVD), sol-gel method (firstly coating a slurry containing a material of the temperature drift compensation layer, and then performing heat sintering), thermal evaporation, electron beam evaporation, or the like may be selected. Then a photolithography process is performed on the temperature drift compensation layer film, where the photolithography process includes photoresist coating (or spraying), pre-baking, exposing, developing, and post-baking. Finally, an etching process is performed to form a pattern of the first temperature drift compensation layer 21. Preferably a wet etching process is performed. Alternatively, a dry etching process may be selected.

At the step S107, the second sub-electrode 112 is formed on a side of the first temperature drift compensation layer 21 away from the base substrate 10.

In some examples, in a case where the second sub-electrode 112 is made of a metal material, the step S107 may include: depositing a second metal film on the side of the first temperature drift compensation layer 21 away from the base substrate 10 preferably by direct current magnetron sputtering (radio frequency magnetron sputtering is also possible). Alternatively, Pulsed Laser Deposition (PLD), Molecular Beam Epitaxy (MBE), thermal evaporation, electron beam evaporation, or the like may be selected, or attaching a copper foil may be adopted. Then, a photolithography process is performed on the second metal film, where the photolithography process includes photoresist coating (or spraying), pre-baking, exposing, developing, and post-baking. Next, an etching process is performed to form a pattern including the second sub-electrode 112, where the etching process is preferably a wet etching process. Alternatively, a dry etching process may be selected. Finally, a photoresist stripping process is performed, thereby completing the fabrication of the second sub-electrode 112.

At the step S108, the release hole 30 is formed to penetrate through the first sub-electrode 111, the second sub-electrode 112, the isolation layer 14, and the first temperature drift compensation layer 21.

In some examples, the step S108 may specifically include: firstly performing a photolithography process on the second sub-electrode 112 at a side away from the base substrate 10, including photoresist coating (or spraying), pre-baking, exposing, developing, and post-baking, to expose a position where the release hole is located. Then, a dry etching process is performed to etch the second sub-electrode 112, then etching gas is replaced to etch the first temperature drift compensation layer 21, then the etching gas is replaced again to etch the first sub-electrode 111, then the etching gas is replaced again to etch the isolation layer 14, until the sacrificial layer is exposed. Finally, a photoresist stripping process is performed, thereby forming the release hole 30.

At the step S109, the piezoelectric layer 12 is formed on a side of the first electrode 11 away from the base substrate 10.

In some examples, taking the piezoelectric layer 12 being an AlN single-layer structure as an example, the step S109 may include: forming a piezoelectric material layer on the side of the first electrode 11 away from the base substrate 10, and conducting an oriented growth of the piezoelectric material layer, where the piezoelectric material layer is preferably formed through radio frequency magnetron sputtering (or direct current magnetron sputtering), and for the AlN piezoelectric material, a target material is Al, and by controlling gas pressure and temperature of Ar and N₂ during deposition and post-annealing time and temperature, a C-axis oriented AlN piezoelectric material layer is formed, and preferably, the growth orientation is (001). The piezoelectric material layer may be deposited by Pulsed Laser Deposition (PLD), Molecular Beam Epitaxy (MBE), Metal Organic Chemical Vapor Deposition (MOCVD), Plasma Enhanced Chemical Vapor Deposition (PECVD), or the like. Next, a photolithography process, including photoresist coating (or spraying), pre-baking, exposing, developing, and post-baking, is performed on the piezoelectric material layer. An etching process is then performed to form a pattern including the piezoelectric layer 12. Preferably, a wet etching process is performed. Alternatively, a dry etching process may be selected. Finally, a photoresist stripping process is performed, thereby completing the fabrication of the piezoelectric layer 12.

At the step S1010, the second electrode 13 is formed on a side of the piezoelectric layer 12 away from the first electrode 11.

In some examples, in a case where the second electrode 13 is made of a metal material, the step S1010 may specifically include: firstly depositing a third metal film on the side of the piezoelectric layer 12 away from the first electrode 11 preferably by direct current magnetron sputtering (radio frequency magnetron sputtering is also possible). Alternatively, Pulsed Laser Deposition (PLD), Molecular Beam Epitaxy (MBE), thermal evaporation, electron beam evaporation, or the like may be selected. Next, a photolithography process is performed on the third metal film, where the photolithography process includes photoresist coating (or spraying), pre-baking, exposing, developing, and post-baking. Thereafter, an etching process is performed to form a pattern including the second electrode 13. Preferably, the etching process is a wet etching process. Alternatively, a dry etching process may be selected. Finally, a photoresist stripping process is performed, thereby completing the fabrication of the second electrode 13.

At the step S1011, the second temperature drift compensation layer 22 is formed on a side of the second electrode 13 away from the base substrate 10.

In some examples, the step S1011 may specifically include: firstly depositing a temperature drift compensation layer film preferably by radio frequency magnetron sputtering. Alternatively, Pulsed Laser Deposition (PLD), Molecular Beam Epitaxy (MBE), Metal Organic Chemical Vapor Deposition (MOCVD), Plasma Enhanced Chemical Vapor Deposition (PECVD), sol-gel method (firstly coating a slurry containing a material of the temperature drift compensation layer, and then performing heat sintering), thermal evaporation, electron beam evaporation, or the like may be selected. Then, a photolithography process is performed on the temperature drift compensation layer film, where the photolithography process includes photoresist coating (or spraying), pre-baking, exposing, developing, and post-baking. Finally, an etching process is performed to form a pattern of the second temperature drift compensation layer 22. Preferably, a wet etching process is performed. Alternatively, a dry etching process may be selected.

At the step S1012, the sacrificial layer is removed.

In some examples, the step S1012 may include: etching the sacrificial layer, preferably through a wet etching process. A mixed etching solution of hydrofluoric acid, dilute nitric acid and deionized water is used to perform an immersion etching process (an etching temperature may be properly increased for increasing the wet etching rate) on the sacrificial layer for a long enough time, to ensure that the material of silicon dioxide doped with boron and phosphorus filled in the first groove 102 is completely dissolved. Finally, the first groove 102 is ultrasonically cleaned with deionized water for many times, and dried, to form the first groove 102.

At the step S1013, the encapsulation layer 16 is formed on a side of the second electrode 13 away from the base substrate 10.

In some examples, taking the encapsulation layer 16 made of an organic compound material as an example, the step S1013 may specifically include: firstly coating an organic material liquid, which may specifically be selected from spin coating, spraying, inkjet printing, transferring, and the like; and then heating and curing the organic material liquid, to form a pattern of the encapsulation layer 16.

At this point, the fabrication of the acoustic wave resonator is completed. Alternatively, if a plurality of bulk acoustic wave resonators are simultaneously fabricated, the fabrication method provided by the embodiment of the present disclosure may further include a step of device cutting.

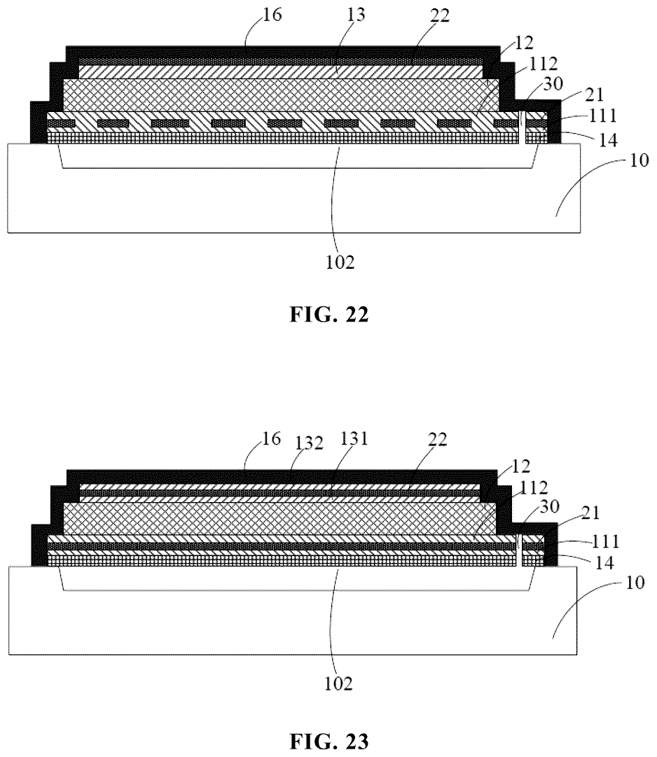

An eleventh example is as follows: FIG. 22 is a schematic diagram illustrating a structure of a bulk acoustic wave resonator in an eleventh example implemented in the present disclosure. As shown in FIG. 11, the structure of the bulk acoustic wave resonator in this example is substantially the same as that of the bulk acoustic wave resonator in the tenth example, except that the first temperature drift compensation layer 21 in this example has a hollow out pattern That is, the first temperature drift compensation layer 21 has through holes extending in the thickness direction thereof, and in this case, the first sub-electrode 111 and the second sub-electrode 112 of the first electrode 11 may be electrically connected together by the through holes penetrating through the first temperature drift compensation layer 21, so that the resistance of the first electrode 11 is reduced, and the in-band insertion loss of the bulk acoustic wave resonator is reduced. The same structures as in the tenth example may be adopted for the remaining structures in the bulk acoustic wave resonator, and therefore, details are not repeated herein.

The method of fabricating the bulk acoustic wave resonator in the eleventh example may be the same as the fabrication method in the tenth example, except that during forming the first temperature drift compensation layer 21, the through holes extending in the thickness direction thereof are formed. That is, the hollow out pattern is formed. The remaining steps are the same as those in the tenth example, and therefore, the details are not repeated herein.

A twelfth example is as follows: FIG. 23 is a schematic diagram illustrating a structure of a bulk acoustic wave resonator in a twelfth example implemented in the present disclosure. As shown in FIG. 23, the bulk acoustic wave resonator includes a base substrate 10, and an isolation layer 14, a first temperature drift compensation layer 21, a first electrode 11, a piezoelectric layer 12, a second electrode 13, and a second temperature drift compensation layer 22 disposed on the base substrate 10. The first electrode 11 includes a first sub-electrode 111 and a second sub-electrode 112, the second electrode 13 includes a third sub-electrode 131 and a fourth sub-electrode 132, and in the bulk acoustic wave resonator, the isolation layer 14, the first sub-electrode 111, the first temperature drift compensation layer 21, the second sub-electrode 112, the piezoelectric layer 12, the third sub-electrode 131, the second temperature drift compensation layer 22, and the fourth sub-electrode 132 are sequentially disposed in a direction away from the base substrate 10. The base substrate 10 has a first groove 102 occupying a portion of the base substrate 10 in a thickness direction of the base substrate 10. That is, an air gap is formed under the isolation layer 14. A release hole 30 penetrating through the first sub-electrode 111, the second sub-electrode 112, the first temperature drift compensation layer 21, and the isolation layer 14 serves to release a sacrificial layer formed in the first groove 102 in a process of fabricating the bulk acoustic wave resonator (details are described in the fabrication method).

With continued reference to FIG. 23, a radio frequency signal is transmitted from the upper left corner in FIG. 23, and then is converted into an acoustic wave signal through the inverse piezoelectric effect at an interface between the third sub-electrode 131 and the piezoelectric layer 12; and then the acoustic wave signal longitudinally propagates in the piezoelectric layer 12, and is converted into a radio frequency signal through the piezoelectric effect when being transmitted to the interface between the second sub-electrode 112 and the piezoelectric layer 12; and then the radio frequency signal is transmitted out. The air gap under the bulk acoustic wave resonator and the air layer above the bulk acoustic wave resonator act as acoustic reflectors, which serve to limit the acoustic signal in the resonator structure instead of being dissipated out, so that the insertion loss of the resonator can be reduced. The first temperature drift compensation layer 21 in the embodiment of the present disclosure is different from a general material, and a material of the temperature drift compensation layer has a property of contracting with heat and expanding with cold. When the ambient temperature rises, an increase of the in-plane lattice constant of the materials of the piezoelectric layer 12, which is connected to the first temperature drift compensation layer 21 through the second sub-electrode 112 and connected to the second temperature drift compensation layer 22 through the third sub-electrode 131, is suppressed, and a degree of the suppression can be adjusted by factors such as selection of different kinds of thin film materials of the temperature drift compensation layer, different thicknesses of the temperature drift compensation layer, and the like, so that the out-plane lattice constant of the piezoelectric layer 12 can be decreased, increased, or unchanged with the rise of the ambient temperature, that is, can be flexibly adjusted, and thus the bulk acoustic wave resonator with a positive temperature coefficient, a negative temperature coefficient, or even a zero temperature coefficient can be obtained.

In some examples, a material of the base substrate 10 is preferably glass, and may alternatively be selected from Si, sapphire, SiC, GaAs, GaN, InP, BN, ZnO, and the like, and a thickness of the base substrate 10 is in a range from 0.1 μm to 10 mm. A thickness of the air gap on the base substrate 10 is in a range from 0.1 μm to 50 μm.

In some examples, materials of the first sub-electrode 111 and the second sub-electrode 112 are selected from metal materials. For example, the materials of the first sub-electrode 111 and the second sub-electrode 112 are a metal Mo, or may be selected from Cu, Al, Co, Ag, Ti, Pt, Ru, W, Au, or an alloy material formed by any combination of the above metals. A thickness of the first electrode 11 composed of the first sub-electrode 111 and the second sub-electrode 112 is about in a range from 1 nm to 10 μm.

In some examples, a material of the piezoelectric layer 12 is preferably hBN, and may also be selected from cBN and wBN. Alternatively, the material of the piezoelectric layer 12 may also be selected from AlN, ZnO, PZT, GaN, InN, CdS, CdSe, ZnS, CdTe, ZnTe, GaAs, GaSb, InAs, InSb, GaSe, GaP, AlP, quartz crystal, LiTaO₃, LiNbO₃, La₃Ga₅SiO₁₄, BaTiO₃, PbNb₂O₆, PBLN, LiGaO₃, LiGeO₃, TiGeO₃, PbTiO₃, PbZrO₃, PVDF, and the like. The piezoelectric layer 12 in the present embodiment may be made of one of the piezoelectric materials described above, or may be a stack of the piezoelectric materials described above. A thickness of the piezoelectric layer 12 is in a range from 10 nm to 100 μm.

In some examples, a material of the second electrode 13 may be selected from Cu, Al, Mo, Co, Ag, Ti, Pt, Ru, W, Au, and alloys thereof. A thickness of the second electrode 13 is in a range from 1 nm to 10 μm.

In some examples, the isolation layer 14 serves to electrically isolate the air gap from the bulk acoustic wave resonator and provide a structural support for the bulk acoustic wave resonator, and is made of a material selected from insulation materials such as SiO₂, Si₃N₄, Al₂O₃, and a stack of combinations thereof. A thickness of the isolation layer 14 is in a range from 1 nm to 100 μm.

In some examples, the first temperature drift compensation layer 21 and the second temperature drift compensation layer 22 are both thin films made of materials having a property of contracting with heat and expanding with cold, and have the property of contracting with heat and expanding with cold. The materials of the first temperature drift compensation layer 21 and the second temperature drift compensation layer 22 may be selected from ZrW₂O₈, Zn₂GeO₄, HfW₂O₈, ZrMo₂O₈, HfMo₂O₈, ZrV₂O₇, HfV₂O₇, ZrV_{1.7}Mo_{0.3}O_{7+δ}, ZrV_{1.5}Mo_{0.5}O_{7+δ}, Cu₂V₂O₇, Cu₂₋ₓZnₓV₂O₇ (x is 0.1 or 0.2), Cu_{2-y}M_{y}V₂O₇ (M is any one of Yb, Sm, and Ce, and y is 0.05), Cu_{1.5}Mg_{0.5}V₂O₇, Cu₂P₂O₇, Cu₂PVO₇, HfMgW₃O₁₂, HfMgMo₃O₁₂, ZrMgMo₃O₁₂, ZrMgW₃O₁₂, ZrMnMo₃O₁₂, HfMnMo₃O₁₂, AScY₂XO₁₂ (A is Zr or Hf, Y is W or Mo, and X is V or P), TaVO₅, NbVO₅, Ag₂O, Th₂O(PO₄)₂, U₂O(PO₄)₂, Zr₂O(PO₄)₂, ScF₃, CaZrF₆, CaHfF₆, MgZrF₆, CaNbF₆, CaTiF₆, Zn(CN)₂, Cd(CN)₂, AgB(CN)₄, CuB(CN)₄, ScCo(CN)₆, Si(NCN)₂, Mn₃AN(A is Zn or Ga), GdInO3, PbTiO3, PbVO3, PbVO_{2.79}F_{0.21}, PbV₁₋ₓCrₓO₃Bi_{0.5}Na_{0.5}VO₃, GeTe, LaCu₃Fe₄O₁₂, BiNiO₃, V₂OPO₄, Ca₂RuO₄, Sr₂IrO₄, Sr₂RhO₄, Ca₂MnO₄, Ca₂GeO₄, Ca₃Mn₂O₇, and Ga₃Ti₂O₇. Thicknesses of the first temperature drift compensation layer 21 and the second temperature drift compensation layer 22 are both in a range from 1 nm to 100 μm.

In some examples, referring to FIG. 23, an encapsulation layer 16 is provided on a side of the second electrode 13 away from the base substrate 10. A material of the encapsulation layer 16 is preferably an organic compound capable of blocking moisture and oxygen, such as polyimide, epoxy, or the like, or may be an inorganic material such as SiNₓ, Al₂O₃, or the like. The encapsulation layer 16 may be a single layer of one material or may be a stack of multiple materials.

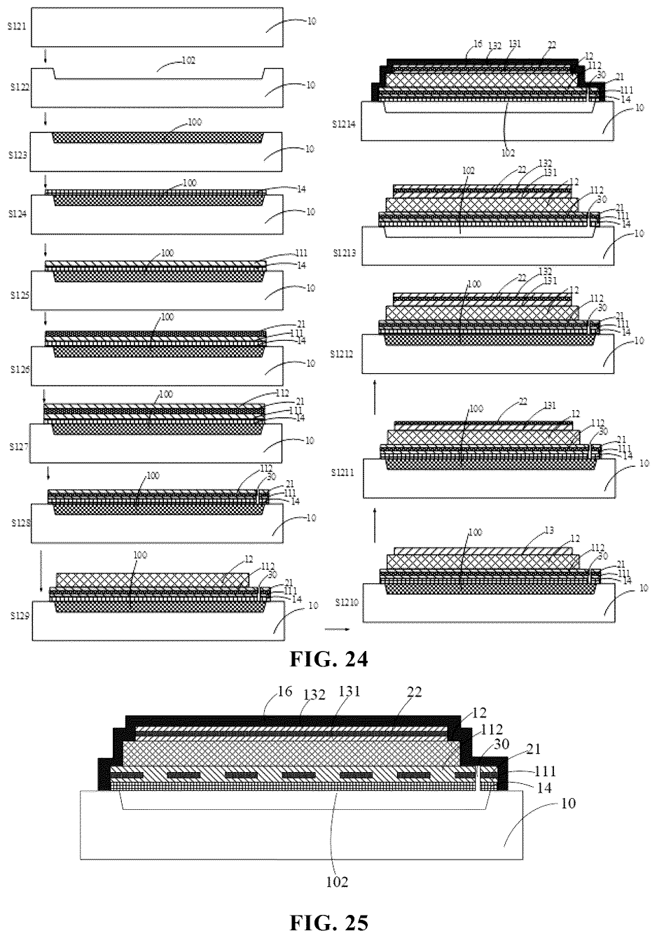

Next, a method of fabricating the bulk acoustic wave resonator in the twelfth example will be described. FIG. 24 is a flow chart illustrating how to fabricate the bulk acoustic wave resonator shown in FIG. 23. As shown in FIG. 24, the fabrication method specifically includes the following steps S121 to S1214.

At the step S121, the base substrate 10 is provided.

In some examples, taking the base substrate 10 being a mono-crystalline silicon substrate as an example, the step S121 may specifically include: firstly, performing ultrasonic cleaning with deionized water on the mono-crystalline silicon substrate; then putting the mono-crystalline silicon substrate into a mixed solution of H₂SO₄:H₂O=3:1, and heating the mixed solution to 250° C. and washing the mono-crystalline silicon substrate for 15 minutes; then putting the mono-crystalline silicon substrate into deionized water for ultrasonic cleaning; then putting the mono-crystalline silicon substrate into a mixed solution of NH₄OH:H₂O=1:6, and heating the mixed solution to 80° C. and washing the mono-crystalline silicon substrate for 15 minutes; taking out the mono-crystalline silicon substrate and putting the mono-crystalline silicon substrate into deionized water for washing; next, putting the mono-crystalline silicon substrate into a mixed solution of HCl:H₂O₂:H₂O=1:1:5, heating the mixed solution to 85° C. and washing the mono-crystalline silicon substrate for 15 minutes, and taking out the mono-crystalline silicon substrate and putting the mono-crystalline silicon substrate into diluted hydrofluoric acid of HF:H₂O=1:20, and rinsing the mono-crystalline silicon substrate for 10 seconds, to remove an oxide layer on the surface of the mono-crystalline silicon substrate; and finally, putting the mono-crystalline silicon substrate into deionized water for 20 minutes of ultrasonic cleaning, and drying the mono-crystalline silicon substrate with an air knife, thereby finishing the whole cleaning process of the base substrate 10.

At the step S122, the first groove 102 in the base substrate 10 is formed.

In some examples, the step S102 may specifically include: fabricating a mask pattern on the base substrate 10, and performing a photolithography process including photoresist coating (or spraying), pre-baking, exposing, developing, and post-baking. Then, an etching process is performed to form the first groove 102, and the etching process may be wet etching or dry etching, preferably wet etching. Finally, a photoresist stripping process is performed, thereby finishing the fabrication of the first groove 102.

At the step S123, a sacrificial layer is formed in the first groove 102.

In some examples, a material of the sacrificial layer may be a loose amorphous silicon dioxide doped with boron and phosphorus. The step S123 may specifically include: forming a slurry containing the loose amorphous silicon dioxide doped with boron and phosphorus by any one of Plasma Enhanced Chemical Vapor Deposition (PECVD), Sub-Atmospheric Pressure Chemical Vapor Deposition (SACVD), and screen printing; performing thermal annealing at 700° C. to 900° C. for 15 to 30 minutes in a vacuum chamber, so that a film of the loose amorphous silicon dioxide doped with boron and phosphorus is liquefied, and the resultant liquid flows and completely fills up the first groove 102, to level the first groove 102; and then cooling and curing the liquid. Finally, chemical mechanical polishing is performed, the base substrate 10 is pressed against a rough polishing pad by a polishing head, a surface of the base substrate 10 is planarized through a certain time of coupling effects of polishing solution corrosion, particle friction, polishing pad friction, and the like, until a surface of the material overflowing from the surface of the first groove 102 is polished to have a height equal to a height of the surface of the base substrate 10.

At the step S124, the isolation layer 14 is formed on the base substrate 10.

In some examples, the step S124 may specifically include: fabricating an isolation layer film on the base substrate 10. Firstly, an electrical insulation material is deposited by radio frequency magnetron sputtering, Pulsed Laser Sputtering (PLD), Atomic Layer Deposition (ALD), or Plasma Chemical Vapor Deposition (PCVD). A photolithography process is performed on the isolation layer film, to form a pattern including the isolation layer 14, and the photolithography process includes photoresist coating (or spraying), pre-baking, exposing, developing, and post-baking. Finally, an etching process is performed, preferably a wet etching process is performed. Alternatively, a dry etching process may be selected.

At the step S125, the first sub-electrode 111 is formed on a side of the isolation layer 14 away from the base substrate 10.

In some examples, in a case where the first electrode 11 is made of a metal material, the step S125 may include: depositing a first metal thin film on the side of the isolation layer 14 away from the base substrate 10 preferably by direct current magnetron sputtering (radio frequency magnetron sputtering is also possible). Alternatively, Pulsed Laser Deposition (PLD), Molecular Beam Epitaxy (MBE), thermal evaporation, electron beam evaporation, or the like may be selected, or attaching a copper foil may be adopted. Then, a photolithography process is performed on the first metal film, where the photolithography process includes photoresist coating (or spraying), pre-baking, exposing, developing, and post-baking. Next, an etching process is performed to form a pattern including the first sub-electrode 111, where the etching process is preferably a wet etching process. Alternatively, a dry etching process may be selected. Finally, a photoresist stripping process is performed, thereby completing the fabrication of the first sub-electrode 111.

At the step S126, the first temperature drift compensation layer 21 is formed on a side of the first sub-electrode 111 away from the base substrate 10.

In some examples, the step S126 may specifically include: firstly depositing a temperature drift compensation layer film preferably by radio frequency magnetron sputtering. Alternatively, Pulsed Laser Deposition (PLD), Molecular Beam Epitaxy (MBE), Metal Organic Chemical Vapor Deposition (MOCVD), Plasma Enhanced Chemical Vapor Deposition (PECVD), sol-gel method (firstly coating a slurry containing a material of the temperature drift compensation layer, and then performing heat sintering), thermal evaporation, electron beam evaporation, or the like may be selected. Then, a photolithography process is performed on the temperature drift compensation layer film, where the photolithography process includes photoresist coating (or spraying), pre-baking, exposing, developing, and post-baking. Finally, an etching process is performed to form a pattern of the first temperature drift compensation layer 21. Preferably, a wet etching process is performed. Alternatively, a dry etching process may be selected.

At the step S127, the second sub-electrode 112 is formed on a side of the first temperature drift compensation layer 21 away from the base substrate 10.

In some examples, in a case where the second sub-electrode 112 is made of a metal material, the step S127 may include: depositing a second metal film on the side of the first temperature drift compensation layer 21 away from the base substrate 10 preferably by direct current magnetron sputtering (radio frequency magnetron sputtering is also possible). Alternatively, Pulsed Laser Deposition (PLD), Molecular Beam Epitaxy (MBE), thermal evaporation, electron beam evaporation, or the like may be selected, or attaching a copper foil may be adopted. Then, a photolithography process is performed on the second metal film, where the photolithography process includes photoresist coating (or spraying), pre-baking, exposing, developing, and post-baking. Next, an etching process is performed to form a pattern including the second sub-electrode 112, where the etching process is preferably a wet etching process. Alternatively, a dry etching process may be selected. Finally, a photoresist stripping process is performed, thereby completing the fabrication of the second sub-electrode 112.

At the step S128, the release hole 30 is formed to penetrate through the first sub-electrode 111, the second sub-electrode 112, the isolation layer 14, and the first temperature drift compensation layer 21.

In some examples, the step S128 may specifically include: firstly performing a photolithography process on the second sub-electrode 112 at a side away from the base substrate 10, including photoresist coating (or spraying), pre-baking, exposing, developing, and post-baking, to expose a position where the release hole is located. Then, a dry etching process is performed to etch the second sub-electrode 112, then etching gas is replaced to etch the first temperature drift compensation layer 21, then the etching gas is replaced again to etch the first sub-electrode 111, then the etching gas is replaced again to etch the isolation layer 14, until the sacrificial layer is exposed. Finally, a photoresist stripping process is performed, thereby forming the release hole 30.

At the step S129, the piezoelectric layer 12 is formed on a side of the first electrode 11 away from the base substrate 10.

In some examples, taking the piezoelectric layer 12 being an AlN single-layer structure as an example, the step S129 may include: forming a piezoelectric material layer on the side of the first electrode 11 away from the base substrate 10, and conducting an oriented growth of the piezoelectric material layer, where the piezoelectric material layer is preferably formed through radio frequency magnetron sputtering (or direct current magnetron sputtering), and for the AlN piezoelectric material, a target material is Al, and by controlling gas pressure and temperature of Ar and N₂ during deposition and post-annealing time and temperature, a C-axis oriented AlN piezoelectric material layer is formed, and preferably, the growth orientation is (001). The piezoelectric material layer may be deposited by Pulsed Laser Deposition (PLD), Molecular Beam Epitaxy (MBE), Metal Organic Chemical Vapor Deposition (MOCVD), Plasma Enhanced Chemical Vapor Deposition (PECVD), or the like. Next, a photolithography process, including photoresist coating (or spraying), pre-baking, exposing, developing, and post-baking, is performed on the piezoelectric material layer. An etching process is then performed to form a pattern including the piezoelectric layer 12. Preferably, a wet etching process is performed. Alternatively, a dry etching process may be selected. Finally, a photoresist stripping process is performed, thereby completing the fabrication of the piezoelectric layer 12.

At the step S1210, the third sub-electrode 131 is formed on a side of the piezoelectric layer 12 away from the first electrode 11.

In some examples, in a case where the third sub-electrode 131 is made of a metal material, the step S1210 may specifically include: firstly depositing a third metal film on the side of the piezoelectric layer 12 away from the first electrode 11 preferably by direct current magnetron sputtering (radio frequency magnetron sputtering is also possible). Alternatively, Pulsed Laser Deposition (PLD), Molecular Beam Epitaxy (MBE), thermal evaporation, electron beam evaporation, or the like may be selected. Next, a photolithography process is performed on the third metal film, where the photolithography process includes photoresist coating (or spraying), pre-baking, exposing, developing, and post-baking. Thereafter, an etching process is performed to form a pattern including the third sub-electrode 131. The etching process is preferably a wet etching process. Alternatively, a dry etching process may be selected. Finally, a photoresist stripping process is performed, thereby completing the fabrication of the third sub-electrode 131.

At the step S1211, the second temperature drift compensation layer 22 is formed on a side of the third group of electrodes away from the base substrate 10.

In some examples, the step S1211 may specifically include: firstly depositing a temperature drift compensation layer film preferably by radio frequency magnetron sputtering. Alternatively, Pulsed Laser Deposition (PLD), Molecular Beam Epitaxy (MBE), Metal Organic Chemical Vapor Deposition (MOCVD), Plasma Enhanced Chemical Vapor Deposition (PECVD), sol-gel method (firstly coating a slurry containing a material of the temperature drift compensation layer, and then performing heat sintering), thermal evaporation, electron beam evaporation, or the like may be selected. Then, a photolithography process is performed on the temperature drift compensation layer film, where the photolithography process includes photoresist coating (or spraying), pre-baking, exposing, developing, and post-baking. Finally, an etching process is performed to form a pattern of the second temperature drift compensation layer 22. Preferably, a wet etching process is performed. Alternatively, a dry etching process may be selected.

At the step S1212, the fourth sub-electrode 132 is formed on a side of the second temperature drift compensation layer 22 away from the third sub-electrode 131.

In some examples, in a case where the fourth sub-electrode 132 is made of a metal material, the step S1212 may specifically include: firstly depositing a fourth metal thin film on the side of the second temperature drift compensation layer 22 away from the third sub-electrode 131 preferably by direct current magnetron sputtering (radio frequency magnetron sputtering is also possible). Alternatively, Pulsed Laser Deposition (PLD), Molecular Beam Epitaxy (MBE), thermal evaporation, electron beam evaporation, or the like may be selected. Then, a photolithography process is performed on the fourth metal film, where the photolithography process includes photoresist coating (or spraying), pre-baking, exposing, developing, and post-baking. Thereafter, an etching process is performed to form a pattern including the fourth sub-electrode 132. The etching process is preferably a wet etching process. Alternatively, a dry etching process may be selected. Finally, a photoresist stripping process is performed, thereby completing the fabrication of the fourth sub-electrode 132.

At the step S1213, the sacrificial layer is removed.

In some examples, the step S1214 may include: etching the sacrificial layer, preferably through a wet etching process. A mixed etching solution of hydrofluoric acid, dilute nitric acid and deionized water is used to perform an immersion etching process (an etching temperature may be properly increased for increasing the wet etching rate) on the sacrificial layer for a long enough time, to ensure that the material of silicon dioxide doped with boron and phosphorus filled in the first groove 102 is completely dissolved. Finally, the first groove 102 is ultrasonically cleaned with deionized water for many times, and dried, to form the first groove 102.

At the step S1214, the encapsulation layer 16 is formed on a side of the second electrode 13 away from the base substrate 10.

In some examples, taking the encapsulation layer 16 made of an organic compound material as an example, the step S1214 may specifically include: firstly coating an organic material liquid, which may specifically be selected from spin coating, spraying, inkjet printing, transferring, and the like; and then heating and curing the organic material liquid, to form a pattern of the encapsulation layer 16.

At this point, the fabrication of the acoustic wave resonator is completed. Alternatively, if a plurality of bulk acoustic wave resonators are simultaneously fabricated, the fabrication method provided by the embodiment of the present disclosure may further include a step of device cutting.

A thirteenth example is as follows: FIG. 25 is a schematic diagram illustrating a structure of a bulk acoustic wave resonator in a thirteenth example implemented in the present disclosure. As shown in FIG. 25, the structure of the bulk acoustic wave resonator in this example is substantially the same as that of the bulk acoustic wave resonator of the twelfth example, except that the first temperature drift compensation layer 21 has a hollow out pattern in this example. That is, the first temperature drift compensation layer 21 has through holes extending in the thickness direction thereof, and in this case, the first sub-electrode 111 and the second sub-electrode 112 of the first electrode 11 may be electrically connected together by the through holes penetrating through the first temperature drift compensation layer 21, so that the resistance of the first electrode 11 is reduced, and the in-band insertion loss of the bulk acoustic wave resonator is reduced. The same structures as in the twelfth example may be adopted for the remaining structures in the bulk acoustic wave resonator, and therefore, details are not repeated herein.

The method of fabricating the bulk acoustic wave resonator in the thirteenth example may be the same as the fabrication method in the twelfth example, except that during forming the first temperature drift compensation layer 21, the through holes extending in the thickness direction thereof are formed, that is, the hollow out pattern is formed. The remaining steps are the same as those in the twelfth example, and therefore, the details are not repeated herein.

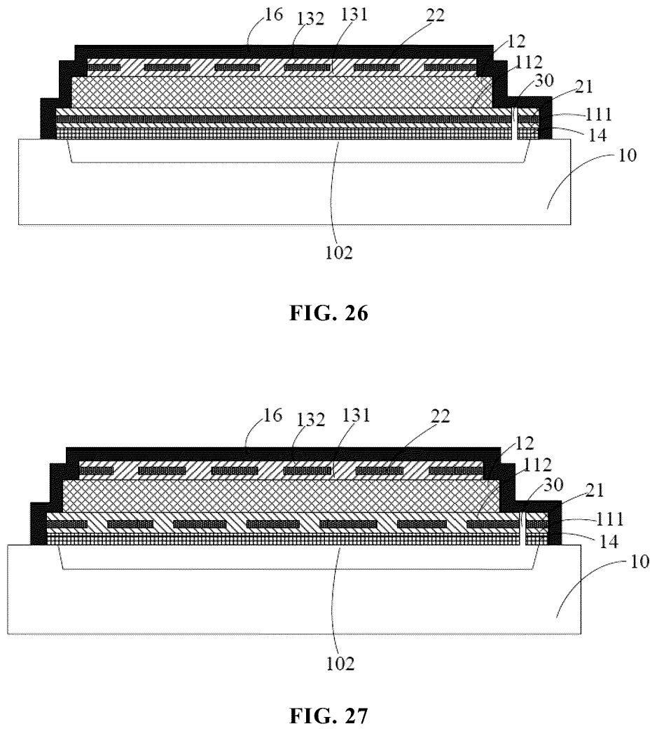

A fourteenth example is as follows: FIG. 26 is a schematic diagram illustrating a structure of a bulk acoustic wave resonator in a fourteenth example implemented in the present disclosure. As shown in FIG. 26, the structure of the bulk acoustic wave resonator in this example is substantially the same as that of the bulk acoustic wave resonator in the twelfth example, except that the second temperature drift compensation layer 22 in this example has a hollow out pattern. That is, the second temperature drift compensation layer 22 has through holes extending in the thickness direction thereof, and in this case, the third sub-electrode 131 and the fourth sub-electrode 132 of the second electrode 13 may be electrically connected together by the through holes penetrating through the second temperature drift compensation layer 22, so that the resistance of the second electrode 13 is reduced, and the in-band insertion loss of the bulk acoustic wave resonator is reduced. The same structures as in the twelfth example may be adopted for the remaining structures in the bulk acoustic wave resonator, and therefore, details are not repeated herein.

The method of fabricating the bulk acoustic wave resonator in the fourteenth example may be the same as the fabrication method in the twelfth example, except that during forming second temperature drift compensation layer 22, the through holes extending in the thickness direction thereof are formed. That is, the hollow out pattern is formed. The remaining steps are the same as those in the twelfth example, and therefore, the details are not repeated here.

A fifteenth example is as follows: FIG. 27 is a schematic diagram illustrating a structure of a of a fifteenth exemplary bulk acoustic wave resonator implemented in the present disclosure. As shown in FIG. 27, the structure of the bulk acoustic wave resonator in this example is substantially the same as that of the bulk acoustic wave resonator in the twelfth example, except that, the first temperature drift compensation layer 21 has a hollow out pattern in this example. That is, the first temperature drift compensation layer 21 has through holes extending in the thickness direction thereof, and the second temperature drift compensation layer 22 has a hollow out pattern. That is, the second temperature drift compensation layer 22 has through holes extending in the thickness direction thereof, and in this case, the first sub-electrode 111 and the second sub-electrode 112 of the first electrode 11 may be electrically connected together by the through holes penetrating through the first temperature drift compensation layer 21, thereby reducing the resistance of the first electrode 11, and the third sub-electrode 131 and the fourth sub-electrode 132 of the second electrode 13 may be connected together by the through holes penetrating through the second temperature drift compensation layer 22, thereby reducing the resistance of the second electrode 13, so that the in-band insertion loss of the bulk acoustic wave resonator is reduced. The same structures as in the twelfth example may be adopted for the remaining structures in the bulk acoustic wave resonator, and therefore, details are not repeated herein.

The method of fabricating the bulk acoustic wave resonator in the fifteenth example may be the same as the fabrication method in the fourteenth example, except that during forming the first temperature drift compensation layer 2, the through holes extending in the thickness direction thereof are formed. That is, the hollow out pattern is formed. The remaining steps are the same as those in the fourteenth example, and therefore, the details are not repeated herein.

Only fifteen exemplary bulk acoustic wave resonators and methods of fabricating a part of the bulk acoustic wave resonators are given above, but it should be understood that providing the temperature drift compensation layer for the bulk acoustic wave resonators in FIGS. 1 and 3 in the manner of providing the temperature drift compensation layer as described above, is within the protection scope of the embodiments of the present disclosure, and will not be described herein again.

An embodiment of the present disclosure further provides an electronic device, which may include any one of the bulk acoustic wave resonators described above.

It will be understood that, the above embodiments are merely exemplary embodiments adopted to illustrate the principles of the present disclosure, and the present disclosure is not limited thereto. It will be apparent to one of ordinary skill in the art that various changes and modifications can be made without departing from the spirit and scope of the present disclosure, and these changes and modifications are to be considered within the scope of the present disclosure.

1. A bulk acoustic wave resonator, comprising a base substrate, a first electrode, a piezoelectric layer, and a second electrode, wherein the first electrode is on the base substrate, the second electrode is on a side of the first electrode away from the base substrate, the piezoelectric layer is between the first electrode and the second electrode, and orthographic projections of any two of the first electrode, the piezoelectric layer and the second electrode on the base substrate at least partially overlap each other;
wherein the bulk acoustic wave resonator further comprises a temperature drift compensation layer which is on a side of the piezoelectric layer close to the base substrate and/or a side of the piezoelectric layer away from the base substrate; and a material of the temperature drift compensation layer has a property of expanding with heat and contracting with cold, and is configured to suppress temperature drift of the bulk acoustic wave resonator.

2. The bulk acoustic wave resonator according to claim 1, wherein the material of the temperature drift compensation layer is ZrW₂O₈, Zn₂GeO₄, HfW₂O₈, ZrMo₂O₈, HfMo₂O₈, ZrV₂O₇, HfV₂O₇, ZrV_{1.7}Mo_{0.3}O_{7+δ}, ZrV_{1.5}Mo_{0.5}O_{7+δ}, Cu₂V₂O₇, Cu₂₋ₓZnₓV₂O₇, Cu_{2-y}M_{y}V₂O₇, Cu_{1.5}Mg_{0.5}V₂O₇, Cu₂P₂O₇, Cu₂PVO₇, HfMgW₃O₁₂, HfMgMo₃O₁₂, ZrMgMo₃O₁₂, ZrMgW₃O₁₂, ZrMnMo₃O₁₂, HfMnMo₃O₁₂, AScY₂XO₁₂, TaVO₅, NbVO₅, Ag₂O, Th₂O(PO₄)₂, U₂O(PO₄)₂, Zr₂O(PO₄)₂, ScF₃, CaZrF₆, CaHfF₆, MgZrF₆, CaNbF₆, CaTiF₆, Zn(CN)₂, Cd(CN)₂, AgB(CN)₄, CuB(CN)₄, ScCo(CN)₆, Si(NCN)₂, Mn₃AN(A is Zn or Ga), GdInO3, PbTiO3, PbVO3, PbVO_{2.79}F_{0.21}, PbV₁₋ₓCrₓO₃, Bi_{0.5}Na_{0.5}VO₃, GeTe, LaCu₃Fe₄O₁₂, BiNiO₃, V₂OPO₄, Ca₂RuO₄, Sr₂IrO₄, Sr₂RhO₄, Ca₂MnO₄, Ca₂GeO₄, Ca₃Mn₂O₇, or Ga₂Ti₂O₇; and
for Cu₂₋ₓZnₓV₂O₇, x is 0.1 or 0.2; for Cu_{2-y}M_{y}V₂O₇, M is any one of Yb, Sm and Ce, and y is 0.05; and for AScY₂XO₁₂, A is Zr or Hf, Y is W or Mo, and X is V or P.

3. The bulk acoustic wave resonator according to claim 1, wherein a thickness of the temperature drift compensation layer is in a range from 1 nm to 100 μm.

4. The bulk acoustic wave resonator according to claim 1, wherein the temperature drift compensation layer has a hollow out pattern.

5. The bulk acoustic wave resonator according to claim 1, wherein the temperature drift compensation layer is on the side of the piezoelectric layer close to the base substrate, and on a side of the first electrode away from the piezoelectric layer.

6. The bulk acoustic wave resonator according to claim 1, wherein the temperature drift compensation layer is on the side of the piezoelectric layer away from the base substrate, and on a side of the second electrode away from the piezoelectric layer.

7. The bulk acoustic wave resonator according to claim 1, wherein the first electrode comprises a first sub-electrode and a second sub-electrode sequentially arranged in a direction away from the base substrate, and the temperature drift compensation layer is on the side of the piezoelectric layer close to the base substrate, and between the first sub-electrode and the second sub-electrode.

8. The bulk acoustic wave resonator according to claim 1, wherein the second electrode comprises a third sub-electrode and a fourth sub-electrode sequentially arranged in a direction away from the base substrate, and the temperature drift compensation layer is on the side of the piezoelectric layer away from the base substrate, and between the third sub-electrode and the fourth sub-electrode.

9. The bulk acoustic wave resonator according to claim 1, wherein the base substrate has a first groove occupying a portion of the base substrate in a thickness direction of the base substrate; and an isolation layer is on a side, facing the first electrode, of an opening of the first groove.

10. The bulk acoustic wave resonator according to claim 1, further comprising an isolation layer between the base substrate and the first electrode; and a space is defined between the isolation layer and the base substrate.

11. The bulk acoustic wave resonator according to claim 1, wherein the base substrate has a first cavity penetrating through the base substrate in a thickness direction of the base substrate; and an isolation layer is on a side of the base substrate close to the first electrode.

12. A method of fabricating a bulk acoustic wave resonator, comprising: sequentially forming a first electrode, a piezoelectric layer and a second electrode on a base substrate, wherein orthographic projections of any two of the first electrode, the piezoelectric layer and the second electrode on the base substrate at least partially overlap each other; wherein the method further comprises: forming a temperature drift compensation layer on a side of the piezoelectric layer close to the first base substrate and/or on a side of the piezoelectric layer away from the first base substrate; and a material of the temperature drift compensation layer has a property of expanding with heat and contracting with cold, and is configured to suppress temperature drift of the bulk acoustic wave resonator.

13. The method according to claim 12, wherein the material of the temperature drift compensation layer is ZrW₂O₈, Zn₂GeO₄, HfW₂O₈, ZrMo₂O₈, HfMo₂O₈, ZrV₂O₇, HfV₂O₇, ZrV_{1.7}Mo_{0.3}O_{7+δ}, ZrV_{1.5}Mo_{0.5}O_{7+δ}, Cu₂V₂O₇, Cu₂₋ₓZnₓV₂O₇, Cu_{2-y}M_{y}V₂O₇, Cu_{1.5}Mg_{0.5}V₂O₇, Cu₂P₂O₇, Cu₂PVO₇, HfMgW₃O₁₂, HfMgMo₃O₁₂, ZrMgMo₃O₁₂, ZrMgW₃O₁₂, ZrMnMo₃O₁₂, HfMnMo₃O₁₂, AScY₂XO₁₂, TaVO₅, NbVO₅, Ag₂O, Th₂O(PO₄)₂, U₂O(PO₄)₂, Zr₂O(PO₄)₂, ScF₃, CaZrF₆, CaHfF₆, MgZrF₆, CaNbF₆, CaTiF₆, Zn(CN)₂, Cd(CN)₂, AgB(CN)₄, CuB(CN)₄, ScCo(CN)₆, Si(NCN)₂, Mn₃AN(A is Zn or Ga), GdInO3, PbTiO3, PbVO3, PbVO_{2.79}F_{0.21}, PbV₁₋ₓCrₓO₃, Bi_{0.5}Na_{0.5}VO₃, GeTe, LaCu₃Fe₄O₁₂, BiNiO₃, V₂OPO₄, Ca₂RuO₄, Sr₂IrO₄, Sr₂RhO₄, Ca₂MnO₄, Ca₂GeO₄, Ca₃Mn₂O₇, or Ga₂Ti₂O₇, and
for Cu₂₋ₓZnₓV₂O₇, x is 0.1 or 0.2; for Cu_{2-y}M_{y}V₂O₇, M is any one of Yb, Sm and Ce, and y is 0.05; and for AScY₂XO₁₂, A is Zr or Hf, Y is W or Mo, and X is V or P.

14. (canceled)

15. The method according to claim 12, wherein the temperature drift compensation layer has a hollow out pattern.

16. The method according to claim 12, wherein the forming the temperature drift compensation layer on the side of the piezoelectric layer close to the base substrate is prior to the forming the first electrode.

17. The method according to claim 12, wherein the forming the temperature drift compensation layer on the side of the piezoelectric layer away from the base substrate is subsequent to the forming the second electrode.

18. The method according to claim 12, wherein the forming the first electrode comprises: sequentially forming a first sub-electrode and a second sub-electrode in a direction away from the base substrate; and
the forming the temperature drift compensation layer on the side of the piezoelectric layer close to the base substrate is between the forming the first sub-electrode and the forming the second sub-electrode.

19. The method according to claim 12, wherein the forming the second electrode comprises: sequentially forming a third sub-electrode and a fourth sub-electrode in a direction away from the base substrate; and
the forming the temperature drift compensation layer on the side of the piezoelectric layer away from the base substrate is between the forming the third sub-electrode and the forming the fourth sub-electrode.

20. The method according to claim 12, further comprising: processing the base substrate to form a first groove occupying a portion of the base substrate in a thickness direction of the base substrate; and providing an isolation layer on a side, facing the first electrode, of an opening of the first groove.

21-22. (canceled)

23. An electronic device, comprising the bulk acoustic wave resonator according to claim 1.
